(19) United States
(12) Patent Application Publication
(10) Pub. No.: US 2021/0013412 A1
(43) Pub. Date: Jan. 14, 2021

(54) PHOTOELECTRIC CONVERSION ELEMENT AND PHOTOELECTRIC CONVERSION ELEMENT MODULE

(71) Applicants: Naomichi KANEI, Shizuoka (JP); Tamotsu HORIUCHI, Shizuoka (JP); Yuuji TANAKA, Shizuoka (JP); Nozomu TAMOTO, Shizuoka (JP); Takahiro IDE, Shizuoka (JP)

(72) Inventors: Naomichi KANEI, Shizuoka (JP); Tamotsu HORIUCHI, Shizuoka (JP); Yuuji TANAKA, Shizuoka (JP); Nozomu TAMOTO, Shizuoka (JP); Takahiro IDE, Shizuoka (JP)

(21) Appl. No.: 16/981,895

(22) PCT Filed: Mar. 13, 2019
(86) PCT No.: PCT/JP2019/010393

§ 371 Date: Sep. 17, 2020

(30) Foreign Application Priority Data
Mar. 19, 2018 (JP) 2018-051312
Mar. 29, 2018 (JP) 2018-065512
Feb. 4, 2019 (JP) 2019-017705

(51) Int. Cl. H01L 51/00; H01L 51/44

(52) U.S. Cl. CPC H01L 51/006; H01L 51/0083; H01L 51/0074; H01L 2251/308; H01L 51/44; H01L 51/0067; H01L 51/0072; H01L 51/0084

(57) ABSTRACT

Provided is a photoelectric conversion element including a first electrode, an electron-transporting layer including a photosensitizing compound, a hole-transporting layer, and a second electrode, wherein the hole-transporting layer includes a p-type semiconductor material and a basic compound, ionization potential of the hole-transporting layer is greater than ionization potential of the p-type semiconductor material, and is less than 1.07 times the ionization potential of the p-type semiconductor material, ionization potential of the photosensitizing compound is greater than the ionization potential of the hole-transporting layer, and an acid dissociation constant (pKa) of the basic compound is 6 or greater but 10 or less.

### TECHNICAL FIELD

The present disclosure relates to a photoelectric conversion element and a photoelectric conversion element module.

### BACKGROUND ART

In recent years, solar cells have become more and more important as alternative energy for fossil fuels and as a measure against global warming. Moreover, solar battery cells or photodiodes are products for which a photoelectric conversion element capable of converting photo energy into electric energy is applied.

Recently, attentions are attracted to photoelectric conversion elements for indoor use, where such photoelectric conversion elements have high power generation performance with low illuminance light (illuminance: 20 lux or greater but 1,000 lux or less) such as light from light emitting diode (LED) or a fluorescent lamp, as well as sun light (illuminance of direct light: about 100,000 lux).

Therefore, proposed is a photoelectric conversion element having high photoelectric conversion performance (see, for example, PTL 1). However, the photoelectric conversion element of PTL 1 has a problem that stability thereof over time is insufficient and it is difficult to obtain both excellent photoelectric conversion performance and stability over time at the same time.

Accordingly, there is a need for a photoelectric conversion element that can obtain both high photoelectric conversion performance with low illumination light and stability over time.

Moreover, there is a problem that output of a photoelectric conversion element significantly reduces when the photoelectric conversion element is stored in a high temperature and high humidity environment. In order to prevent moisture or oxygen of the outer environment from permeating into the photoelectric conversion element, therefore, proposed is a photoelectric conversion element, in which a sealing member configured to seal a photoelectric conversion layer is disposed, for example, between a first electrode and a second substrate (see, for example, PTL 2).

### CITATION LIST

### Patent Literature

[PTL 1] Japanese Unexamined Patent Application Publication No. 2016-178102

[PTL2] Japanese Unexamined Patent Application Publication No. 2016-178288

### SUMMARY OF INVENTION

### Technical Problem

The present disclosure has an object to provide a photoelectric conversion element, which has excellent photoelectric conversion performance even with low illumination light and has excellent stability over time.

### Solution to Problem

According to one aspect of the present disclosure, a photoelectric conversion element includes a first electrode, an electron-transporting layer including a photosensitizing compound, a hole-transporting layer, and a second electrode, wherein the hole-transporting layer includes a p-type semiconductor material and a basic compound, ionization potential of the hole-transporting layer is greater than ionization potential of the p-type semiconductor material, and is less than 1.07 times the ionization potential of the p-type semiconductor material, ionization potential of the photosensitizing compound is greater than the ionization potential of the hole-transporting layer, and an acid dissociation constant (pKa) of the basic compound is 6 or greater but 10 or less.

### Advantageous Effects of Invention

The present disclosure can provide a photoelectric conversion element, which has excellent photoelectric conversion performance even with low illumination light and has excellent stability over time.

### BRIEF DESCRIPTION OF DRAWINGS

FIG. 1 is a schematic view illustrating an example of the photoelectric conversion element of the present disclosure.

FIG. 2 is a schematic view illustrating another example of the photoelectric conversion element of the present disclosure.

FIG. 3 is a schematic view illustrating another example of the photoelectric conversion element of the present disclosure.

FIG. 4 is a schematic view illustrating another example of the photoelectric conversion element of the present disclosure.

FIG. 5 is a schematic view illustrating another example of the photoelectric conversion element of the present disclosure.

FIG. 6 is a schematic view illustrating another example of the photoelectric conversion element module of the present disclosure.

FIG. 7 is a schematic view of FIG. 6 observed from a different angle.

FIG. 8 is a schematic view illustrating an example where a mouse is used as an electronic device.

FIG. 9 is a schematic view illustrating an example where the photoelectric conversion element is mounted in the mouse.

FIG. 10 is a schematic view illustrating an example where a keyboard used for a personal computer is used as an electronic device.

FIG. 11 is a schematic view illustrating an example where the photoelectric conversion element is mounted in the keyboard.

FIG. 12 is a schematic view illustrating an example where the small-size photoelectric conversion element is mounted in part of a key of the keyboard.

FIG. 13 is a schematic view illustrating an example where a sensor is used as an electronic device.

FIG. 14 is a schematic view illustrating an example where a turntable is used as an electronic device.

FIG. 15 is a schematic view illustrating an example of an electronic device in which the photoelectric conversion element and/or photoelectric conversion element module of the present disclosure, and a device driven by electric power generated through photoelectric conversion performed by the photoelectric conversion element and/or photoelectric conversion element module are combined.

FIG. 16 is a schematic view illustrating an example where a power supply IC for a photoelectric conversion element is installed between the photoelectric conversion element and the circuit of the device in FIG. 15.

FIG. 17 is a schematic view illustrating an example where an energy storage device is installed between the power supply IC and the circuit of the device in FIG. 16.

FIG. 18 is a schematic view illustrating an example of a power supply module including the photoelectric conversion element and/or photoelectric conversion element module of the present disclosure and a power supply IC.

FIG. 19 is a schematic view illustrating an example of the power supply module where an energy storage device is added to the power supply IC in FIG. 18.

### DESCRIPTION OF EMBODIMENTS

As a result of the researches diligently conducted by the present inventors, the present inventors have obtained the following insights.

In order to efficiently generate electric power with low illuminance light for indoor use, it is important to suppress current loss inside a photoelectric conversion element. However, it is difficult to obtain excellent photoelectric conversion performance because short-circuit current density reduces as internal resistance increases, and open-circuit voltage decreases as internal resistance decreases.

Ionization potential will be described hereinafter.

An organic semiconductor has the HOMO level and the LUMO level. A difference between the vacuum level and the LUMO level is called electron affinity and a difference between the vacuum level and the HOMO level is called ionization potential.

The ionization potential can be measured in the atmosphere. Specifically, the organic semiconductor is irradiated with ultraviolet rays to excite electrons of the HOMO level to the LUMO level. At the time of the irradiation, photoelectrons start being released at certain energy or higher when energy of the ultraviolet rays for excitation is changed by changing wavelengths of ultraviolet rays for the irradiation. The ionization potential can be measured by determining energy at which photoelectrons start to be released.

The present inventors have found that both high photoelectric conversion performance even with low illumination light and stability over time can be obtained at the same time, when ionization potential of a hole-transporting layer is greater than ionization potential of a p-type semiconductor material and is less than 1.07 times the ionization potential of the p-type semiconductor material, ionization potential of a photosensitizing compound is greater than the ionization potential of the hole-transporting layer, and an acid dissociation constant (pKa) of a basic compound is 6 or greater but 10 or less.

The ionization potential of the photosensitizing compound, the ionization potential of the hole-transporting material, and the ionization potential of the hole-transporting layer can be measured, for example, by means of an atmospheric pressure photoelectron spectroscopy apparatus.

Examples of the atmospheric pressure photoelectron spectroscopy apparatus include AC-2 (device name, available from RIKEN KEIKI Co., Ltd.).

The ionization potential of the photosensitizing compound can be measured in the state where the photosensitizing compound is adsorbed on an electron-transporting layer.

The ionization potential of the hole-transporting layer may be measured by means of the atmospheric pressure photoelectron spectroscopy apparatus without pealing only the hole-transporting layer from the photoelectric conversion element. However, the ionization potential is preferably measured by only the hole-transporting layer.

(Photoelectric Conversion Element)

The photoelectric conversion element of the present disclosure includes a first electrode, an electron-transporting layer including a photosensitizing compound, a hole-transporting layer, and a second electrode, wherein the hole-transporting layer includes a p-type semiconductor material and a basic compound, ionization potential of the hole-transporting layer is greater than ionization potential of the p-type semiconductor material, and is less than 1.07 times the ionization potential of the p-type semiconductor material, ionization potential of the photosensitizing compound is greater than the ionization potential of the hole-transporting layer, and an acid dissociation constant (pKa) of the basic compound is 6 or greater but 10 or less. The photoelectric conversion element may include other layers according to the necessity. Each layer may have a single layer structure or a laminate structure.

<First Electrode>

The photoelectric conversion element includes a first electrode.

A shape and size of the first electrode are not particularly limited and may be appropriately selected depending on the intended purpose.

A structure of the first electrode is not particularly limited and may be appropriately selected depending on the intended purpose. The structure of the first electrode may be a single layer structure or a structure where a plurality of materials are laminated.

A material of the first electrode is not particularly limited and may be appropriately selected depending on the intended purpose, as long as the material is a material having transparency to visible light and conductivity. Examples of the material include transparent conductive metal oxide, carbon, and metal.

Examples of the transparent conductive metal oxide include indium-tin oxide (referred to as “ITO” hereinafter), fluorine-doped tin oxide (referred to as “FTO” hereinafter), antimony-doped tin oxide (referred to as “ATO” hereinafter), niobium-doped tin oxide (referred to as “NTO” hereinafter), aluminium-doped zinc oxide, indium-zinc oxide, and niobium-titanium oxide.

Examples of the carbon include carbon black, carbon nanotubes, graphene, and fullerene.

Examples of the metal include gold, silver, aluminium, nickel, indium, tantalum, and titanium.

The above-listed examples may be used alone or in combination. Among the above-listed examples, transparent conductive metal oxide having high transparency is preferable, and ITO, FTO, ATO, and NTO are more preferable.

An average thickness of the first electrode is not particularly limited and may be appropriately selected depending on the intended purpose. The average thickness of the first electrode is preferably 5 nm or greater but 100 micrometers or less, and more preferably 50 nm or greater but 10 micrometers or less. In the case where a material of the first electrode is carbon or metal, the average thickness of the first electrode is preferably an average thickness with which translucency is easily obtained.

The first electrode can be formed by methods known in the art, such as sputtering, vapor deposition, and spraying.

Moreover, the first electrode is preferably formed on the first substrate. A commercial product where a first electrode is formed on a first substrate in advance and is integrated with the first substrate can be used.

Examples of the integrated commercial product include FTO coated glass, ITO coated glass, zinc oxide/aluminium coated glass, an FTO coated transparent plastic film, and an ITO coated transparent plastic film. Another examples of the integrated commercial product include a glass substrate with a transparent electrode in which tin oxide or indium oxide is doped with a cation or anion having a different atomic value, and a glass substrate with a metal electrode having a structure to pass through light, such as in the form of a mesh or stripes.

The above-listed examples may be used alone, or a mixture, or a laminate. Moreover, a metal lead wire may be used for the purpose of reducing an electric resistance value.

Examples of a material of the metal lead wire include aluminium, copper, silver, gold, platinum, and nickel.

For example, the metal lead wire is used in combination and formed on the substrate by vapor deposition, sputtering, or pressure bonding, followed by disposing a layer of ITO or FTO on the metal lead wire.

<Electron-Transporting Layer>

The photoelectric conversion element includes an electron-transporting layer that includes a photosensitizing compound.

Ionization potential of the photosensitizing compound is greater than ionization potential of a hole-transporting layer. The ionization potential of the photosensitizing compound exceeding the ionization potential of the hole-transporting layer is preferable because hole conduction efficiency to the hole-transporting layer is excellent.

The electron-transporting layer is formed for the purpose of transporting electrons generated by the photosensitizing compound to the first electrode or the hole blocking layer. Therefore, the electron-transporting layer is preferably arranged adjacent to the first electrode or the hole blocking layer.

A structure of the electron-transporting layer is not particularly limited and may be appropriately selected depending on the intended purpose. Within at least two photoelectric conversion elements adjacent to each other, the electron-transporting layers may be extended to each other but the electron-transporting layers are preferably not extended to each other. Moreover, a structure of the electron-transporting layer may be a single layer, or a multiple layer in which a plurality of layers are laminated.

The electron-transporting layer includes an electron-transporting material, and may further include other materials according to the necessity.

The electron-transporting material is not particularly limited and may be appropriately selected depending on the intended purpose. The electron-transporting material is preferably a semiconductor material.

It is preferable that the semiconductor material be in the shape of particles and a porous film be formed by joining the particles together. A photosensitizing compound is chemically or physically adsorbed on surfaces of the semiconductor particles constituting the porous electron-transporting layer.

The semiconductor material is not particularly limited and may be selected from materials known in the art. Examples of the semiconductor material include a single semiconductor, a compound semiconductor, and a compound having a perovskite structure.

Examples of the single semiconductor include silicon and germanium.

Examples of the compound semiconductor include chalcogenide of metal. Specific examples thereof include: oxides of titanium, tin, zinc, iron, tungsten, zirconium, hafnium, strontium, indium, cerium, yttrium, lanthanum, vanadium, niobium, and tantalum; sulfides of cadmium, zinc, lead, silver, antimony, and bismuth; selenides of cadmium and lead; and telluride of cadmium. Other examples of the compound semiconductor include: phosphides of zinc, gallium, indium, and cadmium; gallium arsenide; copper-indium-selenide; and copper-indium-sulfide.

Examples of the compound having a perovskite structure include strontium titanate, calcium titanate, sodium titanate, barium titanate, and potassium niobate.

Among the above-listed examples, oxide semiconductors are preferable, and particularly, titanium oxide, zinc oxide, tin oxide, and niobium oxide are more preferable. Use of titanium oxide as the electron-transporting material of the electron-transporting layer is advantageous because a conduction band is high and thus high open-circuit voltage can be obtained, and high photoelectric conversion performance can be obtained.

The above-listed examples may be used alone or in combination. Moreover, a crystal structure of any of the above-listed semiconductors is not particularly limited and may be appropriately selected depending on the intended purpose. The crystal structure thereof may be a single crystal, polycrystalline, or amorphous.

An average particle diameter of primary particles of the semiconductor material is not particularly limited and may be appropriately selected depending on the intended purpose. The average particle diameter thereof is preferably 1 nm or greater but 100 nm or less, and more preferably 5 nm or greater but 50 nm or less. Moreover, a semiconductor material having the lager particle size may be mixed or laminate. Use of such a semiconductor material may improve a conversion efficiency owing to an effect of scattering incident light. In this case, the average particle diameter is preferably 50 nm or greater but 500 nm or less.

An average thickness of the electron-transporting layer is not particularly limited and may be appropriately selected depending on the intended purpose. The average thickness of the electron-transporting layer is preferably 50 nm or greater but 100 micrometers or less, more preferably 100 nm or greater but 50 micrometers or less, and even more preferably 120 nm or greater but 10 micrometers or less. When the average thickness of the electron-transporting layer is within the preferable range, an amount of the photosensitizing compound per unit projected area can be sufficiently secured, a capturing rate of light can be maintained high, a diffusion length of injected electrons is not easily increased, and loss due to recombination of charge can be maintained low. Therefore, the electron-transporting layer having the average thickness falling in the preferable range is advantageous.

A production method of the electron-transporting layer is not particularly limited and may be appropriately selected depending on the intended purpose. Examples of the production method thereof include a method where a thin film is formed in vacuum, such as sputtering, and a wet film forming method. Among the above-listed example, in view of a production cost, a wet film forming method is preferable, and a method where a paste in which powder or sol of a semiconductor material is dispersed is prepared, and the paste is applied onto a first electrode serving as an electron-collecting electrode substrate or a hole blocking layer is more preferable.

The wet film forming method is not particularly limited and may be appropriately selected depending on the intended purpose. Examples of the wet film forming method include dip coating, spray coating, wire bar coating, spin coating, roller coating, blade coating, gravure coating, and die coating.

As a wet printing method, for example, various methods, such as relief printing, offset printing, gravure printing, intaglio printing, rubber plate printing, and screen printing, can be used.

Examples of a method for producing a dispersion liquid of the semiconductor material include a method where the semiconductor material is mechanically pulverized using a milling device known in the art. According to the method as mentioned, a particular semiconductor material alone or a mixture of the semiconductor material and a resin is dispersed in water or a solvent to thereby produce a dispersion liquid of the semiconductor material.

Examples of the resin include a polymer or copolymer of a vinyl compound (e.g., styrene, vinyl acetate, acrylic acid ester, and methacrylic acid ester), a silicone resin, a phenoxy resin, a polysulfone resin, a polyvinyl butyral resin, a polyvinyl formal resin, a polyester resin, a cellulose ester resin, a cellulose ether resin, a urethane resin, a phenol resin, an epoxy resin, a polycarbonate resin, a polyarylate resin, a polyamide resin, and a polyimide resin. The above-listed examples may be used alone or in combination.

Examples of the solvent include water, an alcohol solvent, a ketone solvent, an ester solvent, an ether solvent, an amide solvent, a halogenated hydrocarbon solvent, and a hydrocarbon solvent.

Examples of the alcohol solvent include methanol, ethanol, isopropyl alcohol, and alpha-terpineol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, tirchloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed examples may be used alone or in combination.

In order to prevent reaggregation of particles, acid, a surfactant, or a chelating agent may be added to a dispersion liquid including the semiconductor material or a paste including the semiconductor material obtained by a sol-gel method.

Examples of the acid include hydrochloric acid, nitric acid, and acetic acid. Examples of the surfactant include polyoxyethylene octylphenyl ether.

Examples of the chelating agent include acetyl acetone, 2-aminoethanol, and ethylene diamine.

Moreover, it is also effective to add a thickener for the purpose of improving film forming ability.

Examples of the thickener include polyethylene glycol, polyvinyl alcohol, and ethyl cellulose.

After applying the semiconductor material, the semiconductor material may be subjected to firing, irradiation with microwaves or an electron beam, or laser beam irradiation in order to electrically contact particles of the semiconductor materials one another to improve the film strength or adhesion to the substrate. The above-listed processes may be performed alone or in combination.

In the case where the electron-transporting layer formed of the semiconductor material is fired, a firing temperature is not particularly limited and may be appropriately selected depending on the intended purpose. Since resistance of the substrate may become too high or a material may be melted when the temperature is too high, the firing temperature is preferably 30 degrees Celsius or higher but 700 degrees Celsius or lower, and more preferably 100 degrees Celsius or higher but 600 degrees Celsius or lower. Moreover, firing duration is not particularly limited and may be appropriately selected depending on the intended purpose. The firing duration is preferably 10 minutes or longer but 10 hours or shorter.

In the case where the electron-transporting layer formed of the semiconductor material is irradiated with microwaves, irradiate duration is not particularly limited and may be appropriately selected depending on the intended purpose. The irradiation duration is preferably 1 hour or shorter. In this case, irradiation may be performed from the side where the electron-transporting layer is formed, or from the side where the electron-transporting layer is not formed.

After firing the electron-transporting layer formed of the semiconductor material, for example, chemical plating using a titanium tetrachloride aqueous solution or a mixed solution with an organic solvent, or electrochemical plating using a titanium trichloride aqueous solution may be performed for the purpose of enhancing an electron injection efficiency from the below-mentioned photosensitizing compound to the semiconductor material.

The film obtained by firing the semiconductor material having a particle diameter of several tens nanometers can form a porous structure. Such a nanoporous structure has an extremely high surface area and the surface area can be represented by a roughness factor. The roughness factor is a numerical value representing an actual area of the inner side of pores relative to an area of the semiconductor particles applied onto the first substrate. Accordingly, the larger value of the roughness factor is more preferable. In view of a relationship with the average thickness of the electron-transporting layer, the roughness factor is preferably 20 or greater.

<<Photosensitizing Compound>>

A photosensitizing compound is adsorbed on a surface of the semiconductor material constituting the electron-transporting layer in order to further improve output or a photoelectric conversion efficiency.

The photosensitizing compound is not particularly limited and may be appropriately selected depending on the intended purpose, as long as the photosensitizing compound is a compound that is photoexcited by excitation light emitted to the photoelectric conversion element. Examples of the photosensitizing compound include compounds known in the art below.

Specific examples thereof include metal complex compounds, cumarin compounds disclosed in J. Phys. Chem. C, 7224, Vol. 111 (2007), polyene compounds disclosed in Chem. Commun., 4887 (2007), indoline compounds disclosed in J. Am. Chem. Soc., 12218, Vol. 126 (2004), Chem. Commun., 3036 (2003), and Angew. Chem. Int. Ed., 1923, Vol. 47 (2008), thiophene compounds disclosed in J. Am. Chem. Soc., 16701, Vol. 128 (2006), and J. Am. Chem. Soc., 14256, Vol. 128 (2006), cyanine dyes, me-rocyanine dyes, 9-arylxanthene compounds, triaryl methane compounds, ph-thalocyanine compounds disclosed in J. Phys. Chem., 2342, Vol. 91 (1987), J. Phys. Chem. B, 6272, Vol. 97 (1993), Electroanal. Chem., 31, Vol. 537 (2002) J. Porphyrins Phthalocyanines, 230, Vol. 3 (1999), Angew. Chem. Int. Ed., 373, Vol. 46 (2007), and Langmuir, 5436, Vol. 24 (2008), and porphyrin compounds.

Among the above-listed examples, a metal complex compound, a cumarin compound, a polyene compound, an indoline compound, and a thiophene compound are preferable. The compounds represented by Structural Formulae (1), (2), and (3) below available from MITSUIBISHI PAPER MILLS LIMITED, and moreover a compound represented by General Formula (3) below are more preferable. The above-listed photosensitizing compounds may be used alone or in combination.

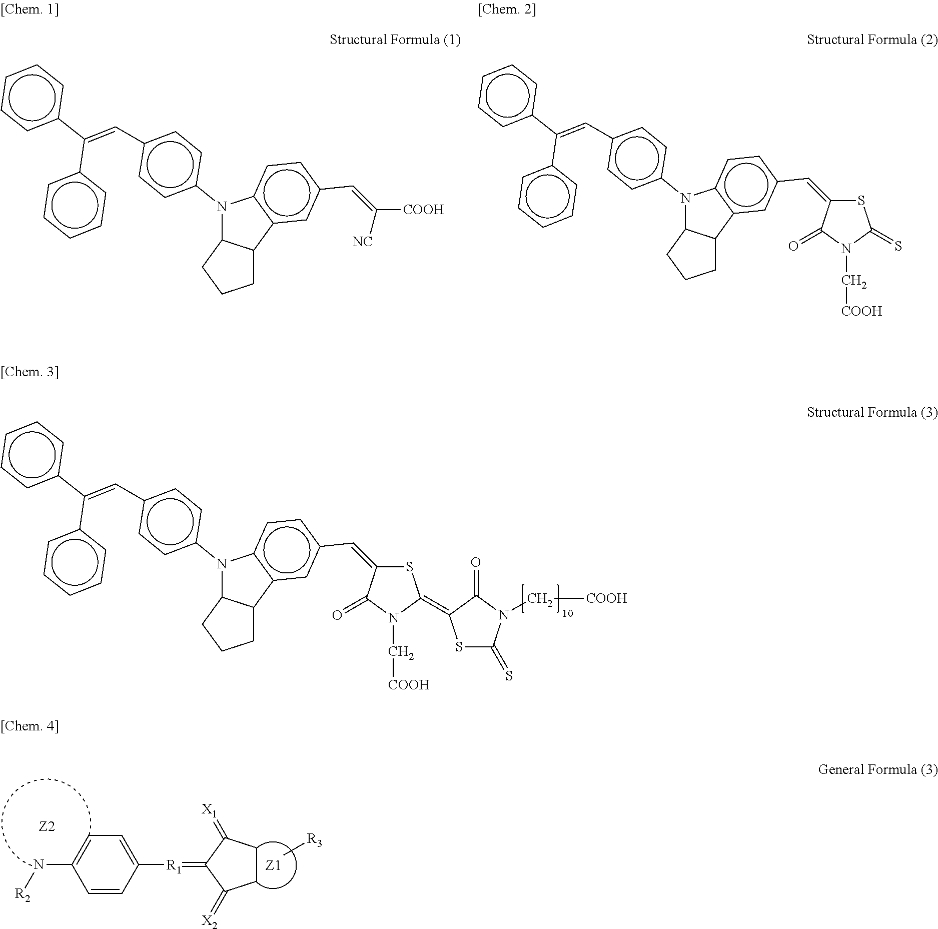

In General Formula (3), X₁ and X₂ are each an oxygen atom, a sulfur atom, and a selenium atom; R₁ is a methine group that may have a substituent, where specific examples of the substituent include an aryl group (e.g., a phenyl group and a naphthyl group) and a hetero cycle (e.g., a thienyl group and a furyl group); R₂ is an alkyl group that may have a substituent, an aryl group, or a heterocyclic group, where examples of the alkyl group include a methyl group, an ethyl group, a 2-propyl group, and a 2-ethylhexyl group, and examples of the aryl group and heterocyclic group includes the groups listed above; R₃ is an acid group, such as carboxylic acid, sulfonic acid, phosphonic acid, boronic acid, and phenols; and Z1 and Z2 are each a substituent for forming a ring structure where examples of Z1 include a condensation hydrocarbon-based compound (e.g., a benzene ring and a naphthalene ring) and a heteroring (e.g., a thiophene ring, and a furan ring) all of which may have a substituent, specific examples thereof include the above-listed alkyl group, and an alkoxy group (e.g., a methoxy group, an ethoxy group, and a 2-isopropoxy group), and examples of Z2 include the following (A-1) to (A-22).

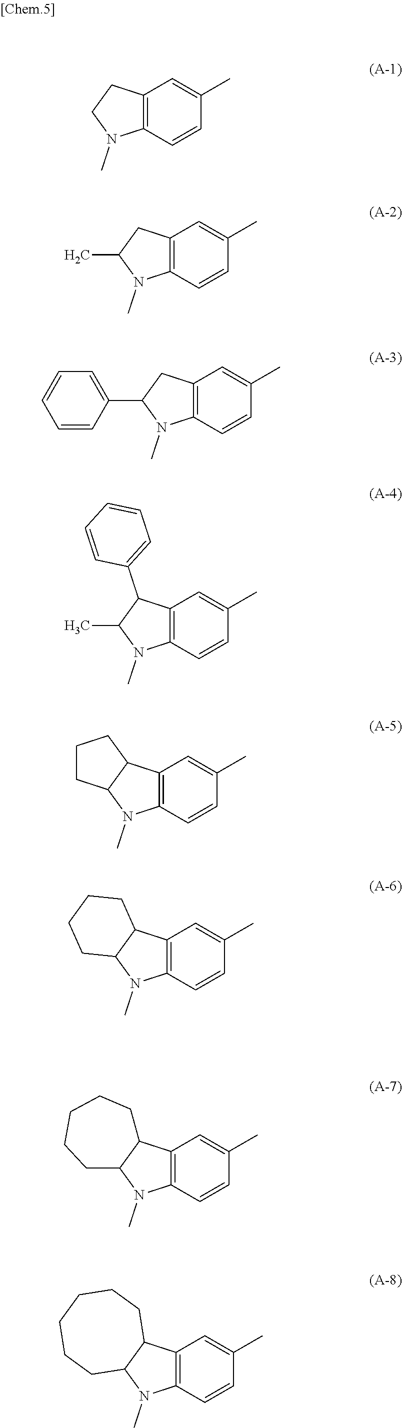

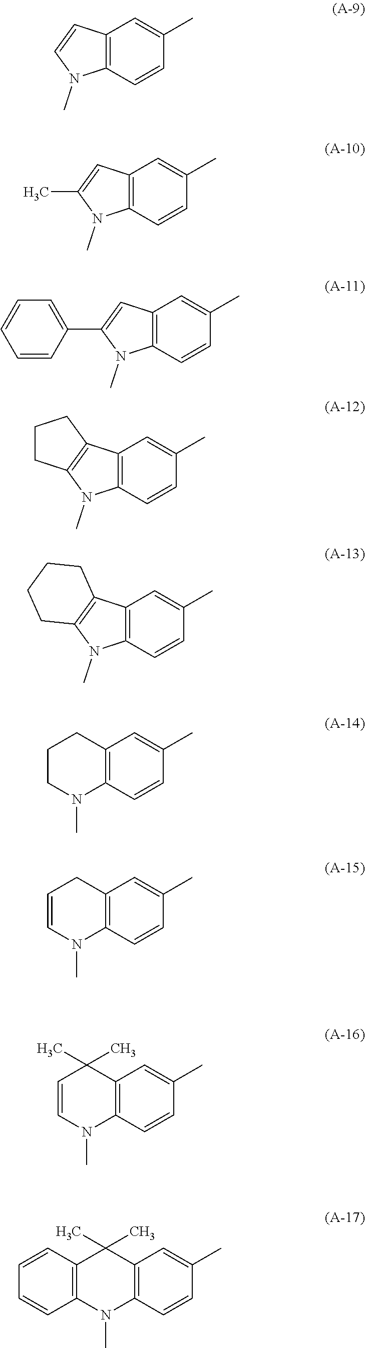

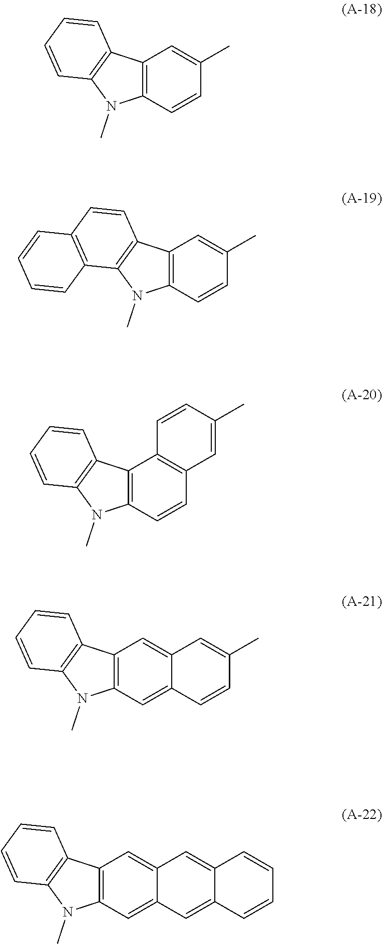 [SMILES: Cc1ccc2c(c1)c1ccccc1n2C ; Cc1ccc2c(c1)c1ccc3ccccc3c1n2C ; Cc1ccc2c(ccc3c2c2ccccc2n3C)c1 ; Cc1ccc2cc3c(cc2c1)c1ccccc1n3C ; Cn1c2ccccc2c2cc3cc4ccccc4cc3cc21]

Specific examples of the photosensitizing compound represented by General Formula (3) include the following (B-1) to (B-36). However, the photosensitizing compound is not limited to the following examples.

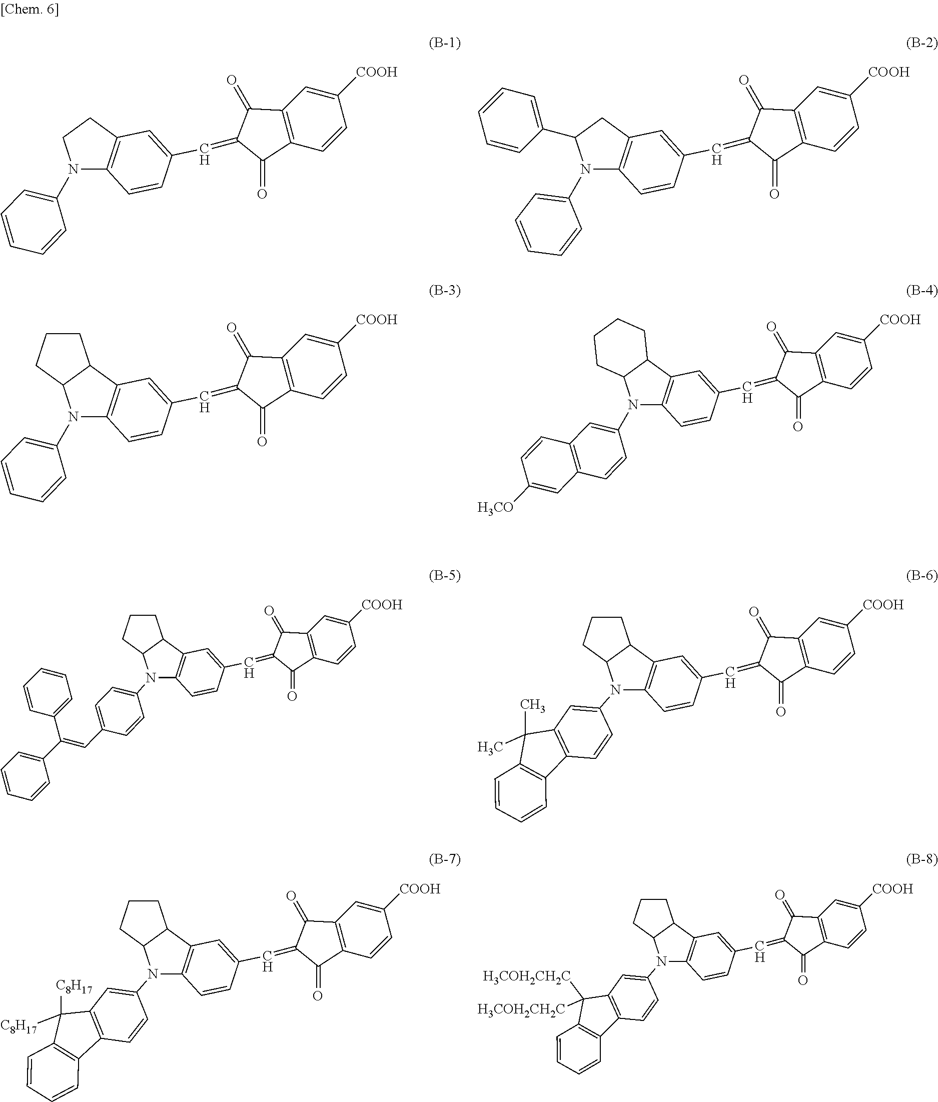

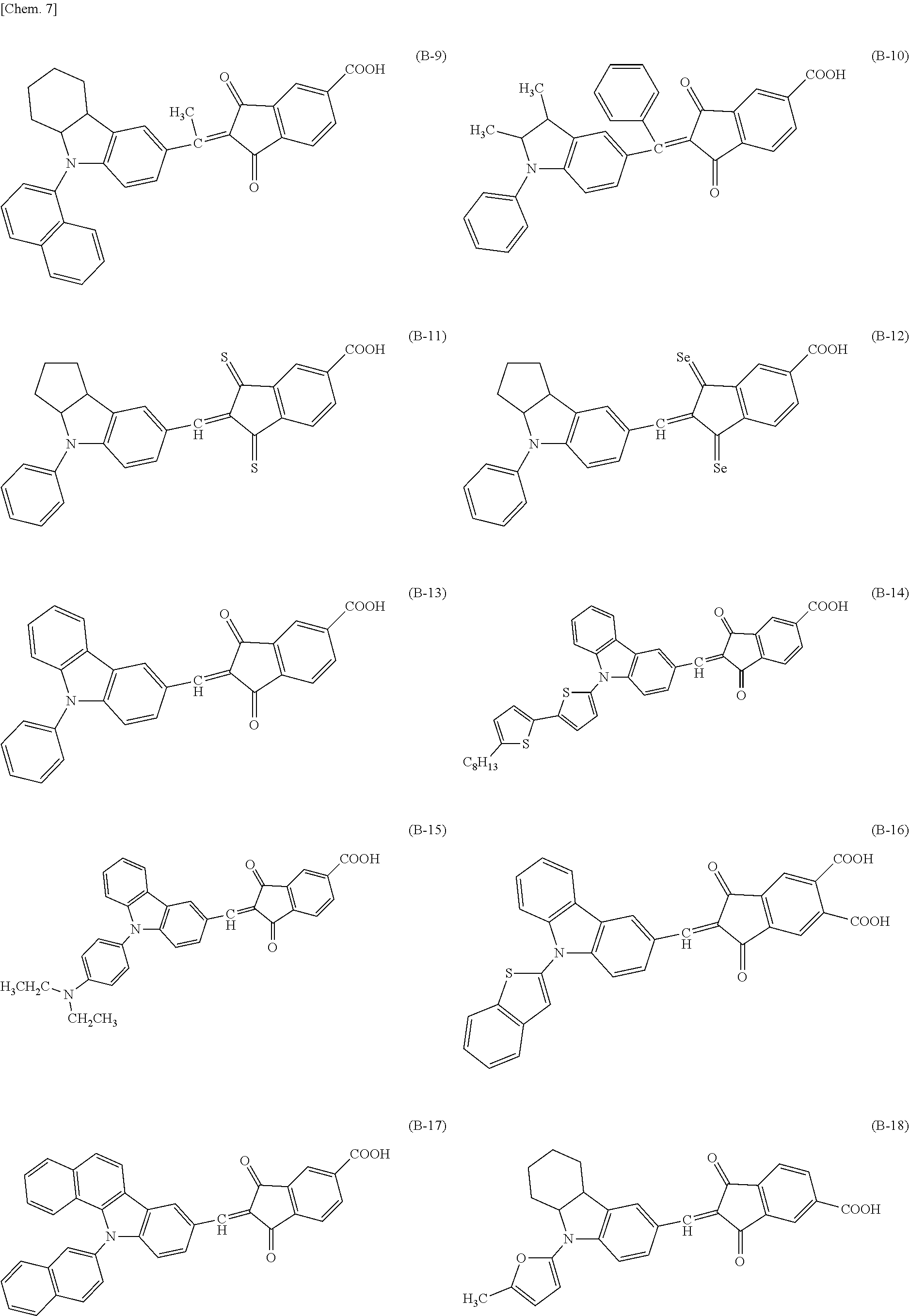

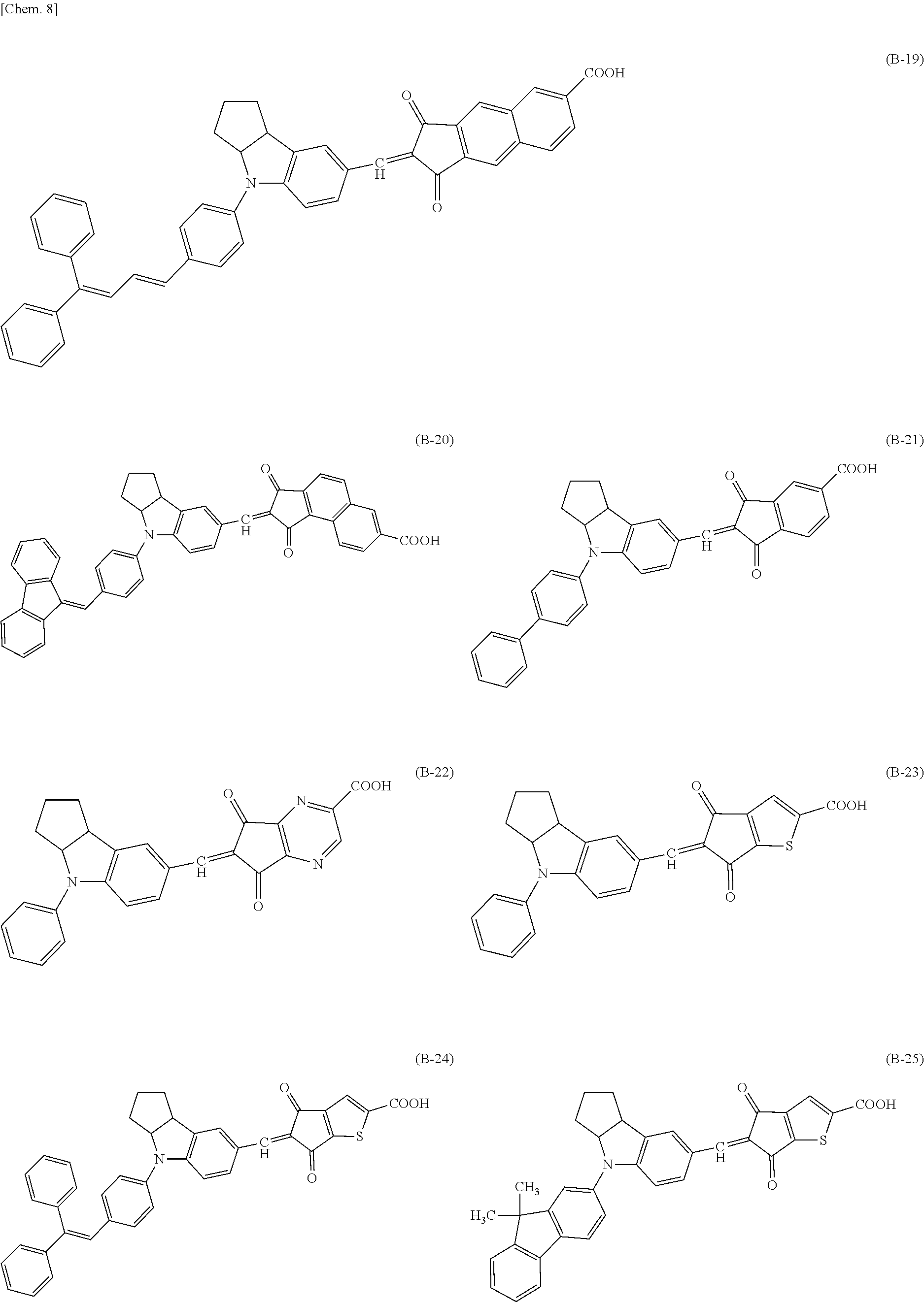

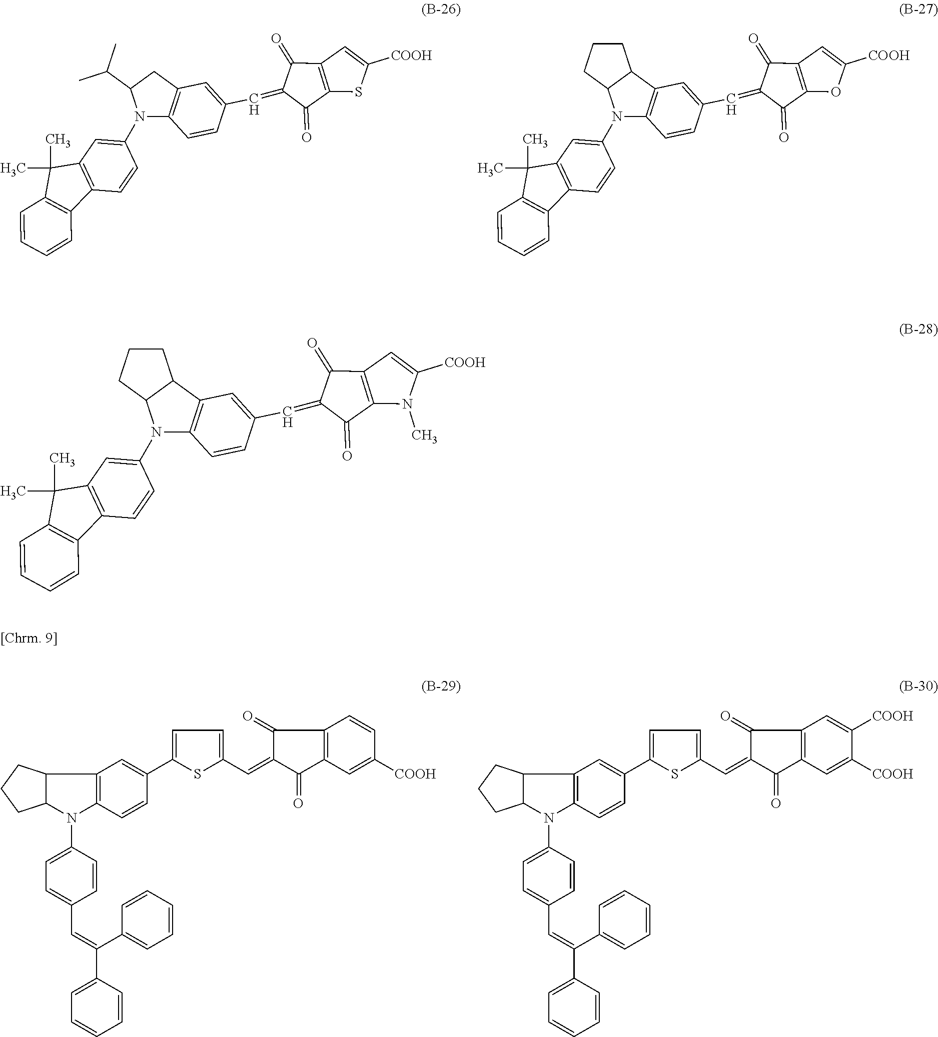

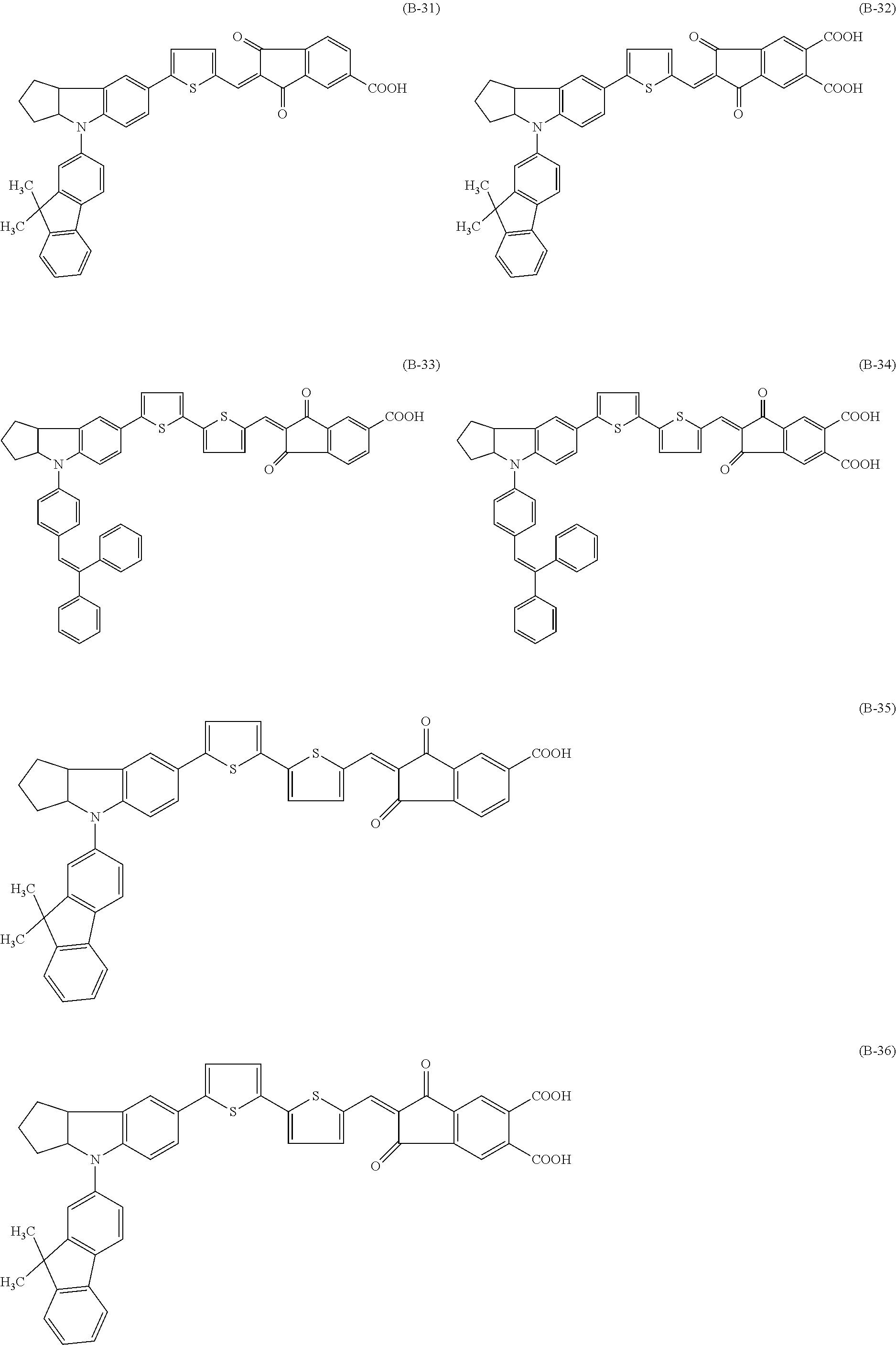

As a method for making the photosensitizing compound adsorbed on a surface of the semiconductor material of the electron-transporting layer, a method where the electron-transporting layer including the semiconductor material is immersed in a solution or dispersion liquid of the photosensitizing compound, or a method where a solution or dispersion liquid of the photosensitizing compound is applied onto the electron-transporting layer to adsorb the photosensitizing compound can be used. In case of the method of immersing the electron-transporting layer to which the semiconductor material is formed in a solution or dispersion liquid of the photosensitizing compound, an immersion method, a dipping method, a roller method, or an air knife method can be used. In case of the method for applying a solution or dispersion liquid of the photosensitizing compound to the electron-transporting layer to make the photosensitizing compound adsorbed on the electron-transporting layer, wire bar coating, slide hopper coating, extrusion coating, curtain coating, spin coating, or spray coating can be used. Moreover, it is also possible to adsorb the photosensitizing compound on the electron-transporting layer in a supercritical fluid using carbon dioxide etc.

When the photosensitizing compound is adsorbed on the semiconductor material, a condensing agent may be used in combination.

The condensing agent may be an agent that exhibits a catalytic function to physical or chemical bind a photosensitizing compound to a surface of a semiconductor material, or an agent that exhibits a stoichiometric function to move a chemical equilibrium advantageously. Moreover, thiol or a hydroxyl compound may be added as a condensation auxiliary.

Examples of the solvent in which the photosensitizing compound is dissolved or dispersed include water, an alcohol solvent, a ketone solvent, an ester solvent, an ether solvent, an amide solvent, a halogenated hydrocarbon solvent, and a hydrocarbon solvent.

Examples of the alcohol solvent include methanol, ethanol, and isopropyl alcohol.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diethyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed examples may be used alone or in combination.

Since there is a photosensitizing compound that may function more effectively when aggregates between compounds are prevented, depending on a kind of the photosensitizing compound for use, an aggregate dissociating agent may be used in combination.

The aggregate dissociating agent is not particularly limited and may be appropriately selected depending on a dye for use. The aggregate dissociating agent is preferable a steroid compound (e.g., cholic acid and chenodexycholic acid), long-chain alkyl carboxylic acid, or long-chain alkyl phosphonic acid.

An amount of the aggregate dissociating agent is preferably 0.01 parts by mass or greater but 500 parts by mass or less, and more preferably 0.1 parts by mass or greater but 100 parts by mass or less, relative to 1 part by mass of the photosensitizing compound.

A temperature at the time when the photosensitizing compound alone or a combination of the photosensitizing compound and the aggregate dissociating agent are adsorbed on a surface of the semiconductor material constituting the electron-transporting layer is preferably −50 degrees Celsius or higher but 200 degrees Celsius or lower. The adsorption duration is preferably 5 seconds or longer but 1,000 hours or shorter, more preferably 10 seconds or longer but 500 hours or shorter, and even more preferably 1 minute or longer but 150 hours or shorter. The process of adsorption is preferably performed in the dark. Moreover, the process of adsorption may be performed with still standing or with stirring.

A method for stirring is not particularly limited and may be appropriately selected depending on the intended purpose. Examples of the method include methods using a stirrer, a ball mill, a paint conditioner, a sand mill, Attritor, a disperser, and ultrasonic disperser.

<Hole-Transporting Layer>

The photoelectric conversion element includes a hole-transporting layer.

The hole-transporting layer preferably includes a p-type semiconductor material and a basic compound.

The hole-transporting layer includes the p-type semiconductor material.

Ionization potential of the hole-transporting layer is greater than ionization potential of the p-type semiconductor material and is less than 1.07 times the ionization potential of the p-type semiconductor material. When the ionization potential of the hole-transporting layer is greater than the ionization potential of the p-type semiconductor material and is less than 1.07 times of the ionization potential of the p-type semiconductor material, both high photoelectric conversion performance with low illumination light and stability over time can be obtained at the same time.

<<P-Type Semiconductor Material>>

The p-type semiconductor material is not particularly limited and may be appropriately selected depending on the intended purpose. Examples of the p-type semiconductor material include an inorganic p-type semiconductor material and an organic p-type semiconductor material.

The inorganic p-type semiconductor material is not particularly limited and may be appropriately selected depending on the intended purpose. Examples of the inorganic p-type semiconductor material include CuSCN, CuI, CuBr, NiO, V₂O₅, and graphene oxide.

Among the above-listed examples, the organic p-type semiconductor material is preferable.

The organic p-type semiconductor material is not particularly limited and may be appropriately selected depending on the intended purpose. For example, organic p-type semiconductor materials known in the art can be used.

Examples of the organic p-type semiconductor materials known in the art include an oxadiazole compound, a triphenylmethane compound, a pyrazoline compound, a hydrazone compound, a tetraaryl benzidine compound, a stilbene compound, and a spiro compound. The above-listed examples may be used alone or in combination. Among the above-listed examples, a spiro compound is preferable.

Examples of the spiro compound include a compound represented by General Formula (4) below.

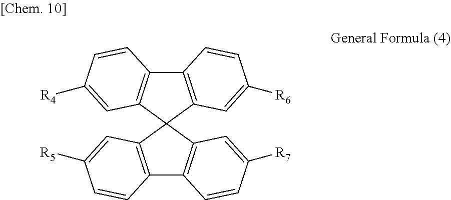

In General Formula (4), R₄ to R₇ are each a substituted amino group, such as a dimethylamino group, a diphenylamino group, and a naphthyl-4-tolylamino group.

The spiro compound is not particularly limited and may be appropriately selected depending on the intended purpose. Examples of the spiro compound include Exemplary Compounds D-1 to D-20 below, but the spiro compound for use is not limited to Exemplary Compounds D-1 to D-20. The above-mentioned examples may be used alone or in combination.

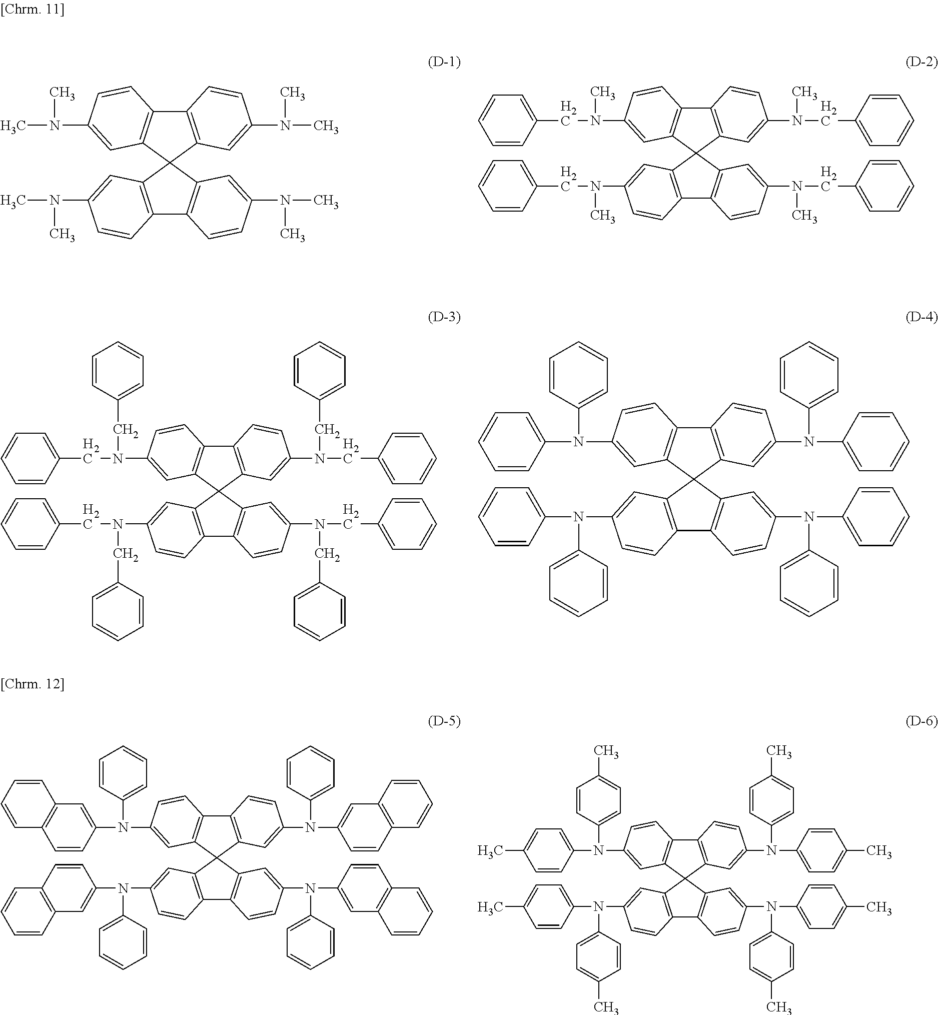

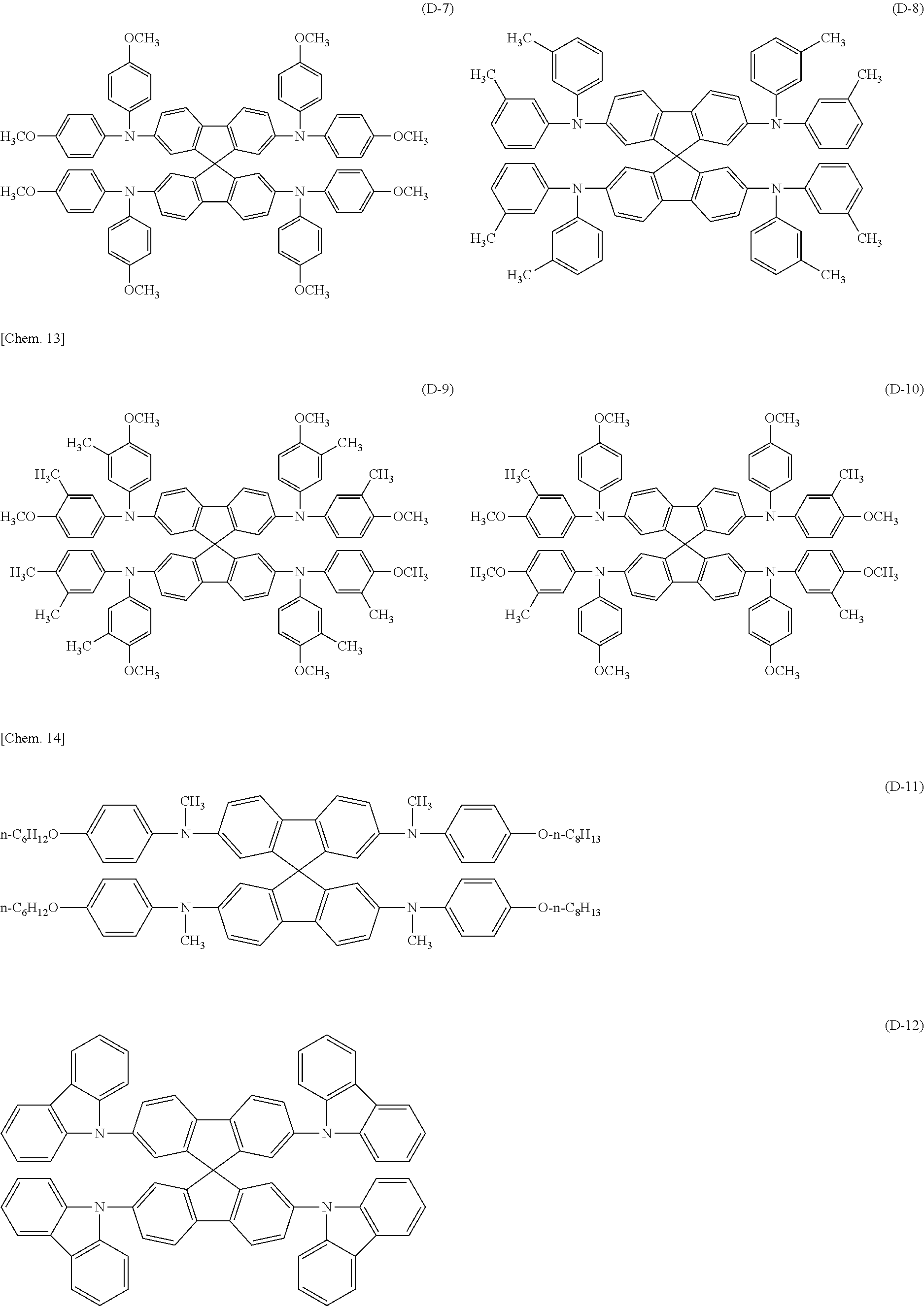

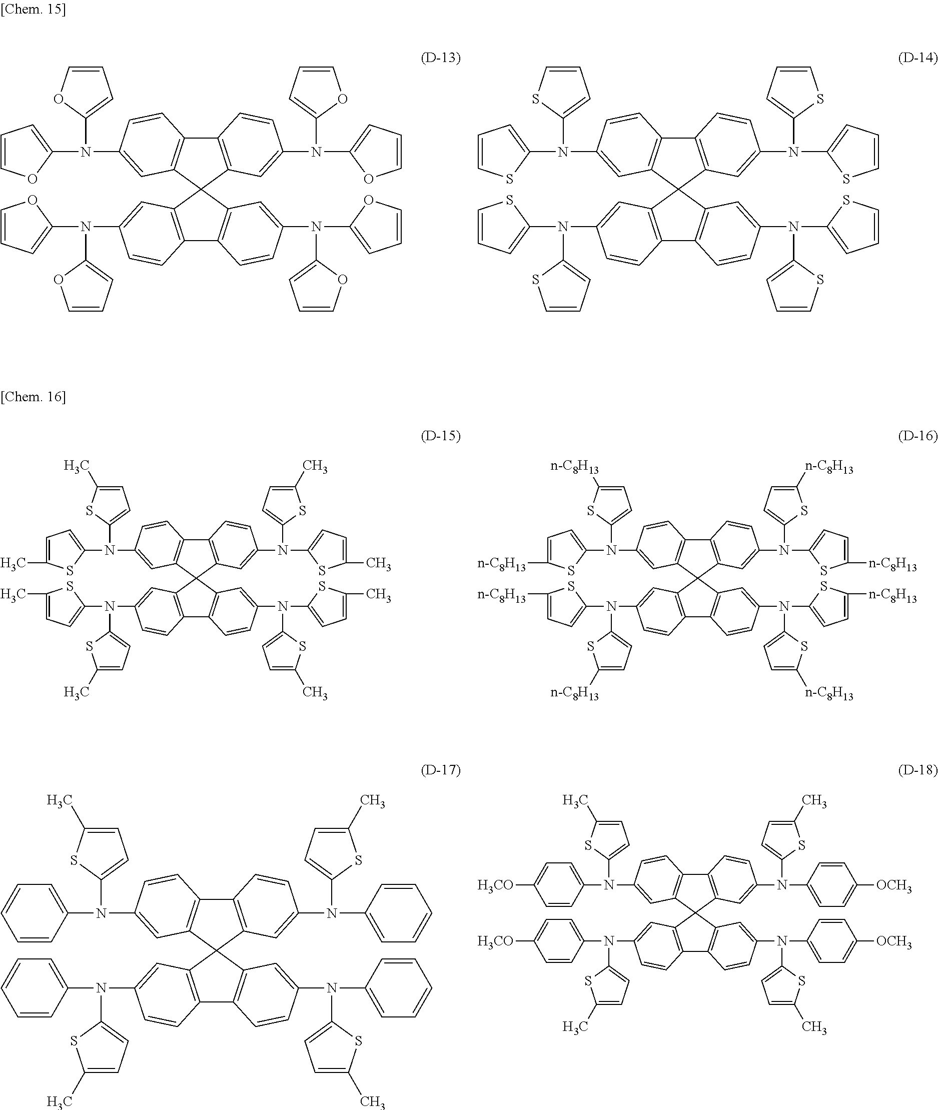

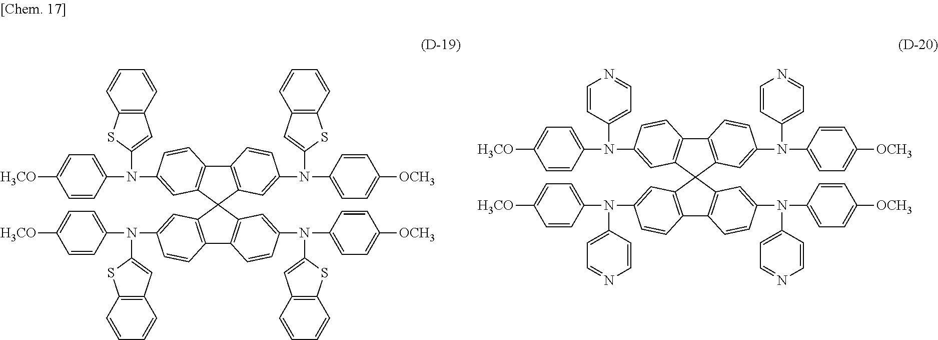 [SMILES: COc1ccc(N(c2ccc3c(c2)C2(c4cc(N(c5ccc(OC)cc5)c5cc6ccccc6s5)ccc4-3)c3cc(N(c4ccc(OC)cc4)c4cc5ccccc5s4)ccc3-c3ccc(N(c4ccc(OC)cc4)c4cc5ccccc5s4)cc32)c2cc3ccccc3s2)cc1 ; COc1ccc(N(c2ccncc2)c2ccc3c(c2)C2(c4cc(N(c5ccncc5)c5ccc(OC)cc5)ccc4-3)c3cc(N(c4ccncc4)c4ccc(OC)cc4)ccc3-c3ccc(N(c4ccncc4)c4ccc(OC)cc4)cc32)cc1]

Since two benzidine skeletons are spirally bonded within the spiro compound, an electron cloud a shape of which is close to a sphere is formed, hopping conductivity between molecules thereof is excellent, and therefore the spiro compounds have excellent photoelectric conversion performance. Since the spiro compounds are amorphous (irregular-shaped compounds that do not have a crystal structure), the spiro compounds tend to be densely filled in a porous electron-transporting layer. Since the spiro compounds do not absorb light of 450 nm or longer, furthermore, light absorption of the photosensitizing compound can be effectively performed and therefore the spiro compounds are particularly preferable for a solid dye-sensitized solar cell.

<<Basic Compound>>

The hole-transporting layer includes a basic compound. Moreover, an acid dissociation constant (pKa) of the basic compound is preferably 6 or greater but 10 or less.

It is assumed that the basic compound is present at an interface near the electron-transporting layer to suppress reverse electron transfer (i.e., electron transfer from the electron-transporting layer to the hole-transporting layer) from the electron-transporting layer. Since the hole-transporting layer includes the basic compound has pKa of 6 or greater but 10 or less, moreover, internal resistance of the photoelectric conversion element increases. As a result, loss current of low illuminance light such as room light is reduced and therefore both high photoelectric conversion performance even with low illumination light and stability over time can be obtained at the same time.

The pKa can be calculated, for example, using ACD/Labs Software V11.02.

As the basic compound, a basic compound represented by General Formula (A) or General Formula (B) below is preferable, and a tertiary amine compound represented by General Formula (1) or General Formula (2) below is more preferable. The hole-transporting layer including the basic compound represented by General Formula (A) or General Formula (B) below is advantageous because high open-circuit voltage is obtained and high photoelectric conversion performance is obtained. When the hole-transporting layer including at least one of tertiary amine compounds represented by General Formula (1) and General Formula (2) below, moreover, both high photoelectric conversion performance even with low illumination light and stability over time can be obtained at the same time.

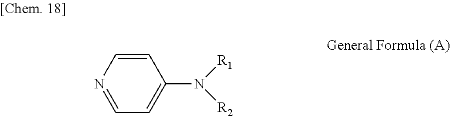

In General Formula (A) above, R₁ and R₂ are each independently an alkyl group or an aromatic hydrocarbon group, where R₁ and R₂ are identical groups or different groups, or are bonded to each other to form a heterocyclic group including a nitrogen.

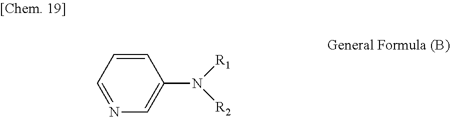

In General Formula (B) above, R₁ and R₂ are each independently an alkyl group or an aromatic hydrocarbon group, where R₁ and R₂ are identical groups or different groups, or are bonded to each other to form a heterocyclic group including a nitrogen.

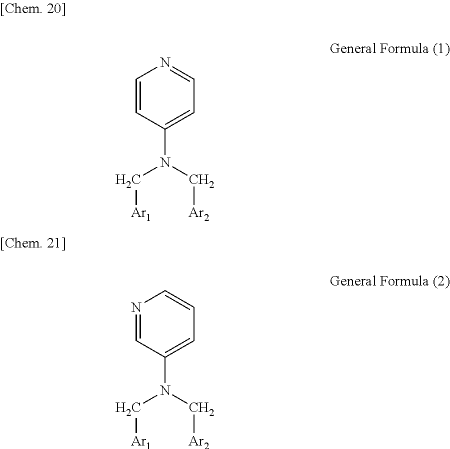

In General Formulae (1) and (2) above, Ar₁ and Ar₂ are each an aryl group that may have a substituent, where Ar₁ and Ar₂ may be identical or different and may be bonded to each other.

Specific exemplary compounds of the basic compounds represented by General Formulae (A) and (B) are listed below but the basic compounds are not limited to the following examples.

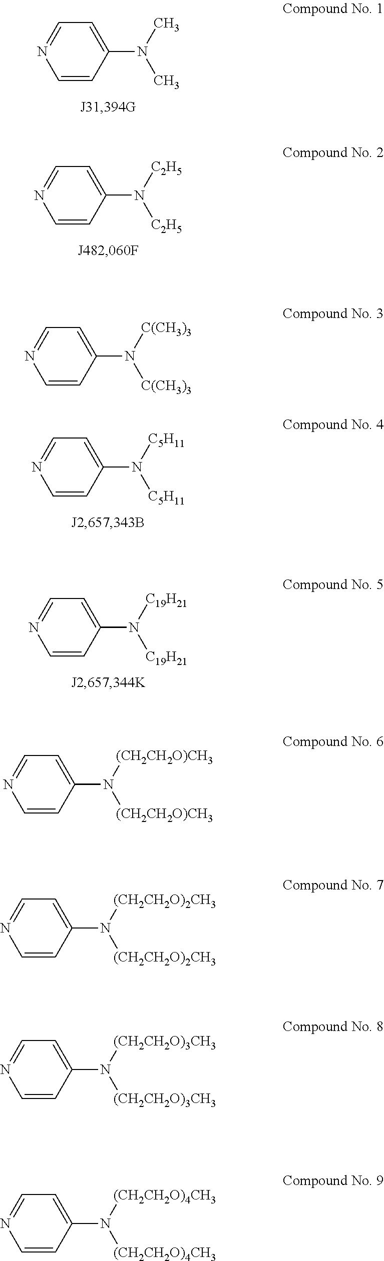

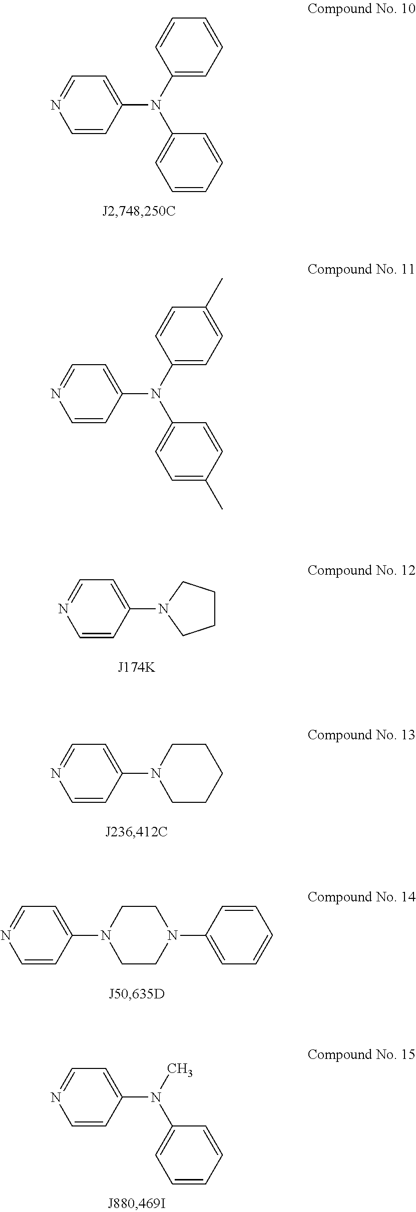

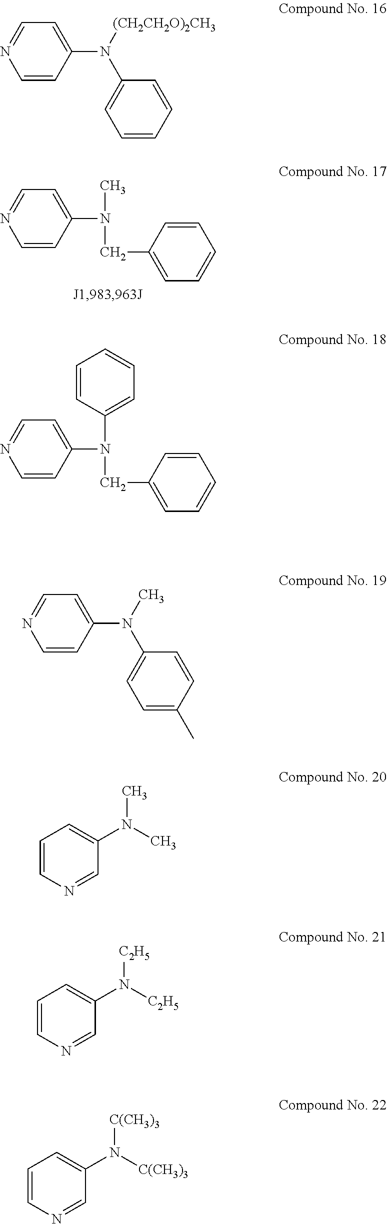

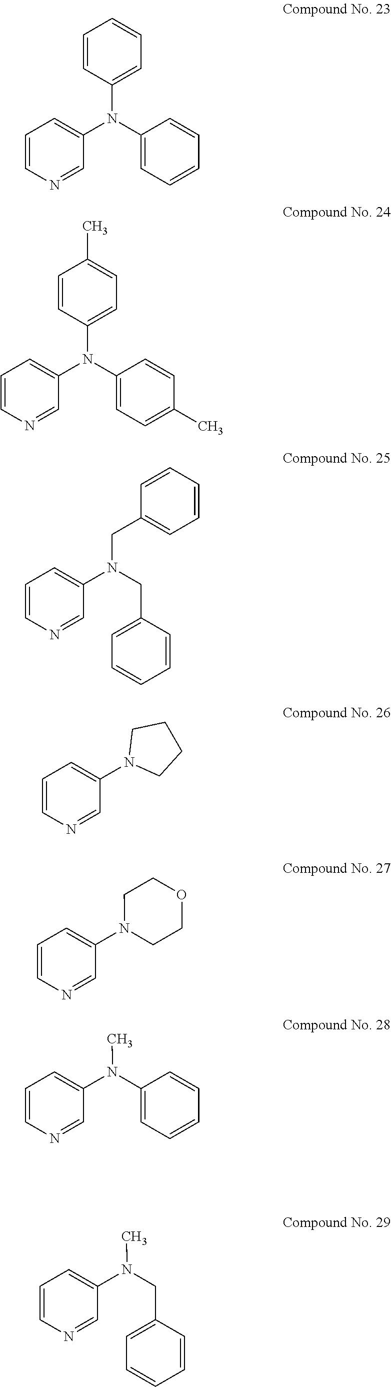

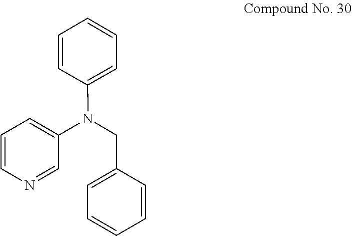

Next, as specific examples of tertiary amine compounds represented by General Formula (1) and General Formula (2), for example, Exemplary Compounds C-1 to C-20 are listed below. However, the tertiary amine compounds represented by General Formula (1) and General Formula (2) are not limited to Exemplary Compounds C-1 to C-20. The listed examples may be used alone or in combination.

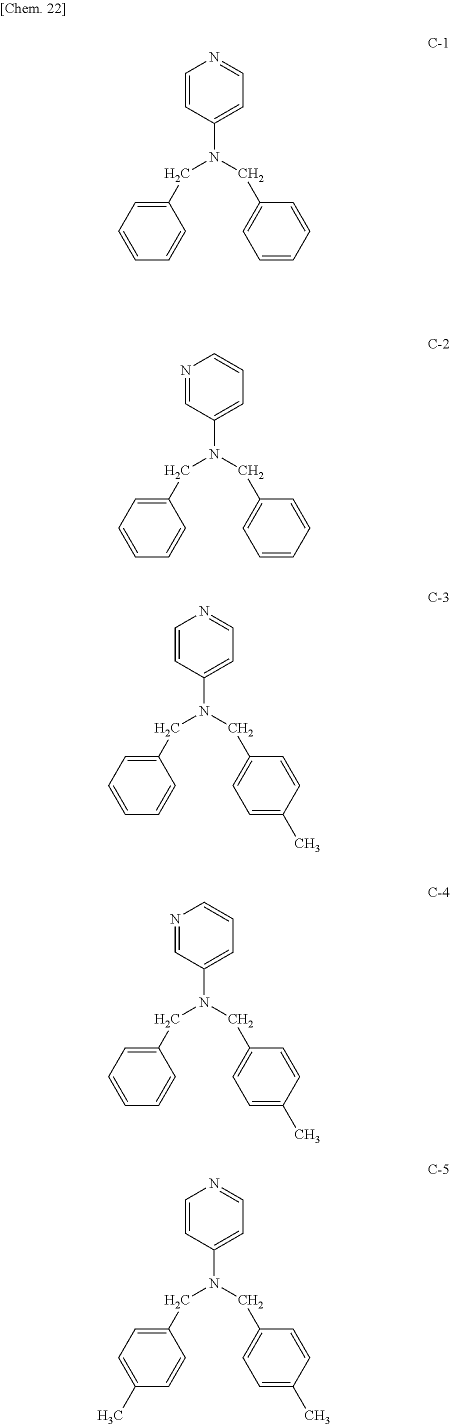

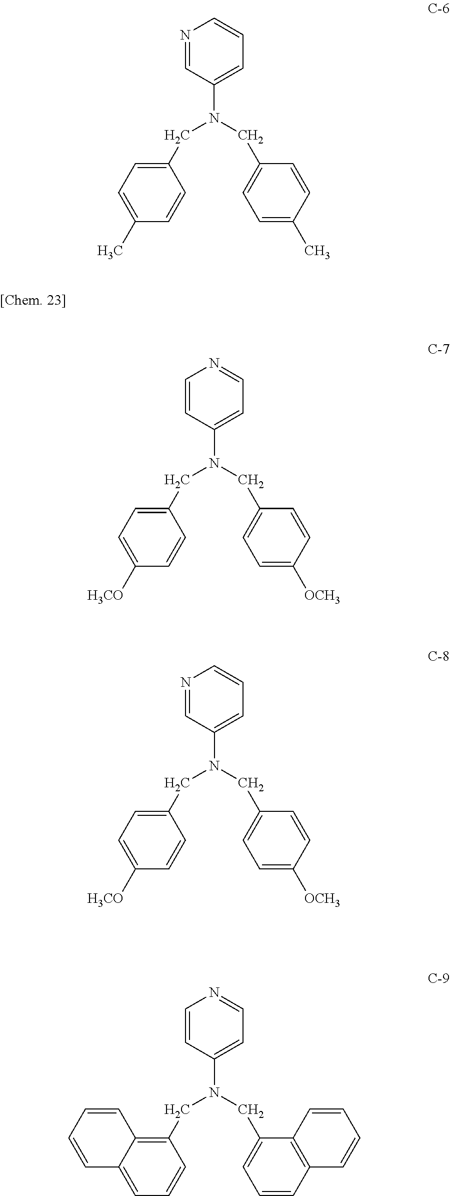

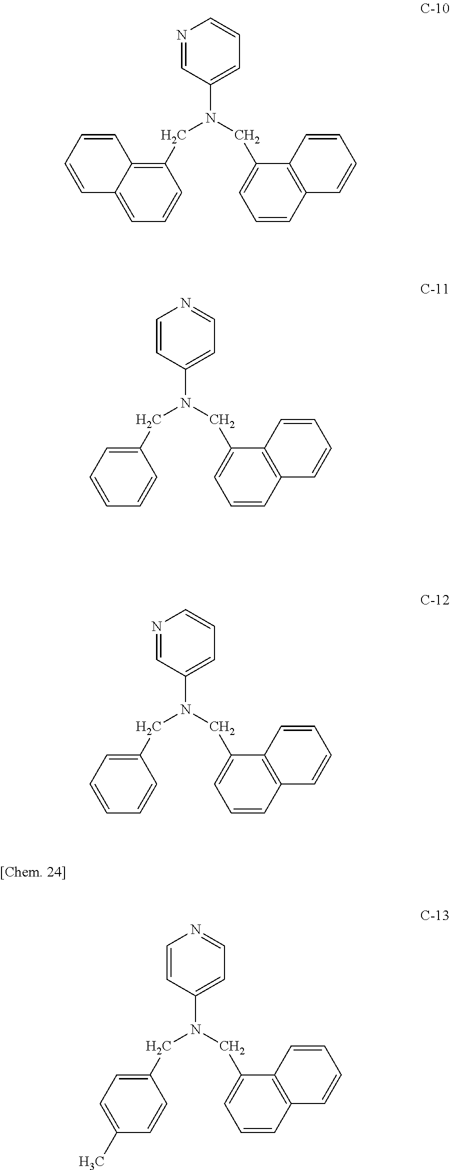

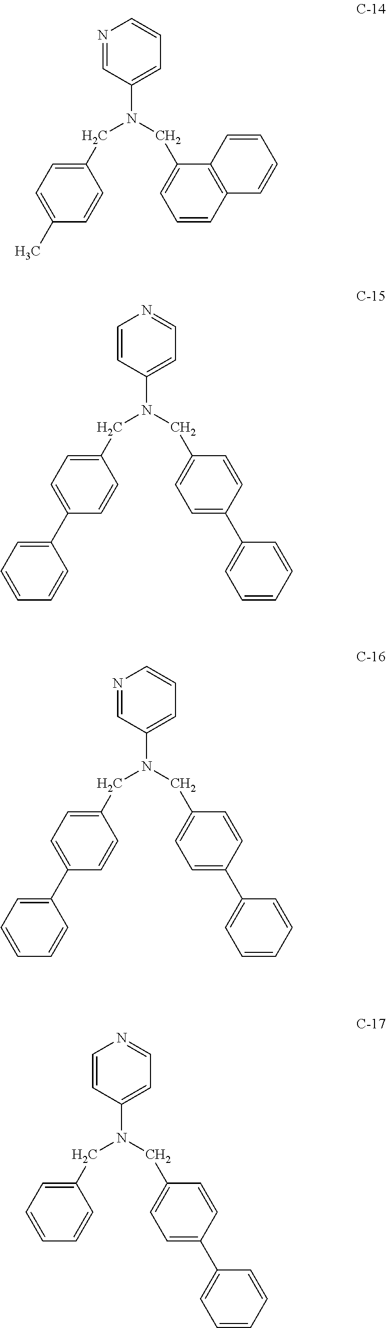

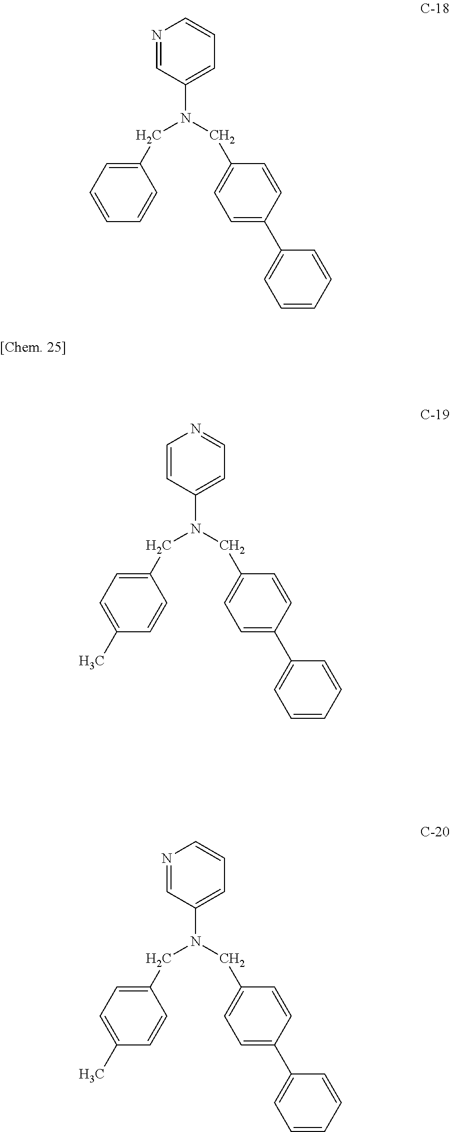

An amount of the basic compound in the hole-transporting layer is preferably 1 part by mass or greater but 50 parts by mass or less, and more preferably 10 parts by mass or greater but 30 parts by mass, relative to a total amount of the hole-transporting material. When the amount of the tertiary amine compound is within the above-mentioned preferable range, high open-circuit voltage can be maintained, high output is obtained, and high stability and durability can be obtained even after use over a long period in various environments.

A molecular weight of the basic compound is preferably 140 g/mol or greater. When the basic compound is 140 g/mol or greater, physical or electrical contact between the electron-transporting layer and the hole-transporting layer can be suppressed owing to the presence of the basic compound at the interface near the electron-transporting layer and therefore reverse electron transfer can be reduced. Therefore, high photoelectric conversion performance can be obtained even with low illumination light.

A state of the hole-transporting layer is not particularly limited and may be appropriately selected depending on the intended purpose, as long as the hole-transporting layer has a function of transferring holes. Examples thereof include an electrolytic solution obtained by dissolving a redox couple in an organic solvent, a gel electrolyte obtained by impregnating a polymer matrix with a liquid obtained by dissolving a redox couple in an organic solvent, a molten salt including a redox couple, and a solid electrolyte. The above-listed examples may be used alone or in combination.

<<Oxidizing Agent>>

The hole-transporting layer preferably includes an oxidizing agent. When the oxidizing agent is included in the hole-transporting layer, part of the organic hole-transporting material becomes radical cations. Therefore, conductivity of the hole-transporting layer improves, and durability and stability of output properties can be enhanced.

Since the organic hole-transporting material is oxidized with the oxidizing agent, release (reduction) of the oxidized state due to influence of the surrounding environment of the photoelectric conversion layer can be suppressed. Therefore, excellent stability is obtained over time.

The oxidizing agent is not particularly limited and may be appropriately selected depending on the intended purpose. Examples of the oxidizing agent include tris(4-bromophenyl)aminium hexachloroantimonate, silver hexafluoroantimonate, ni-trosonium tetrafluoroborate, silver nitrate, and a metal complex. The above-listed examples may be used alone or in combination. Among the above-listed examples, a metal complex is more preferable.

For example, the metal complex is made up of a metal cation, a ligand, and an anion.

The metal cation is not particularly limited and may be appropriately selected depending on the intended purpose. Examples of the metal cation includes cations of chromium, manganese, zinc, iron, cobalt, nickel, copper, molybdenum, ruthenium, rhodium, palladium, silver, tungsten, rhenium, osmium, iridium, vanadium, gold, and platinum. Among them, cations of manganese, zinc, iron, cobalt, nickel, copper, ruthenium, silver, and vanadium are preferable, and a cobalt complex is more preferable.

The ligand is preferably a ligand including a 5- and/or 6-membered heterocycle including at least one nitrogen atom, where the ligand may include a substituent. Specific examples of the ligand are listed below, but the ligand is not limited to the following examples.

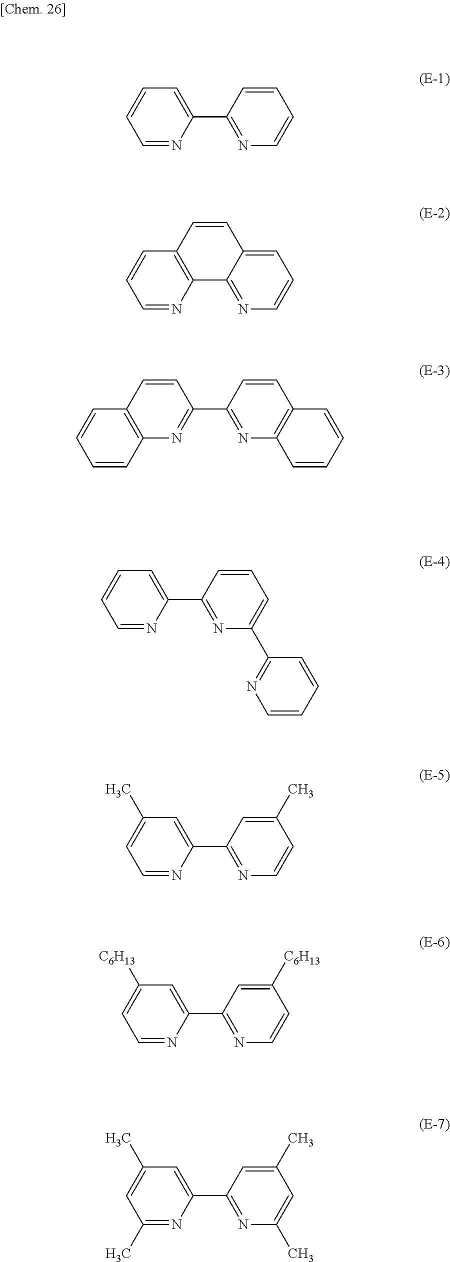

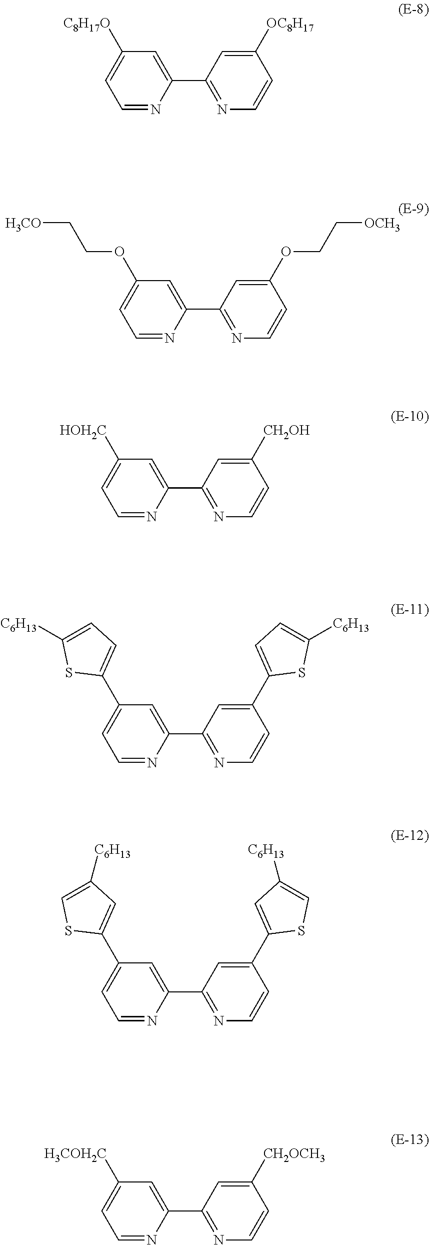

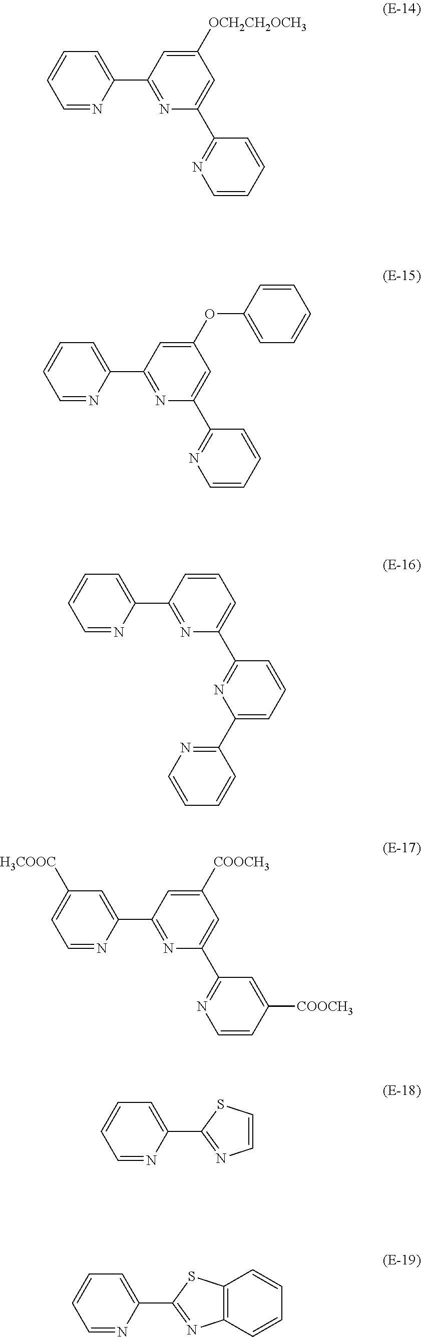

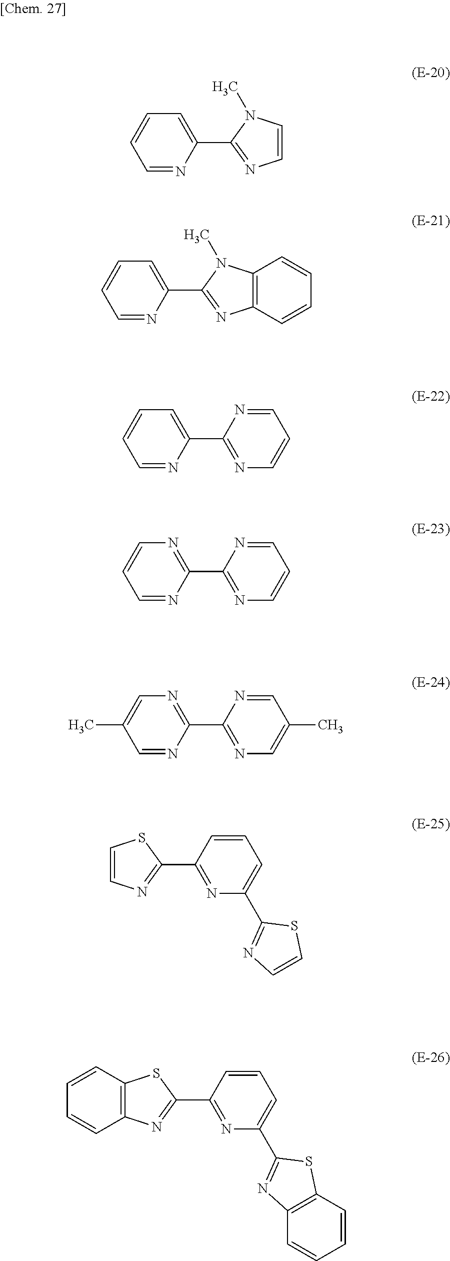

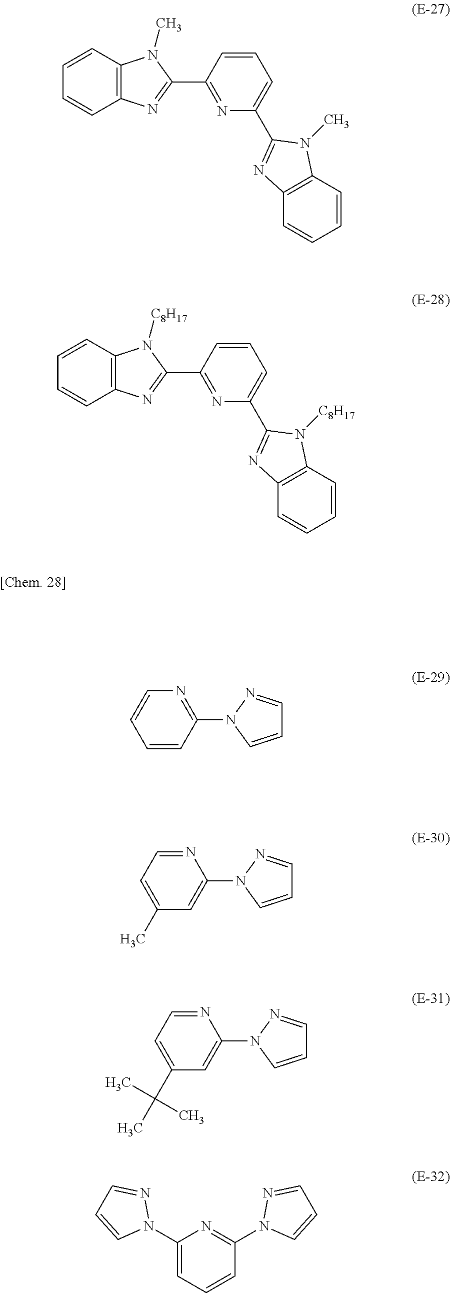

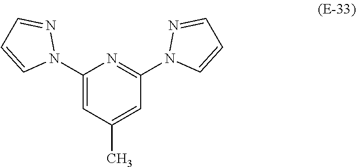 [SMILES: Cc1cc(-n2cccn2)nc(-n2cccn2)c1]

Examples of the anion include a hydride ion (H⁻), a fluoride ion (F⁻), a chloride ion (Cl⁻), a bromide ion (Br⁻), an iodide ion (I⁻), a hydroxide ion (OH⁻), a cyanide ion (CN⁻), a nitric acid ion (NO₃⁻), a nitrous acid ion (NO₂⁻), a hypochlorous acid ion (ClO⁻), a chlorous acid ion (ClO₂⁻), a chloric acid ion (ClO₃⁻), a perchloric acid ion (ClO₄⁻), a per-manganic acid ion (MnO₄⁻), an acetic acid ion (CH₃COO⁻), a hydrogen carbonate ion (HCO₃⁻), a dihydrogen phosphate ion (H₂PO₄⁻), a hydrogen sulfate ion (HSO₄⁻), a hydrogen sulfide ion (HS⁻), a thiocyanic acid ion (SCN⁻), a tetrafluoroboric acid ion (BF₄⁻), a hexafluorophosphate ion (PF₆⁻), a tetracyanoborate ion (B(CN)₄⁻), a di-cyanoamine ion (N(CN)₂⁻), a p-toluenesulfonic acid ion (TsO⁻), a trifluoromethyl sulfonate ion (CF₃SO₂⁻), a bis(trifluoromethylsulfonyl)amine ion (N(SO₂CF₃)²⁻), a tetrahydroxoaluminate ion ([Al(OH)₄]⁻ or [Al(OH)₄(H₂O)₂]⁻), a dicyanoargentate (I) ion ([Ag(CN)₂]⁻), a tetrahydroxochromate (III) ion ([Cr(OH)₄]⁻), a tetrachloroaurate (III) ion ([AuCl₄]⁻), an oxide ion (O²⁻), a sulfide ion (S²⁻), a peroxide ion (O₂²⁻), a sulfuric acid ion (SO₄²⁻), a sulfurous acid ion (SO₃²⁻), a thiosulfuric acid (S₂O₃²⁻), a carbonic acid ion (CO₃²⁻), a chromic acid ion (CrO₄²⁻), a dichromic acid ion (Cr₂O₇²⁻), a mono-hydrogen phosphate ion (HPO₄²⁻), a tetrahydroxozincate (II) ion ([Zn(OH)₄]²⁻), a tetra-cyanozincate (II) ion ([Zn(CN)₄]²⁻), a tetrachlorocuprate (II) ion ([CuCl₄]²⁻), a phosphoric acid ion (PO₄³⁻), a hexacyanoferrate (III) ion ([Fe(CN)₆]³⁻), a bis(thiosulfate)argentat (I) ion ([Ag(S₂O₃)₂]³⁻), and a hexacyanoferrate (II) ion ([Fe(CN)₆]⁴⁻). Among the above-listed examples, a tetrafluoroboric acid ion, a hexafluorophosphate ion, a tetracyanoborate ion, a bis(trifluoromethylsulfonyl)amine ion, and a perchloric acid ion are preferable.

The metal complex is particularly preferably a trivalent cobalt complex represented by General Formula (5) below. Use of the trivalent cobalt complex as the metal complex is advantageous because the trivalent cobalt complex has an excellent function as an oxidizing agent.

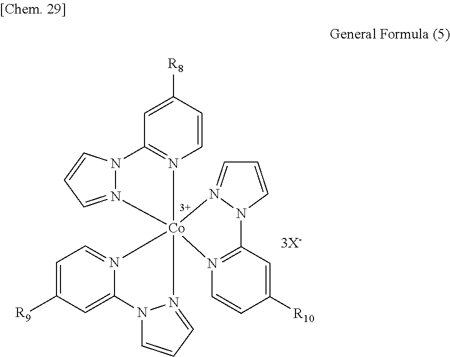

In General Formula (5) above, R₈ to R₁₀ are each a hydrogen atom, a methyl group, an ethyl group, a tertiary butyl group, or a trifluoromethyl group; and X is an anion selected from the above-listed anions.

Specific examples of the cobalt complex represented by General Formula (5) above are listed below, but the cobalt complex represented by General Formula (5) is not limited to these examples. The below-listed examples may be used alone or in combination.

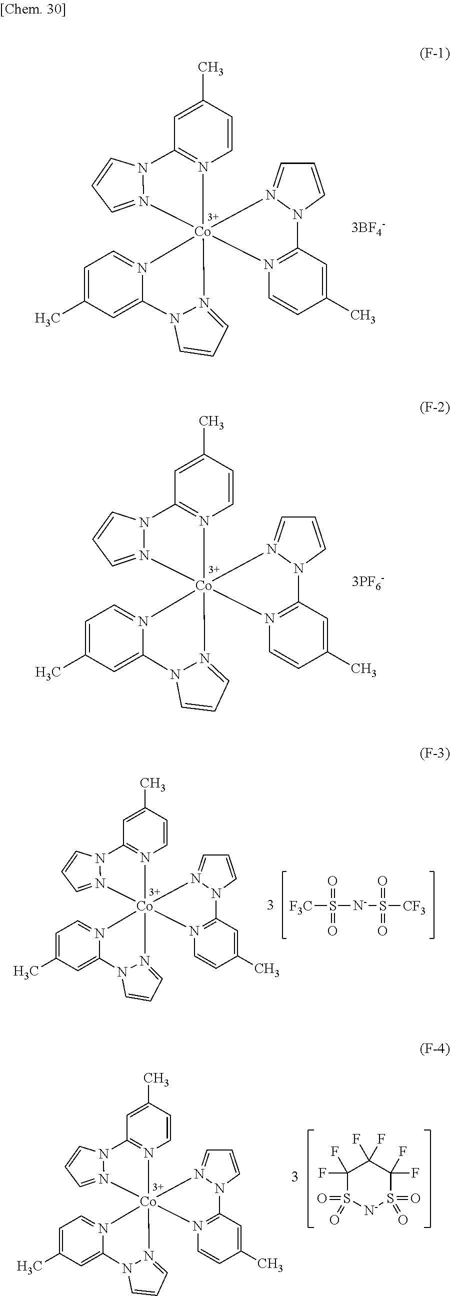

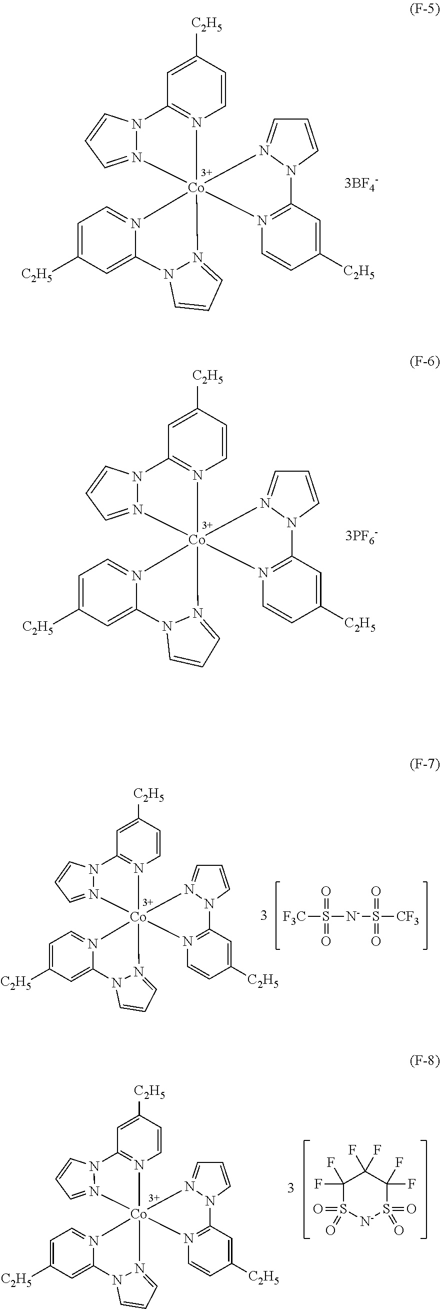

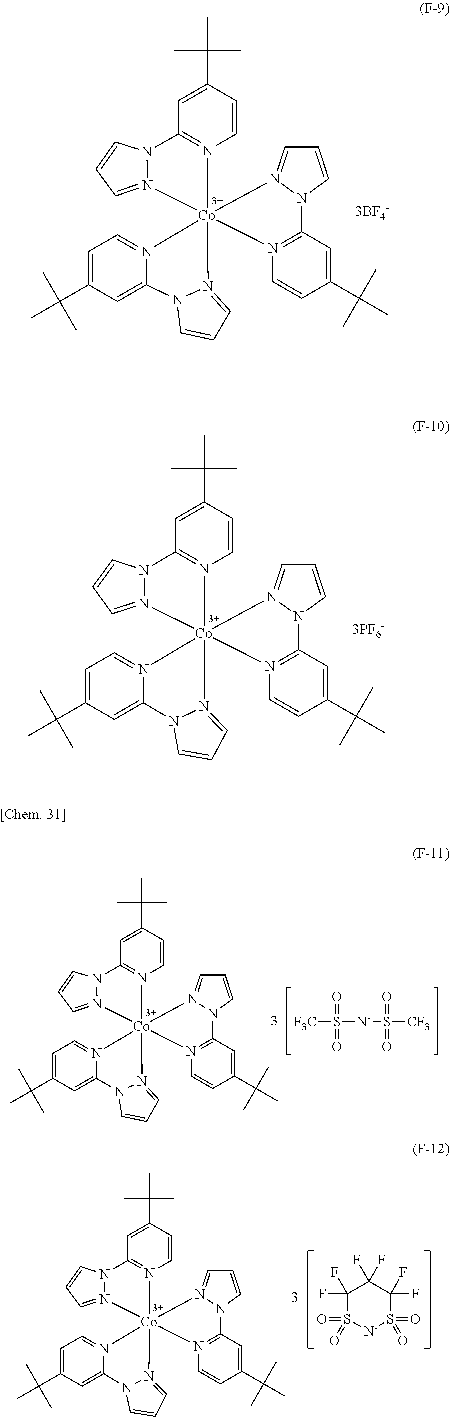

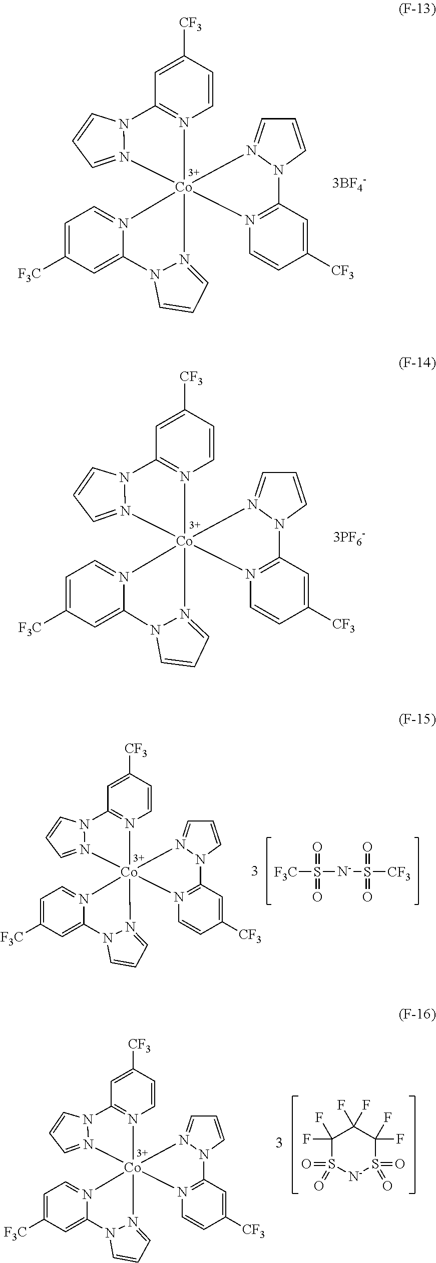

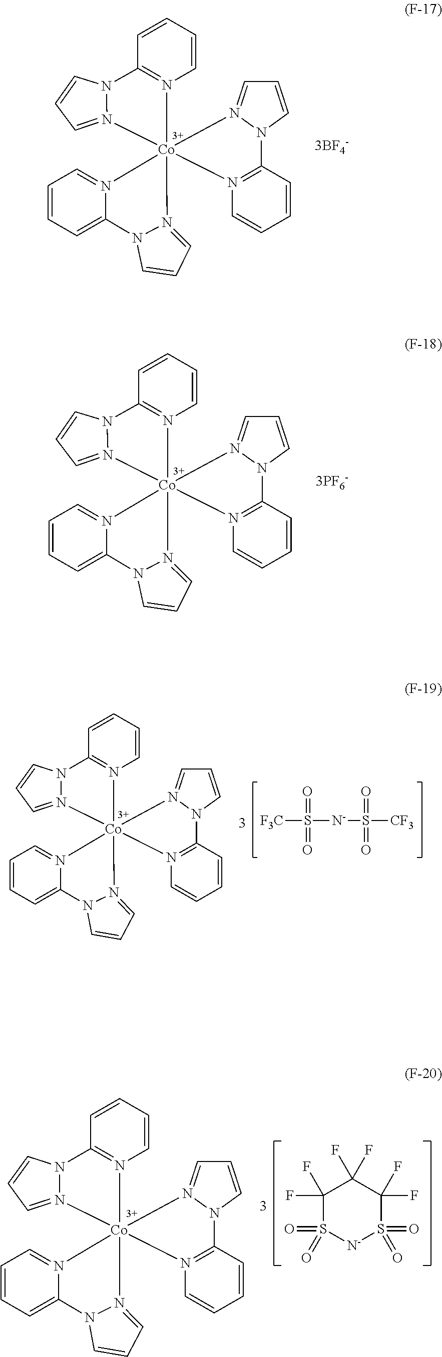

As the metal complex, moreover, a trivalent cobalt complex represented by General Formula (6) below is also effectively used.

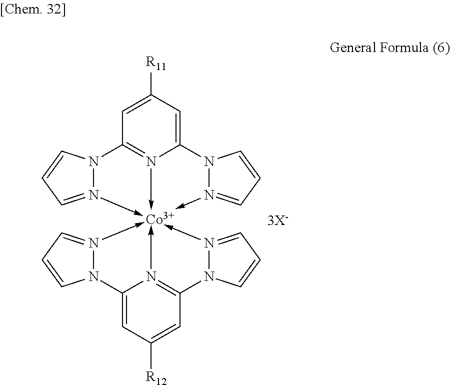

In General Formula (6) above, R₁₁ to R₁₂ are each a hydrogen atom, a methyl group, an ethyl group, a tertiary butyl group, or a trifluoromethyl group; and X is an anion selected from the above-listed anions.

Specific examples of the cobalt complex represented by General Formula (6) above are listed below. However, the cobalt complex represented by General Formula (6) is not limited to these examples. The below-listed examples may be used alone or in combination.

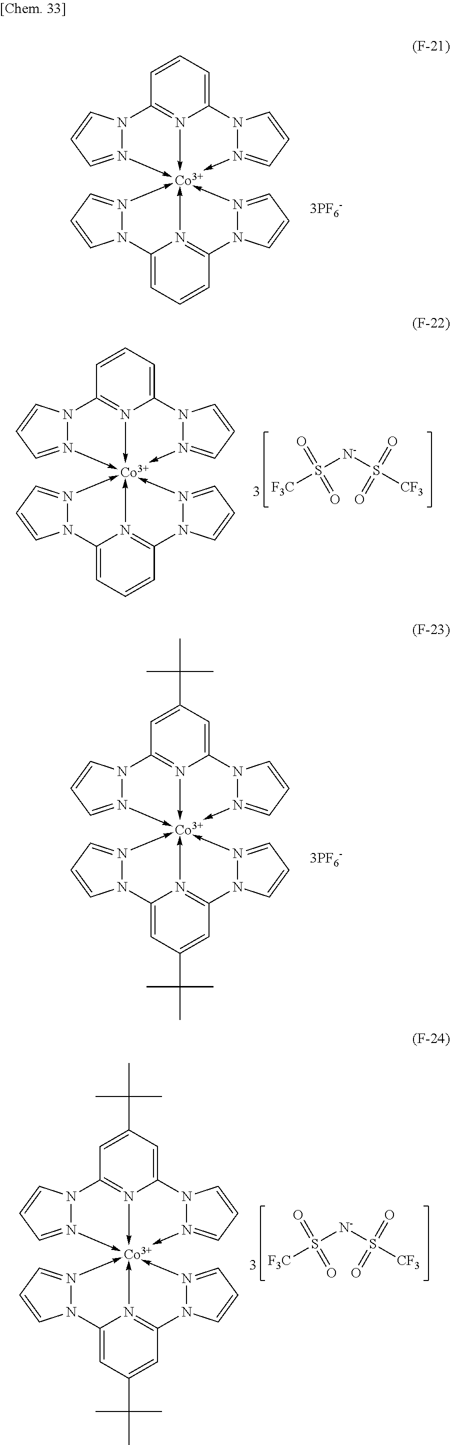

An amount of the oxidizing agent is preferably 0.5 parts by mass or greater but 50 parts by mass or less, and more preferably 5 parts by mass or greater but 30 parts by mass or less relative to 100 parts by mass of the hole-transporting material. It is not necessary to oxidize the entire hole-transporting material through the addition of the oxidizing agent and the addition thereof is effective as long as at least part of the hole-transporting material is oxidized.

<<Alkali Metal Salt>>

The hole-transporting layer preferably includes an alkali metal salt as additive. Use of the alkali metal salt in the hole-transporting layer is advantageous because charges smoothly move and excellent photoelectric conversion performance can be obtained.

It is assumed that cations of the alkali metal salt are present at an interface near the electron-transporting layer, and the hole-transporting layer is doped with anions of the alkali metal salt.

Examples of the alkali metal salt include: lithium salts, such as lithium chloride, lithium bromide, lithium iodide, lithium perchlorate, lithium bis(trifluoromethanesulfonyl)diimide, lithium diisopropyl imide, lithium acetate, lithium tetrafluoroborate, lithium pentafluorophosphate, and lithium tetracyanoborate; sodium salts, such as sodium chloride, sodium bromide, sodium iodide, sodium perchlorate, sodium bis(trifluoromethanesulfonyl)diimide, sodium acetate, sodium tetrafluoroborate, sodium pentafluorophosphate, and sodium tetracyanoborate; and potassium salts, such as potassium chloride, potassium bromide, potassium iodide, and potassium perchlorate. Among the above-listed examples, lithium bis(trifluoromethanesulfonyl)diimide and lithium diisopropyl imide are preferable.

An amount of the alkali metal salt is preferably 1 part by mass or greater but 50 parts by mass or less, and more preferably 5 parts by mass or greater but 30 parts by mass or less, relative to 100 parts by mass of the hole-transporting material.

The hole-transporting layer may have a single layer structure formed of a single material, or a laminate structure including a plurality of compounds. In the case where the hole-transporting layer has a laminate structure, a polymer material is preferably used for a layer of the hole-transporting layer disposed near the second electrode. Use of the polymer material having excellent film formability is advantageous because a surface of the porous electron-transporting layer can be made smoother and photoelectric conversion properties can be improved. Since the polymer material does not easily permeate the porous electron-transporting layer, moreover, a surface of the porous electron-transporting layer is desirably covered and an effect of preventing short circuits at the time when an electrode is disposed may be obtained.

Examples of the polymer material for use in the hole-transporting layer include hole transport polymer materials known in the art.

Examples of the hole transport polymer material include a polythiophene compound, a polyphenylene vinylene compound, a polyfluorene compound, a polyfluorene compound, a polyphenylene compound, a polyaryl amine compound, and a polythiadiazole compound.

Examples of the polythiophene compound include poly(3-n-hexylthiophene), poly(3-n-octyloxythiophene), poly(9,9′-dioctyl-fluorene-co-bithiophene), poly(3,3″-didodecyl-quaterthiophene), poly(3,6-dioctylthieno[3,2-b]thiophene), poly(2,5-bis(3-decylthiophen-2-yl)thieno[3,2-b]thiophene), poly(3,4-didecylthiophene-co-thieno[3,2-b]thiophene), poly(3,6-dioctylthieno[3,2-b]thiophene-co-thieno[3,2-b]thiophene), poly(3,6-dioctylthieno[3,2-b]thiophene-co-thiophene), and poly(3,6-dioctylthieno[3,2-b]thiophene-co-bithiophene).

Examples of the polyphenylene vinylene compound include poly[2-methoxy-5-(2-ethylhexyloxy)-1,4-phenylenevinylene], poly[2-methoxy-5-(3,7-dimethyloctyloxy)-1,4-phenylenevinylene], and poly[(2-methoxy-5-(2-ethylhexyloxy)-1,4-phenylenevinylene)-co-(4,4′-biphenylene-vi nylene)].

Examples of the polyfluorene compound include poly(9,9′-didodecylfluorenyl-2,7-diyl), poly[(9,9-dioctyl-2,7-divinylenefluorene)-alt-co-(9,10-anthracene)], poly[(9,9-dioctyl-2,7-divinylenefluorene)-alt-co-(4,4′-biphenylene)], poly[(9,9-dioctyl-2,7-divinylenefluorene)-alt-co-(2-methoxy-5-(2-ethylhexyloxy)-1,4-phenylene)], and poly[(9,9-dioctyl-2,7-diyl)-co-(1,4-(2,5-dihexyloxy)benzene)]. Examples of the polyphenylene compound include poly[2,5-dioctyloxy-1,4-phenylene] and poly[2,5-di(2-ethylhexyloxy-1,4-phenylene].

Examples of the polyaryl amine compound include poly[(9,9-dioctylfluorenyl-2,7-diyl)-alt-co-(N,N′-diphenyl)-N,N′-di(p-hexylphenyl)-1,4-diaminobenzene], poly[(9,9-dioctylfluorenyl-2,7-diyl)-alt-co-(N,N′-bis(4-octyloxyphenyl)benzidine-N,N′-(1,4-diphenylene)], poly[(N,N′-bis(4-octyloxyphenyl)benzidine-N,N′-(1,4-diphenylene)], poly[(N,N′-bis(4-(2-ethylhexyloxy)phenyl)benzidine-N,N′-(1,4-diphenylene)-1, poly[phenylimino-1,4-phenylenevinylene-2,5-dioctyloxy-1,4-phenylenevinylene-1,4-p henylene], poly[p-tolyimino-1,4-phenylenevinylene-2,5-di(2-ethylhexyloxy)-1,4-phenylenevinylene-1,4-phenylene], and poly[4-(2-ethylhexyloxy)phenylimino-1,4-biphenylene].

Examples of the polythiadiazole compound include poly[(9,9-dioctylfluorenyl-2,7-diyl)-alt-co-(1,4-benzo(2,1′, 3)thiadiazole], and poly(3,4-didecylthiophene-co-(1,4-benzo(2,1′,3)thiadiazole).

Among the above-listed examples, a polythiophene compound and a polyaryl amine compound are preferable in view of carrier mobility and ionization potential.

Various additives may be added to the hole-transporting material.

Examples of the additive include: iodine and metal iodide, such as lithium iodide, sodium iodide, potassium iodide, cesium iodide, calcium iodide, copper iodide, iron iodide, and silver iodide; quaternary ammonium salt, such as tetraalkyl ammonium iodide and pyridinium iodide; metal bromide, such as lithium bromide, sodium bromide, potassium bromide, cesium bromide, and calcium bromide; bromine salt of a quaternary ammonium salt, such as tetraalkyl ammonium bromide and pyridinium bromide; metal chloride, such as copper chloride and silver chloride; metal acetate, such as copper acetate, silver acetate, and palladium acetate; metal sulfate, such as copper sulfate and zinc sulfate; metal complex, such as ferrocyanide-ferricyanide, ferrocene-ferricinium ion; sulfur compounds, such as sodium polysulfide and alkyl thiol-alkyl disulfide; viologen dyes and hydroquinone; ionic liquids disclosed in Inorg. Chem. 35 (1996) 1168, such as 1,2-dimethyl-3-n-propylimidazolium iodide, 1-methyl-3-n-hexylimidazolium iodide, 1,2-dimethyl-3-ethylimidazolium trifluo-romethanesulfonate, 1-methyl-3-butylimidazolium nonafluorobutylsulfonate, and 1-methyl-3-ethylimidazolium bis(trifluoromethyl)sulfonylimide; basic compounds, such as pyridine, 4-t-butylpyridine, and benzoimidazole, and derivatives thereof; and alkali metal salts.

An average thickness of the hole-transporting layer is not particularly limited and may be appropriately selected depending on the intended purpose. The hole-transporting layer preferably has a structure where the hole-transporting layer penetrates pores of the porous electron-transporting layer. The average thickness of the hole-transporting layer on the electron-transporting layer is preferably 0.01 micrometers or greater but 20 micrometers or less, more preferably 0.1 micrometers or greater but 10 micrometers or less, and even more preferably 0.2 micrometers or greater but 2 micrometers or less.

The hole-transporting layer can be directly formed on the electron-transporting layer to which the photosensitizing compound is adsorbed. A production method of the hole-transporting layer is not particularly limited and may be appropriately selected depending on the intended purpose. Examples of the production method thereof include a method where a thin film is formed in vacuum, such as vapor deposition, and a wet film forming method. Among the above-listed examples, a wet film forming method is particularly preferable in view of a production cost. A method where the hole-transporting layer is applied onto the electron-transporting layer is preferable.

In case of the wet film forming method, a coating method is not particularly limited and is performed according to any of methods known in the art. Examples of the coating method include dip coating, spray coating, wire bar coating, spin coating, roller coating, blade coating, gravure coating, and die coating. As a wet printing method, various methods, such as relief printing, offset printing, gravure printing, intaglio printing, rubber plate printing, and screen printing, can be used.

Moreover, a film may be formed in a supercritical fluid or subcritical fluid having the lower temperature and pressure than critical points. The supercritical fluid is not particularly limited and may be appropriately selected depending on the intended purpose, as long as the supercritical fluid is a fluid that exists as a non-condensable high-pressure fluid in the temperature and pressure region exceeding the limits (critical points) where a gas and a liquid can coexist and is not condensed as being compressed, and is a fluid in the state equal to or higher the critical temperature and equal to or higher than the critical pressure. The supercritical fluid is preferably a supercritical fluid having a low critical temperature.

Examples of the supercritical fluid include carbon monoxide, carbon dioxide, ammonia, nitrogen, water, an alcohol solvent, a hydrocarbon solvent, a halogen solvent, and an ether solvent.

Examples of the alcohol solvent include methanol, ethanol, and n-butanol.

Examples of the hydrocarbon solvent include ethane, propane, 2,3-dimethylbutane, benzene, and toluene. Examples of the halogen solvent include methylene chloride and chlorotrifluoromethane.

Examples of the ether solvent include dimethyl ether.

The above-listed examples may be used alone or in combination.

Among the above-listed examples, carbon dioxide is preferable because carbon dioxide has critical pressure of 7.3 MPa and a critical temperature of 31 degrees Celsius, and therefore a supercritical state of carbon dioxide is easily formed and carbon dioxide is inflammable and easily handled.

The subcritical fluid is not particularly limited and may be appropriately selected depending on the intended purpose, as long as the subcritical fluid is a fluid that exists as a high-pressure liquid in the temperature and pressure region near the critical points. The compounds listed as the supercritical compound can be also suitably used as the subcritical fluid.

The critical temperature and critical pressure of the supercritical fluid are is not particularly limited and may be appropriately selected depending on the intended purpose. The critical temperature is preferably −273 degrees Celsius or higher but 300 degrees Celsius or lower, and more preferably 0 degrees Celsius or higher but 200 degrees Celsius or lower.

In addition to the supercritical fluid or subcritical fluid, moreover, an organic solvent or an entrainer may be used in combination. A solubility in the supercritical fluid can be easily performed by adding the organic solvent or the entrainer.

The organic solvent is not particularly limited and may be appropriately selected depending on the intended purpose. Examples of the organic solvent include a ketone solvent, an ester solvent, an ether solvent, an amide solvent, a halogenated hydrocarbon solvent, and a hydrocarbon solvent.

Examples of the ketone solvent include acetone, methyl ethyl ketone, and methyl isobutyl ketone.

Examples of the ester solvent include ethyl formate, ethyl acetate, and n-butyl acetate.

Examples of the ether solvent include diisopropyl ether, dimethoxy ethane, tetrahydrofuran, dioxolane, and dioxane.

Examples of the amide solvent include N,N-dimethylformamide, N,N-dimethylacetamide, and N-methyl-2-pyrrolidone.

Examples of the halogenated hydrocarbon solvent include dichloromethane, chloroform, bromoform, methyl iodide, dichloroethane, trichloroethane, trichloroethylene, chlorobenzene, o-dichlorobenzene, fluorobenzene, bromobenzene, iodobenzene, and 1-chloronaphthalene.

Examples of the hydrocarbon solvent include n-pentane, n-hexane, n-octane, 1,5-hexadiene, cyclohexane, methylcyclohexane, cyclohexadiene, benzene, toluene, o-xylene, m-xylene, p-xylene, ethylbenzene, and cumene.

The above-listed examples may be used alone or in combination.

After laminating the hole-transporting material on the electron-transporting layer to which the photosensitizing compound is adsorbed, moreover, pressing may be performed. Since the hole-transporting material is more closely attached to the electron-transporting layer that is a porous electrode by performing the pressing, efficiency may be improved.

A method of the pressing is not particularly limited and may be appropriately selected depending on the intended purpose. Examples of the method thereof include press molding using a plate, such as IR pellet press, and roll pressing using a roller.

The pressure is preferably 10 kgf/cm² or greater, and more preferably 30 kgf/cm² or greater.

The duration of the pressing is not particularly limited and may be appropriately selected depending on the intended purpose. The duration is preferably 1 hour or shorter. Moreover, heat may be applied at the time of the pressing. At the time of the pressing, a release agent may be disposed between a press and the electrode.

Examples of the release agent include fluororesins, such as polyethylene tetrafluoride, polychloro ethylene trifluoride, an ethylene tetrafluoride-propylene hex-afluoride copolymer, a perfluoroalkoxy fluorocarbon resin, polyvinylidene fluoride, an ethylene-ethylene tetrafluoride copolymer, an ethylene-chloroethylene trifluoride copolymer, and polyvinyl fluoride. The above-listed examples may be used alone or in combination.

After performing the pressing but before disposing a second electrode, metal oxide may be disposed between the hole-transporting material and the second electrode.

Examples of the metal oxide include molybdenum oxide, tungsten oxide, vanadium oxide, and nickel oxide. The above-listed examples may be used alone or in combination. Among the above-listed examples, molybdenum oxide is preferable.

A method for disposing the metal oxide on the hole-transporting layer is not particularly limited and may be appropriately selected depending on the intended purpose. Examples of the method include a method where a thin film is formed in vacuum, such as sputtering and vacuum vapor deposition, and a wet film forming method.

As the wet film forming method, a method where a paste in which powder or sol of metal oxide is dispersed is prepared and the paste is applied onto the hole-transporting layer is preferable. In the case where the wet film forming method is used, a coating method is not particularly limited and may be performed according to any of methods known in the art. Examples of the coating method include dip coating, spray coating, wire bar coating, spin coating, roller coating, blade coating, gravure coating, and die coating. As a wet printing method, moreover, various methods, such as relief printing, offset printing, gravure printing, intaglio printing, rubber plate printing, and screen printing, can be used.

An average thickness of the applied metal oxide is preferably 0.1 nm or greater but 50 nm or less, and more preferably 1 nm or greater but 10 nm or less.

<Second Electrode>

The photoelectric conversion element includes a second electrode.

The second electrode may be formed on the hole-transporting layer or the metal oxide of the hole-transporting layer. As the second electrode, moreover, an electrode identical to the first electrode may be used. In the case where the strength of the second electrode can be sufficiently secured, a support is not necessarily required.

Examples of a material of the second electrode include metal, a carbon compound, conductive metal oxide, and a conductive polymer.

Examples of the metal include platinum, gold, silver, copper, and aluminium.

Examples of the carbon compound include graphite, fullerene, carbon nanotubes, and

graphene.

Examples of the conductive metal oxide include ITO, FTO, and ATO.

Examples of the conductive polymer include polythiophene and polyaniline.

The above-listed examples may be used alone or in combination.

A method for depositing the above-mentioned metal oxide on the hole-transporting material is not particularly limited. Examples of the method thereof include: a method where a thin film is formed in vacuum, such as sputtering and vacuum vapor deposition; and wet film formation. As the wet film formation method, preferable is a method where a paste in which a powder or sol of metal oxide is dispersed is prepared and the paste is applied onto the hole-transporting layer.

In the case where the wet film formation method is used, a coating method is not particularly limited and the coating may be performed according to any of methods known in the art.

Examples of the coating method include dip coating, spray coating, wire bar coating, spin coating, roller coating, blade coating, gravure coating, and die coating. As a wet printing method, moreover, various methods, such as relief printing, offset printing, gravure printing, intaglio printing, rubber plate printing, and screen printing, can be used. The film thickness is preferably 0.1 nm or greater but 50 nm or less, and more preferably 1 nm or greater but 10 nm or less.

The second electrode is additionally applied after forming the hole-transporting layer, or onto the above-mentioned metal oxide.

As the second electrode, moreover, an electrode identical to the above-described first electrode can be typically used. When the second electrode has a structure where strength or sealability is sufficiently maintained, a support is not required.

The second electrode can be formed on the hole-transporting layer by an appropriate method, such as coating, laminating, vapor deposition, CVD, and bonding, depending on a material of the second electrode for use, or the hole-transporting layer for use.

Within the photoelectric conversion element, at least one of the first electrode and the second electrode is preferably substantially transparent. It is preferable that the side of the first electrode be transparent and incident light enter the photoelectric conversion element from the side of the first electrode. In this case, a material that reflects light is preferably used at the side of the second electrode. As the material that reflects light, glass or a plastic to which metal or conductive oxide is deposited through vapor deposition, or a metal thin film is preferably used. Moreover, it is also effective to dispose an anti-reflection layer at the side from which incident light enters.

<Sealing Member>

The photoelectric conversion element preferably includes a sealing member configured to shield the electron-transporting layer and the hole-transporting layer from an outer environment of the photoelectric conversion element.

It is preferable that the sealing member be sandwiched between a pair of substrates, and the photoelectric conversion element have a void space inside the sealed photoelectric conversion element where at least the electron-transporting layer and the hole-transporting layer are shielded from an outer environment.

The photoelectric conversion element preferably includes a sealing member configured to shield the electron-transporting layer, the hole-transporting layer, and the second electrode from an outer environment of the photoelectric conversion element.

It is preferable that the sealing member be sandwiched between a pair of substrates, and the photoelectric conversion element have a void space inside the sealed photoelectric conversion element where at least the electron-transporting layer, the hole-transporting layer, and the second electrode are shielded from an outer environment.

Since the epoxy resin is used as the sealing member and moreover the hole-transporting layer includes at least one of tertiary amide compounds represented by General Formula (1) and General Formula (2), high output similar to before storage can be maintained even when the photoelectric conversion element is stored in a high temperature and high humidity environment. Moreover, high output can be maintained even when continuous irradiation of low illuminance light is performed.

The epoxy resin is not particularly limited and may be appropriately selected depending on the intended purpose, as long as the epoxy resin is a resin obtained by curing a monomer or oligomer including an epoxy group in a molecule thereof. Examples of the epoxy resin include a water-dispersing epoxy resin, a non-solvent epoxy resin, a solid epoxy resin, a heat-curable epoxy resin, a curing agent-mixed epoxy resin, and an ultraviolet ray-curable epoxy resin. Among the above-listed examples, a heat-curable epoxy resin and an ultraviolet ray-curable epoxy resin are preferable, and an ultraviolet ray-curable epoxy resin is more preferable. Note that, heating may be performed even on an ultraviolet ray-curable resin.

Moreover, examples of the epoxy resin include a bisphenol A-based epoxy resin, a bisphenol F-based epoxy resin, a novolac-based epoxy resin, a alicyclic epoxy resin, a long-chain aliphatic epoxy resin, a glycidyl amine-based epoxy resin, a glycidyl ether-based epoxy resin, and a glycidyl ester-based epoxy resin. The above-listed examples may be used alone or in combination.

The epoxy resin may include a curing agent or various additives according to the necessity.

Examples of the curing agent include an amine-based curing agent, an acid anhydride-based curing agent, a polyamide-based curing agent, and other curing agents.

Examples of the amine-based curing agent include: aliphatic polyamine, such as di-ethylenetriamine and triethylenetetramine; and aromatic polyamine, such as meth-phenylenediamine, diaminodiphenylmethane, and diaminodiphenylsulfone.

Examples of the acid anhydride-based curing agent include phthalic anhydride, tetra or hexahydrophthalic anhydride, methyltetrahydrophthalic anhydride, methylnadic anhydride, pyromellitic anhydride, HET anhydride, and dodecenylsuccinic anhydride.

Examples of other curing agents include imidazoles and polymercaptan. The above-listed examples may be used alone or in combination.

Examples of the additives include fillers, a gap agent, a polymerization initiator, a desiccant (dehumidifying agent), a curing accelerator, a coupling agent, a flexibilizer, a colorant, a flame retardant auxiliary, an antioxidizing agent, and an organic solvent. The above-listed examples may be used alone or in combination. Among the above-listed examples, fillers, a gap agent, a curing accelerator, a polymerization initiator, and a desiccant (dehumidifying agent) are preferable, and fillers and a polymerization initiator are more preferable.

As well as that the fillers are effective for suppressing entry of moisture or oxygen of the outer environment, the fillers are particularly effective because the fillers can impart an effect of reducing volume contraction during curing, an amount of gas at the time of curing or heating, improving mechanical strength, and controlling heat trans-mittance or fluidity, and the fillers are very effective for maintaining stable output in various environments.

The output properties or durability of the photoelectric conversion element is not only influenced by moisture or oxygen enters the photoelectric conversion element from the outer environment but also gas generated at the time when the sealing member is cured and at the time of heating. Particularly, the gas generated at the time of heating significantly affects output properties when the photoelectric conversion element is stored in a high temperature environment.

In this case, entry of moisture or oxygen can be suppressed by adding fillers, a gap agent, or a disccant into the sealing member, and therefore an amount of the sealing member for use can be reduced to thereby obtain an effect of reducing gas. Use of such additives is effective not only at the time of curing but also when a photoelectric conversion element is stored in a high temperature environment.

The fillers are not particularly limited and any of fillers known in the art can be used as the fillers. For example, inorganic fillers, such as crystalline or irregular silica, talc, alumina, aluminium nitrate, calcium silicate, and calcium carbonate, are preferably used. The above-listed examples may be used alone or in combination.

An average primary particle diameter of the fillers is preferably 0.1 micrometers or greater but 10 micrometers or less, and more preferably 1 micrometer or greater but 5 micrometers or less. When the average primary particle diameter is 0.1 micrometers or greater but 10 micrometers or less, an effect of suppressing entry of moisture or oxygen can be sufficiently obtained, an appropriate viscosity is obtained, adhesion with a substrate or defoaming is improved, and it is effective for controlling a width of a sealing part or workability.

An amount of the fillers is preferably 10 parts by mass or greater but 90 parts by mass or less, and more preferably 20 parts by mass or greater but 70 parts by mass or less, relative to a total amount of the sealing member. When the amount of the fillers is 10 parts by mass or greater but 90 parts by mass or less, an effect of suppressing entry of moisture or oxygen can be sufficiently obtained, an appropriate viscosity is obtained, and excellent adhesion and workability can be obtained.

The gap agent is also called a gap controlling agent or a spacing agent, and is configured to control a gap of the sealing part. When a sealing member is applied onto a first substrate of a first electrode and a second substrate is placed thereon to seal, for example, a gap of a sealing part is matched with a size of a gap agent because the gap agent is mixed with the epoxy resin, and therefore the gap of the sealing part can be easily controlled.

As the gap agent, any of materials known in the art can be used as long as the gap agent is a particulate material having a uniform particle size and having high solvent resistance and heat resistance. The gap agent is preferably a material which has high affinity to the epoxy resin and is in the shape of particles that are spheres. Specific examples of the gap agent include glass beads, silica particles, and organic resin particles. The above-listed examples may be used alone or in combination.

A particle size of the gap agent can be selected depending on a gap of a sealing part to be set. The particle size thereof is preferably 1 micrometer or greater but 100 micrometers or less, and more preferably 5 micrometers or greater but 50 micrometers or less.

The polymerization initiator is a material that is added for the purpose of initiating polymerization using heat or light.

The thermal polymerization initiator is a compound that generates an active species, such as radicals and cations, upon heating. As the thermal polymerization initiator, specifically, an azo compound, such as 2,2′-azobisbutyronitrile (AIBN), or peroxide, such as benzoyl peroxide (BPO) is used. As the thermal cationic polymerization initiator, benzenesulfonic acid ester, or alkyl sulfonium salt is used.

As the photopolymerization initiator, a photo cationic polymerization initiator is preferably used for the epoxy resin. When the photo cationic polymerization initiator is mixed with the epoxy resin and light irradiation is performed, the photo cationic polymerization initiator is decomposed to generate strong acid, and the acid induces polymerization of the epoxy resin to proceed a curing reaction. The photo cationic polymerization initiator has effects that a volume contraction during curing is small, oxygen inhibition does not occur, and storage stability is high.

Examples of the photo cationic polymerization initiator include an aromatic diazonium salt, an aromatic iodonium salt, an aromatic sulfonium salt, a metallocene compound, and a silanol-aluminium complex.

Moreover, a photoacid generator having a function of generating acid upon irradiation of light can be also used. The photoacid generator functions as an acid for initiating cationic polymerization. Examples of the photoacid generator include onium salts, such as an ionic sulfonium salt-based photoacid generator made up of a cation part and an anionic part and an ionic part, and an ionic iodonium salt made up of a cation part and an anionic part. The above-listed examples may be used alone or in combination.

An amount of the polymerization initiator added is preferably 0.5 parts by mass or greater but 10 parts by mass, more preferably 1 part by mass or greater but 5 parts by mass or less, relative to a total amount of the sealing member. The polymerization initiator added in the amount of 0.5 parts by mass or greater but 10 parts by mass is effective because curing is appropriately progressed, an amount of uncured resides can be reduced, and an excessive amount of gas generated can be prevented.

The desiccant is also called a dehumidifying agent and is a material having a function of physically or chemically adsorbing or absorbing moisture. There is a case where humidity resistance is further enhanced or an influence of outgassing may be reduced by adding the desiccant to the sealing member. Therefore, use of the desiccant is effective.

The desiccant is preferably a particulate material. Examples of the desiccant include inorganic water-absorbing materials, such as calcium oxide, barium oxide, magnesium oxide, magnesium sulfate, sodium sulfate, calcium chloride, silica gel, molecular sieve, and zeolite. Among the above-listed examples, zeolite is preferable because zeolite has a large amount of moisture absorption. The above-listed examples may be used alone or in combination.

The curing accelerator is also called a curing catalyst and is used for the purpose of accelerating curing speed. The curing accelerator is mainly used for a heat curable epoxy resin.

Examples of the curing accelerator include: tertiary amine or tertiary amine salts, such as 1,8-diazabicyclo(5,4,0)-undec-7-ene (DBU) and 1,5-bicyclo(4,3,0)-non-5-ene (DBN); imidazole-based curing accelerators, such as 1-cyanoethyl-2-ethyl-4-methylimidazole and 2-ethyl-4-methylimidazole; and phofine or phosphonium salts, such as triphenylphosphine and tetraphenylphosphonium tetraphenylborate. The above-listed examples may be used alone or in combination.

The coupling agent has an effect of increasing molecular binding force. Examples of the coupling agent include a silane coupling agent. Examples of the coupling agent include: silane coupling agents, such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-gamma-aminopropyltrimethoxysilane, N-(2-aminoethyl)3-aminopropylmethyldimethoxysilane, N-(2-aminoethyl)3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)3-aminopropyltrimethoxysilane hydrochloride, and 3-methacryloxypropyltrimethoxysilane. The above-listed examples may be used alone or in combination.

As the sealing member, an epoxy resin composition that is commercially available as an encapsulant, a sealing material, or an adhesive has been known, and such commercial products can be used in the present disclosure. Among such commercial products, there are epoxy resin compositions that are developed and commercially available for use in solar cells or organic EL elements, and such commercial products are particularly effectively used in the present disclosure.

Examples of the commercial products include: TB3118, TB3114, TB3124, and TB3125F (available from ThreeBond); WorldRock5910, WorldRock5920, and WorldRock8723 (available from Kyoritsu Chemical Co., Ltd.); and WB90US(P) (available from MORESCO Corporation).

Moreover, the epoxy resin composition is disclosed, for example, in Japanese Patent Nos. 4918975, 5812275, 5835664, and 5930248, and Japanese Patent Application Laid-Open No. 2012-136614, and any of the epoxy resin compositions disclosed therein may be also used.

Moreover, a sheet-shaped sealing material may be also effectively used in the present disclosure.

The sheet-shaped sealing material is a product where an epoxy resin layer is formed on a sheet in advance. As the sheet, glass or a film having high gas barrier properties may be used. The sheet corresponds to a substrate in the present disclosure. The sealing member and the substrate can be formed at once by bonding the sheet-shaped sealing member onto the second electrode of the photoelectric conversion element or the photoelectric conversion element module and the curing the epoxy resin layer. A structure where a void space is disposed inside the photoelectric conversion element can be formed by the formation pattern of the epoxy resin layer formed on the sheet and therefore use of such a sheet-shaped sealing material is effective.

The position of the sealing member is not particularly limited and may be appropriately selected depending on the intended purpose, as long as the sealing member is disposed at the position by which at least the electron-transporting layer, the hole-transporting layer, and the second electrode are shielded from the outer environment of the photoelectric conversion element. For example, the sealing member may be disposed over the entire surface to over the electron-transporting layer, the hole-transporting layer, and the second electrode. Alternatively, a substrate may be disposed above the second electrode, and the sealing member may be disposed on the rim of the substrate to bond to at least one of the first substrate, the first electrode, and the hole-blocking layer.

As described as the latter, the structure where the substrate is disposed and the sealing member is disposed on the rim of the substrate can dispose a void space inside the photoelectric conversion element or the photoelectric conversion element module. The void space can control oxygen or humidity and is effective for improving output or durability.

In the present disclosure, the void space particularly preferably includes oxygen. The function of hole transportation of the hole-transporting layer can be stably maintained over a long period as oxygen is included, and therefore durability of the photoelectric conversion element or the photoelectric conversion element module can be improved. In the present disclosure, the oxygen concentration of the void space disposed inside the photoelectric conversion element by sealing is not limited as the effect is obtained as long as oxygen is included. The oxygen concentration is preferably 1.0% by volume or greater but 21.0% by volume or less, and more preferably 3.0% by volume or greater but 15.0% by volume or less.

The oxygen concentration of the void space can be controlled by performing sealing in a glove box an oxygen concentration of which is set. The setting of the oxygen concentration can be performed by a method where a gas cylinder including gas having a specific oxygen concentration is used, or a method using a nitrogen gas generator. The oxygen concentration inside the glove box is measured by means of a commercially available oxygen meter or oxygen monitor.

For example, a measurement of the oxygen concentration inside the void space formed by sealing can be performed by means of an atmospheric pressure ionization mass spectrometer (API-MS). Specifically, the oxygen concentration is determined in the following manner. The photoelectric conversion element or photoelectric conversion element module is placed in a chamber filled with inert gas, the sealing is open inside the chamber, an quantitative analysis of the gas inside the chamber is performed by API-MS to determine quantities of all of the components in the gas included in the void space, and a ratio of the oxygen relative to a total of all of the components is calculated to determine the oxygen concentration.

Gas other than oxygen is preferably inert gas. Examples of the inert gas include nitrogen and argon.

During sealing, a dew point inside the glove box is preferably controlled as well as the oxygen concentration thereon. To control the dew point is effective for improving output or durability of the photoelectric conversion element or photoelectric conversion element module.

The dew point is determined as a temperature at which coagulation starts when gas including water vapor is cooled. The dew point is preferably 0 degrees Celsius or lower, and more preferably −20 degrees Celsius or lower. The lower limit of the dew point is preferably −50 degrees Celsius or higher.

Moreover, a passivation layer may be disposed between the second electrode and the sealing member. The passivation layer is not particularly limited and may be appropriately selected depending on the intended purpose. For example, aluminium oxide, silicon nitrate, and silicon oxide are preferable for the passivation layer.

A formation method of the sealing member is not particularly limited and may be appropriately selected depending on the intended purpose. Examples of the formation method include dispensing, wire bar coating, spin coating, roller coating, blade coating, gravure coating, relief printing, offset printing, intaglio printing, rubber plate printing, and screen printing.

<First Substrate>

The photoelectric conversion element may include a first substrate.

A shape, structure, and size of the first substrate are not particularly limited and may be appropriately selected depending on the intended purpose.

The material of the first substrate is not particularly limited and may be appropriately selected depending on the intended purpose, as long as the material is a material having translucency and insulation. Examples of the material include substrates, such as glass, plastic plates, plastic films, plastic membranes, ceramics, and inorganic transparent crystals. Among the above-listed example, a substrate having heat resistance against a firing temperature is preferable in the case where a step of firing is included at the time when an electron-transporting layer is formed as described below. Moreover, the first substrate is preferably a substrate having flexibility.

<Second Substrate>

The photoelectric conversion element may include a second substrate.

The second substrate is not particularly limited and any of substrates known in the art can be used. Examples thereof include substrates, such as glass, transparent plastic plates, transparent plastic membranes, inorganic transparent crystals, plastic films, and ceramics. A convex-concave part may be formed at a contact area of the second substrate with a sealing member in order to increase adhesion between the second substrate and the sealing member.

A formation method of the convex-concave part is not particularly limited and may be appropriately selected depending on the intended purpose. Examples of the formation method include sand blasting, water blasting, polishing with sand paper, chemical etching, and laser processing.

As a method for increasing adhesion between the second substrate and the sealing member, for example, organic matter on a surface thereof may be removed or hy-drophilicity of the surface thereof may be improved. A method for removing organic matter on a surface of the second substrate is not particularly limited and may be appropriately selected depending on the intended purpose. Examples of the method include UV ozone washing and an oxygen plasma treatment.

<Hole-Blocking Layer>

The photoelectric conversion element may include a hole-blocking layer.

The hole-blocking layer is preferably disposed between the first electrode and the electron-transporting layer.

The hole-blocking layer is configured to transport electrons, which are generated by a photosensitizing compound and transported to the electron-transporting layer, to the first electrode and prevent from being in contact with the hole-transporting layer. The presence of the hole-blocking layer can suppress flow of holes into the first electrode and prevent low output caused by recombination of electrons and holes. Since a solid photoelectric conversion element to which a hole-transporting layer is disposed has high speed of recombination between holes in the hole-transporting material and electrons on a surface of the electrode compared to a fluid-type photoelectric conversion element, an effect obtainable by forming the hole-blocking layer is significant.

A material of the hole-blocking layer is not particularly limited and may be appropriately selected depending on the intended purpose, as long as the material of the hole-blocking layer is a material that is transparent to visible light and has electron transporting properties. Examples of the material of the hole-blocking layer include a single semiconductor (e.g., silicon and germanium), a compound semiconductor (e.g., chalcogenide of metal), and a compound having a perovskite structure.

Examples of the chalcogenide of metal include: oxides of titanium, tin, zinc, iron, tungsten, zirconium, hafnium, strontium, indium, cerium, yttrium, lanthanum, vanadium, niobium, and tantalum; sulfides of cadmium, zinc, lead, silver, antimony, and bismuth; selenides of cadmium and lead; and telluride of cadmium. Other examples of the compound semiconductor include: phosphides of zinc, gallium, indium, and cadmium; gallium arsenide; copper-indium-selenide; and copper-indium-sulfide.

Examples of the compound having a perovskite structure include strontium titanate, calcium titanate, sodium titanate, barium titanate, and potassium niobate.

Among the above-listed examples, oxide semiconductors are preferable, titanium oxide, niobium oxide, magnesium oxide, aluminium oxide, zinc oxide, tungsten oxide, and tin oxide are more preferable, and titanium oxide is even more preferable.

The above-listed examples may be used alone or in combination. The above-listed materials may be used as a single layer or a laminate. Moreover, a crystal structure of any of the above-listed semiconductors is not particularly limited and may be appropriately selected depending on the intended purpose. The crystal structure thereof may be a single crystal, polycrystalline, or amorphous.

A film forming method of the hole-blocking layer is not particularly limited and may be appropriately selected depending on the intended purpose. Examples of the film forming method of the hole-blocking layer include a sol-gel method that is wet film formation, a hydrolysis method from titanium tetrachloride, and sputtering that is dry film formation. Among the above-listed examples, sputtering is preferable. When the film forming method of the hole-blocking layer is sputtering, a film density can be made sufficiently high and current loss can be suppressed.

A film thickness of the hole-blocking layer is not particularly limited and may be appropriately selected depending on the intended purpose. The film thickness of the hole-blocking layer is preferably 5 nm or greater but 1 micrometer or less. In case of a film formed by a wet system, the film thickness is more preferably 500 nm or greater but 700 nm or less. In case of a film formed by a dry system, the film thickness is more preferably 5 nm or greater but 30 nm or less.

### EMBODIMENTS

Examples of the photoelectric conversion element of the present disclosure will be described with reference to drawings hereinafter. However, the present disclosure is not limited to the following examples. For example, the number, position, shape etc. of the following constituting members, which are not described in the embodiments, are also included in the scope of the present disclosure.

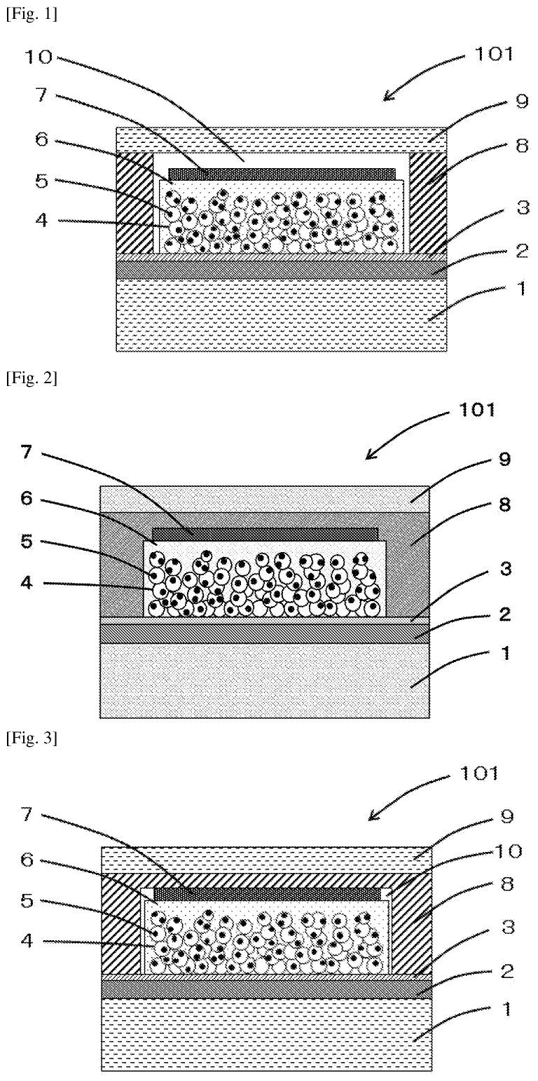

FIG. 1 is a schematic view illustrating an example of the photoelectric conversion element of the present disclosure.

As illustrated in FIG. 1, a first electrode 2 is formed on a first substrate 1, and a hole-blocking layer 3 is formed on the first electrode 2 in the photoelectric conversion element 101. An electron-transporting layer 4 is formed on the hole-blocking layer 3, and a photosensitizing compound 5 is adsorbed on a surface of an electron-transporting material constituting the electron-transporting layer 4. A hole-transporting layer 6 is formed at the upper part and the inner part of the electron-transporting layer 4, and a second electrode 7 is formed on the hole-transporting layer 6. A second substrate 9 is disposed above the second electrode 7, and the second substrate 9 is fixed to the hole-blocking layer 3 with sealing members 8. Since the hole-blocking layer 3 is formed, recombination of electrons and holes can be prevented and the hole-blocking layer is effective for improving power generation performance.

The photoelectric conversion element illustrated in FIG. 1 may include a void space 10 between the second electrode 7 and the second substrate 9. Since the void space is included, an oxygen concentration within the void space can be controlled and therefore power generation performance and durability can be improved. Since the second electrode 7 and the second substrate 9 are not directly in contact with each other, moreover, pealing or breakage of the second electrode 7 can be prevented.

The oxygen concentration in the void space is not particularly limited and may be appropriately selected depending on the intended purpose. The oxygen concentration is preferably 1.0% by volume or greater but 21.0% by volume or less, and more preferably 3.0% by volume or greater but 15.0% by volume or less.

Although they are not illustrated, each of the first electrode 2 and the second electrode 7 may have a path that conducts to each of electrode extraction terminals.

FIG. 2 is a schematic view illustrating another example of the photoelectric conversion element of the present disclosure, and illustrates a case where a void space is not disposed and the void space of FIG. 1 is covered with the sealing member 8.

A production method of the photoelectric conversion element in which a void space is not disposed is not particularly limited and may be appropriately selected depending on the intended purpose. Examples of the production method thereof include: a method where the sealing member 8 is applied onto an entire surface of the second electrode 7, and the second substrate 9 is placed thereon; and a method using the above-mentioned sheet-shaped sealing material.

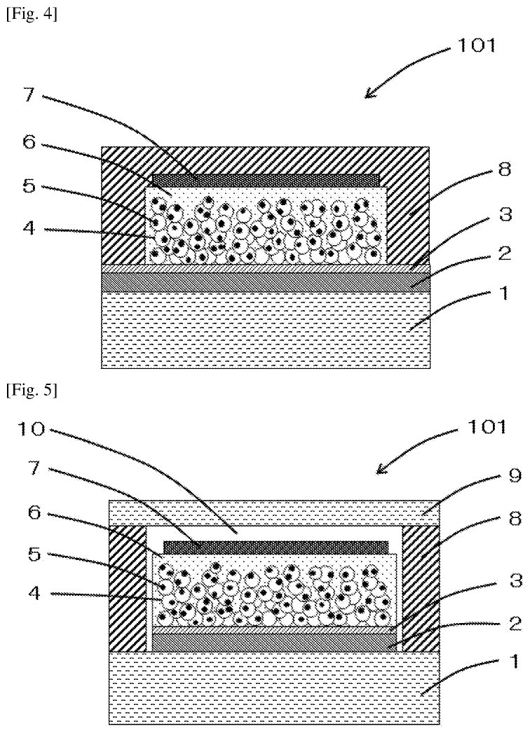

The void space inside the sealing may be completely removed, or may be partially left as illustrated in FIG. 3. Since almost the entire surface is covered with the sealing material, the peeling or breakage of the second substrate 9 can be reduced when the photoelectric conversion element is twisted or stress is applied by dropping the photoelectric conversion element. Therefore, mechanical strength of the photoelectric conversion element can be enhanced. As a modified example of FIG. 2, moreover, the photoelectric conversion element may have a structure where the second substrate is not disposed as illustrated in FIG. 4.

FIG. 5 is a schematic view illustrating another example of the photoelectric conversion element of the present disclosure, and illustrates an example where the sealing member 8 is bonded to the first substrate 1 and the second substrate 9. Since the photoelectric conversion element has the above-described structure, adhesion between the sealing member 8 and the substrates becomes high, and an effect of increasing mechanical strength of the photoelectric conversion element can be obtained. Since the adhesion is increased, moreover, an effect of further enhancing a sealing effect for preventing excess moisture or oxygen from entering can be obtained.

(Photoelectric Conversion Element Module)

The photoelectric conversion element module of the present disclosure includes a photoelectric conversion element-disposed region where a plurality of photoelectric conversion elements are disposed next to one another, and a sealing member that is disposed at a rim of the photoelectric conversion element-disposed region, and includes an epoxy resin. Each of the photoelectric conversion elements includes a first electrode, an electron-transporting layer including a photosensitizing compound, a hole-transporting layer, and a second electrode. The sealing member is configured to shield the electron transporting layer from an outer environment of the photoelectric conversion element. The hole-transporting layer includes a p-type semiconductor material and a basic compound. Ionization potential of the hole-transporting layer is greater than ionization potential of the p-type semiconductor material and is less than 1.07 times the ionization potential of the p-type semiconductor material. Ionization potential of the photosensitizing compound is greater than the ionization potential of the hole-transporting layer. An acid dissociation constant (pKa) of the basic compound is 6 or greater but 10 or less. The photoelectric conversion element may further include other layers. Each layer may have a single layer structure or a laminate structure.

Moreover, the photoelectric conversion element module of the present disclosure may have a structure where a plurality of the photoelectric conversion elements are included.

A constitution of each layer of the photoelectric conversion element module may be identical to the constitution of each layer of the photoelectric conversion element.

As an example of the configuration of the photoelectric conversion element module, there is a configuration where a plurality of the photoelectric conversion elements are connected in series or parallel.

The photoelectric conversion element module may have an embodiment where, among at least two photoelectric conversion elements next to each other, at least the hole-transporting layer in one of the photoelectric conversion elements and the hole-transporting layer in other photoelectric conversion element are extended to each other to form a continuous layer.

The photoelectric conversion element module may have a structure where the photoelectric conversion element module includes a pair of substrates, the photoelectric conversion element-disposed region is disposed between the substrates, and the sealing member is sandwiched between the substrates.

### EMBODIMENTS

Examples of the photoelectric conversion element module of the present disclosure will be described with reference to drawings hereinafter. However, the present disclosure is not limited to the following examples. For example, the number, position, shape etc. of the following constituting members, which are not described in the embodiments, are also included in the scope of the present disclosure.

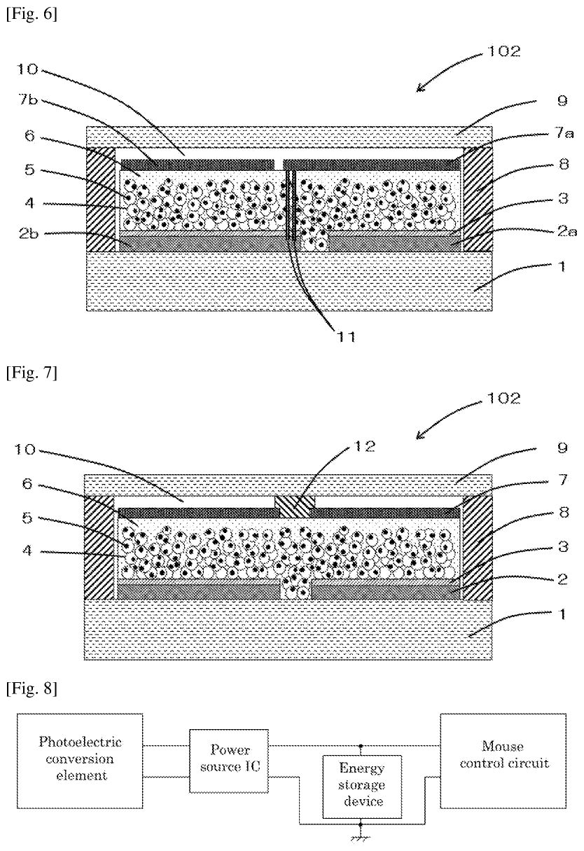

FIG. 6 is a schematic view illustrating an example of the photoelectric conversion element module of the present disclosure and is an example illustrating a cross-section of part of the photoelectric conversion element module including a plurality of photoelectric conversion elements connected in series.

In FIG. 6, a penetration part 11 is formed after forming a hole-transporting layer 6, and then a second electrode 7 is formed to introduce the second electrode material inside the penetration part 11 to thereby electrically connect to a first electrode 2b of an adjacent cell. Although they are not illustrated in FIG. 6, each of the first electrode 2a and the second electrode 7b have a path for electrically connecting to an electrode of an adjacent cell or an output extraction terminal.

The penetration part 11 may penetrate through the first electrode 2 to reach the first substrate 1, or may not reach the first substrate 1 by stopping the processing at the inner part of the first electrode 2.

In the case where a shape of the penetration part 11 is a fine hole that passes through the first electrode 2 to reach the first substrate 1, a film cross-sectional area of the first electrode 2 reduces as a total opening area of the fine hole is too large relative to area of the penetration part 11, and therefore a resistance value increases and reduction of a photoelectric conversion efficiency may be caused. Therefore, a ratio of the total opening area of the fine hole to the area of the penetration part 11 is preferably 5/100 or greater but 60/100 or less.

A formation method of the penetration part 11 is not particularly limited and may be appropriately selected depending on the intended purpose. Examples of the formation method include sand blasting, water blasting, polishing with sand paper, chemical etching, and laser processing. Among the above-listed examples, laser processing is preferable. According to the above-mentioned formation method, a fine hole can be formed without using sand, etching, or a resist, and moreover a process can be performed cleanly with good reproducibility. In the case where the penetration part 11 is formed, moreover, at least one of the hole-blocking layer 3, the electron-transporting layer 4, the hole-transporting layer 6, and the second electrode 7 can be removed by impact peeling through laser processing. As a result, it is not necessary to dispose a mask at the time of laminating, and removal and formation of the fine penetration part 11 can be easily performed at once.

FIG. 7 is a schematic view illustrating an example of the photoelectric conversion element module of the present disclosure, and is an example illustrating a cross-section of part of a photoelectric conversion element module where the photoelectric conversion element module includes a plurality of photoelectric conversion elements connected in series and a sealing member 12 like a beam is disposed in a void space between cells.

In the case where a void space is disposed between the second electrode 7 and the second substrate 9 as in FIG. 1, peeling or breakage of the second electrode 7 can be prevented, but mechanical strength of sealing may reduce. In the case where the space between the second electrode 7 and the second substrate 9 is filled with the sealing member as in FIG. 3, on the other hand, mechanical strength of sealing increases, but peeling of the second electrode 7 may be caused. In order to increase electric power generation, an increase in an area of the photoelectric conversion element module is effective. However, reduction of mechanical strength cannot be avoided when the photoelectric conversion element module includes a void space.

Therefore, peeling or breakage of the second electrode 8 can be prevented and mechanical strength of sealing can be increased by disposing the sealing member 12 like a beam as illustrated in FIG. 7, and such use of the sealing member 12 is effective.

(Electronic Device)

An electronic device of the present disclosure includes the photoelectric conversion element and/or photoelectric conversion element module of the present disclosure and a device that is driven by electric power generated through photoelectric conversion performed by the photoelectric conversion element and/or photoelectric conversion element module. The electronic device may further include other devices according to the necessity.

(Power Supply Module)

A power supply module of the present disclosure includes the photoelectric conversion element and/or photoelectric conversion element module of the present disclosure and a power supply IC, and may further includes other devices according to the necessity.

Specific embodiments of the electronic device including the photoelectric conversion element or the photoelectric conversion element module and a device that is driven by electricity generated by the photoelectric conversion element or the photoelectric conversion element module will be described.

An example where a mouse is used as the electronic device is illustrated in FIG. 8.

As illustrated in FIG. 8, the photoelectric conversion element or photoelectric conversion element module and a power supply IC and moreover an energy storage device are combined and electricity is supplied to a power supply of a control circuit of the mouse. As a result, the electricity is charged in the energy storage device when the mouse is not used, and the mouse can be driven by the electricity, and therefore the mouse that does not require wiring or replacement a battery can be obtained. Since a battery is not required, moreover, a weight thereof can be reduced and therefore it is effective.

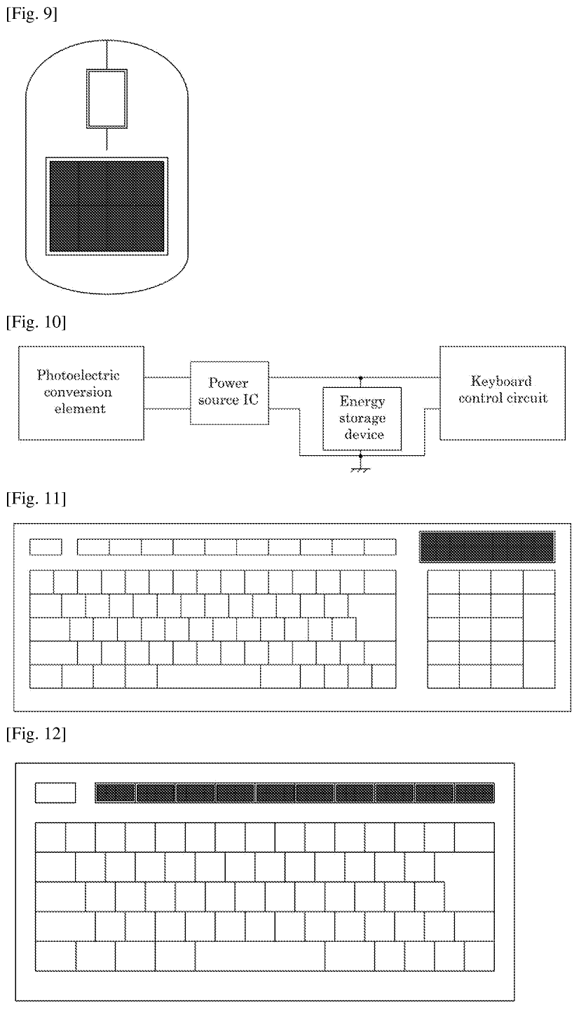

FIG. 9 is a schematic view illustrating a mouse to which a photoelectric conversion element is mounted. The photoelectric conversion element, the power supply IC, and the energy storage device are mounted inside the mouse, but an upper part of the photoelectric conversion element is covered with a transparent housing to allow light to reach the photoelectric conversion element. Moreover, a whole housing of the mouse can be formed of a transparent resin. The arrangement of the photoelectric conversion element is not limited to the example as mentioned above. For example, the photoelectric conversion element may be arranged in a position to which light is applied even when the mouse is covered with a hand, and such an arrangement may be preferable.

Other embodiments of the photoelectric conversion element and photoelectric conversion element module of the present disclosure and an electronic device having a device driven by electric power generated by the photoelectric conversion element and photoelectric conversion element module will be described.

FIG. 10 illustrates an example where a keyboard used for a personal computer is used as the electronic device.

As illustrated in FIG. 10, the photoelectric conversion element, a power supply IC, and an energy storage device are combined, and electricity supplied is connected to a power supply of a control circuit of the keyboard. As a result, electricity is charged in the energy storage device when the keyboard is not used, and the keyboard can be driven by the electricity, and therefore the keyboard that does not require wiring or replacement of a battery can be obtained. Since a battery is not required, moreover, a weight thereof can be reduced and therefore it is effective.

FIG. 11 is a schematic view of a keyboard to which the photoelectric conversion element is mounted. The photoelectric conversion element, the power supply IC, and the energy storage device are mounted inside the keyboard, but an upper part of the photoelectric conversion element is covered with a transparent housing to allow light to reach the photoelectric conversion element. A whole housing of the keyboard can be formed of a transparent resin. The arrangement of the photoelectric conversion element is not limited to the example as mentioned above.

In case of a small keyboard having a small space into which the photoelectric conversion element is disposed, as illustrated in FIG. 12, a small photoelectric conversion element may be embedded in part of the key, and such an arrangement may be effective.

Another embodiment of the photoelectric conversion element and photoelectric conversion element module of the present disclosure and an electronic device having a device driven by electric power generated by the photoelectric conversion element and photoelectric conversion element module will be described.

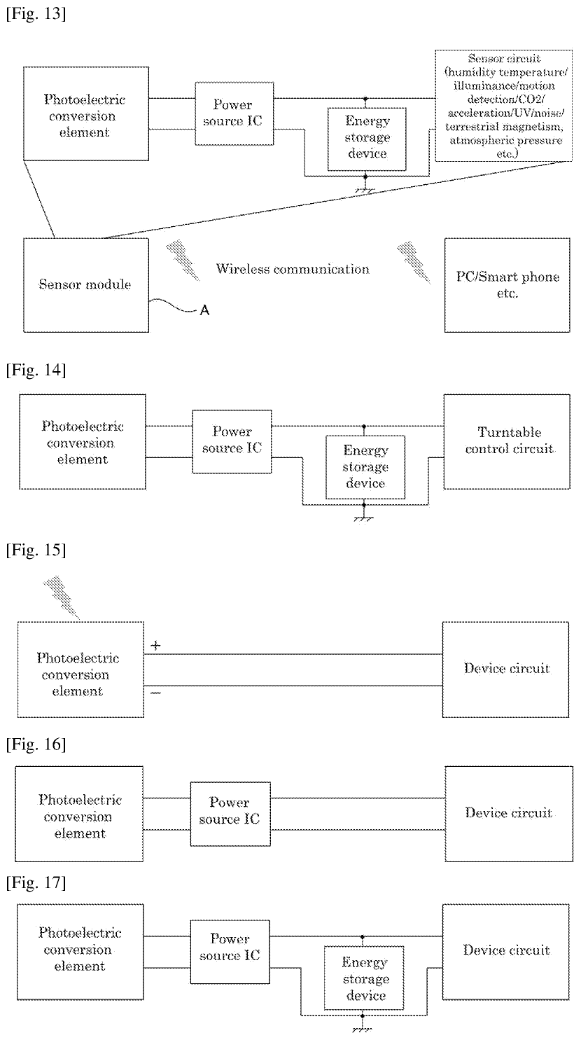

FIG. 13 illustrates an example where a sensor is used as the electronic device.

As illustrated in FIG. 13, the photoelectric conversion element, a power supply IC, and an energy storage device are combined, and electricity supplied is connected to a power supply of a sensor circuit. As a result, a sensor module can be constituted without connecting an external power supply and without replacing a battery. A sensing target is a temperature and humidity, illuminance, motion detector, CO₂, acceleration, UV, noise, terrestrial magnetism, atmospheric pressure, etc., and such an electronic device can be applied for various sensors and effective. As illustrated with A in FIG. 13, the sensor module is configured to sense a measuring target on a periodic bases and transmit the read data to PC or a smartphone through wireless communication.

It is expected that use of sensors is getting significantly increased as IoT society is realized. Replacing batteries of numeral sensors is time consuming and is not realistic. Moreover, the fact that a sensor is generally installed in a position where it is difficult to replace a battery, such as a celling and a wall, also makes workability bad. It is also significant advantage that electricity can be supplied by the photoelectric conversion element. Moreover, an advantage that freedom in an arrangement is high can be obtained as the photoelectric conversion element can obtain high output even with low illuminance light and the output thereof has less dependency to an incident angle of light.

Another embodiment of the photoelectric conversion element and photoelectric conversion element module of the present disclosure and an electronic device having a device driven by electric power generated by the photoelectric conversion element and photoelectric conversion element module will be described.

FIG. 14 illustrates an example where a turntable is used as the electronic device.

As illustrated in FIG. 14, the photoelectric conversion element, a power supply IC, and an energy storage device are combined, and electricity supplied is connected to a power supply of a turntable circuit. As a result, a turntable can be constituted without connecting an external power supply and without replacing a battery.

The turntable is used, for example, in a display case in which products are displayed. Wiring of a power supply of the turntable degrades an appearance of the display, and moreover displayed products need to be removed when a battery of the turntable is replaced, which is time-consuming work. The above-mentioned problems can be solved by using the photoelectric conversion element of the present disclosure and therefore use thereof is effective.

<Use>

The photoelectric conversion element and photoelectric conversion element module of the present disclosure, the electronic device including a device that is driven by electricity generated by the photoelectric conversion element and photoelectric conversion element module of the present disclosure, and the power supply module have been described above. The embodiments described are only part of applicable embodiments, and use of the photoelectric conversion element or photoelectric conversion element module of the present disclosure is not limited to the above-described embodiments.

The photoelectric conversion element or photoelectric conversion element module can be applied for, for example, a power supply device by combining with a circuit board configured to control generated electricity.

Examples of devices using the power supply device include electronic desk cal-culators, watches, mobile phones, electronic organizers, and electronic paper.

Moreover, a power supply device including the photoelectric conversion element can be used as an auxiliary power supply for prolonging a continuous use time of a charge-type or a dry cell-type of an electrical appliance.

The photoelectric conversion element or photoelectric conversion element module of the present disclosure can function as a self-sustaining power supply, and a device can be driven by electricity generated through photoelectric conversion. Since the photoelectric conversion element and photoelectric conversion element module can generate electricity upon irradiation of light, it is not necessary to connect the electronic device with a power supply or to replace a battery. Therefore, the electronic device can be driven in a place where there is no a power supply facility, the electronic device can be worn or used mobile, and the electronic device can be driven without replacing a battery in a place where it is difficult to perform replacement of the battery. In the case where a dry cell is used, moreover, a weight of the electronic device increases by the weight of the dry cell or a size of the electronic device increases. Therefore, there may be a problem in installing the electronic device on a wall or celling, or transporting. Since the photoelectric conversion element and photoelectric conversion element module of the present disclosure are light and thin, there is high freedom in installing, and there is a significant advantage in wearing or carrying the electronic device.

As described above, the photoelectric conversion element and photoelectric conversion element module of the present disclosure can be used as self-sustaining power supply, and such a self-sustaining power supply can be combined with various electronic devices. For example, the self-sustaining power supply can be used in combination with a display device (e.g., an electronic desk calculator, a watch, a mobile phone, an electronic organizer, and electronic paper), an accessory device of a personal computer (e.g., a mouse and a keyboard), various sensor devices (e.g., a temperature and humidity sensor and a motion detection sensor), transmitters (e.g., a beacon and GPS), and numerous electronic devices (e.g., auxiliary lamps and remote controllers).

The photoelectric conversion element and photoelectric conversion element module of the present disclosure is widely applied because the photoelectric conversion element or photoelectric conversion element module can generate electric power particularly with low illuminance light and can generate electric power indoor, moreover in a shaded place. Moreover, the photoelectric conversion element and photoelectric conversion element module is highly safe because liquid leakage is not cause unlike a dry cell, and accidental ingestion that is often caused with a button cell does not occur. Furthermore, the photoelectric conversion element or photoelectric conversion element module can be used as an auxiliary power supply for prolonging a continuous use time of a charge-type or a dry cell-type of an electrical appliance. As described above, an electronic device that is light and easy to use, has high freedom in installing, does not require replacement of a battery, is highly safe, and is effective for reducing envi-ronmental loads can be obtained by combining the photoelectric conversion element or photoelectric conversion element module of the present disclosure with a device that can be driven by electric power generated through photoelectric conversion performed by the photoelectric conversion element or photoelectric conversion element module.

A basic structural view of an electronic device in which the photoelectric conversion element and/or photoelectric conversion element module of the present disclosure and a device that is driven by electric power generated through photoelectric conversion performed by the photoelectric conversion element and/or photoelectric conversion element module is illustrated in FIG. 15. The electronic device can generate electric power as the photoelectric conversion element is irradiated with light and electric power can be extracted. The circuit of the device can be driven by the generated electric power.

Since output of the photoelectric conversion element varies depending on illuminance of the surrounding environment, there may be a case where the electronic device illustrated in FIG. 15 may not be stably driven. In this case, it is possible to embed a power supply IC for a photoelectric conversion element between the photoelectric conversion element and the circuit of the device in order to supply stable voltage to the side of the circuit as illustrated in FIG. 16, and such an arrangement is effective.

The photoelectric conversion element can generate electric power as long as light of sufficient illuminance is applied, but desired electric power cannot be obtained when illuminance is insufficient to generate electric power, which is a disadvantage of the photoelectric conversion element. In this case, excess electric power from the photoelectric conversion element can be stored in the energy storage device, the electric power stored in the energy storage device can be supplied to a circuit of the device even when illuminance is too low or light is not applied to the photoelectric conversion element, and the electronic device can be stably driven, by mounting the energy storage device, such as a capacitor, between a power supply IC and the circuit of the device as illustrated in FIG. 17.

As described above, the electronic device in which the photoelectric conversion element and/or photoelectric conversion element module of the present disclosure and a device circuit are combined can be driven even in an environment where a power supply is unavailable, does not require replacement of a battery, and can be stably driven by combining with a power supply IC or an energy storage device. In this manner, advantages of the photoelectric conversion element can be maximized.

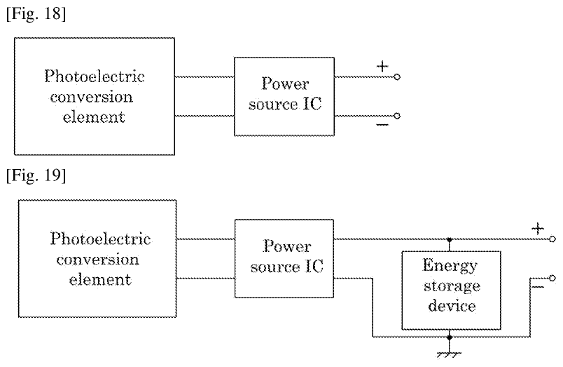

Meanwhile, the photoelectric conversion element and/or photoelectric conversion element module of the present disclosure can be also used as a power supply module, and such use is effective. As illustrated in FIG. 18, for example, a DC power supply module capable of supplying electric power generated through photoelectric conversion performed by the photoelectric conversion element to a power supply IC for a photoelectric conversion element at a constant voltage level by connecting the photoelectric conversion element and/or photoelectric conversion element module of the present disclosure to the power supply IC for the photoelectric conversion element.

By adding an energy storage device to the power supply IC as illustrated in FIG. 19, moreover, electric power generated by the photoelectric conversion element can be stored in the energy storage device. Therefore, a power supply module to which electric power can be supplied even when illuminance is too low or light is not applied to the photoelectric conversion element can be composed.

The power supply modules of the present disclosure illustrated in FIG. 18 and FIG. 19 can be used as a power supply module without replacing a battery as in case of primary cells known in the art.

### EXAMPLES

The present disclosure will be described more specifically below by way of Examples. The present disclosure should not be construed as being limited to these Examples.

### Example 1

<Production of Photoelectric Conversion Element>

First, a dense layer formed of titanium oxide was formed as a hole-blocking layer on an ITO coated glass by reactive sputtering with oxygen gas, where the ITO coated glass was formed by sequentially depositing, as a first electrode, a film of indium-doped tin oxide (ITO) and a film of niobium-doped tin oxide (NTO) by sputtering on a glass substrate serving as a first substrate.

Subsequently, 3 g of titanium oxide (product name: P90, available from NIPPON AEROSIL CO., LTD.), 0.2 g of acetyl acetone, and 0.3 g of polyoxyethylene octylphenyl ether (available from Wako Pure Chemical Corporation) serving as a surfactant were subjected to a bead mill treatment together with 5.5 g of water and 1.0 g of ethanol for 12 hours to thereby produce a titanium oxide dispersion liquid. To the produced titanium oxide dispersion liquid, 1.2 g of polyethylene glycol (product name: Polyethylene glycol 20,000, available from Wako Pure Chemical Corporation) to thereby produce a paste. The produced paste was applied (average thickness: 1.5 micrometers) onto the hole-blocking layer and dried at 50 degrees Celsius, followed by baking in the air for 30 minutes at 500 degrees Celsius, to thereby form a porous electron-transporting layer.

The glass substrate on which the electron-transporting layer had been formed was immersed in an acetnitrile/t-butanol (volume ratio 1:1) solution including 0.2 mM of the photosensitizing compound represented by Structural Formula (A) below (product name: DN455, available from Chemicrea Inc.) and 0.4 mM of chenodeoxycholic acid (CDCA, available from Tokyo Chemical Industry Co., Ltd.) and was left to stand in the dark for 1 hour, to thereby allow the photosensitizing compound to adsorb on a surface of the electron-transporting layer. Next, 25.5 mg of 1-ethyl-3-methylimidazolium bis(trifluoromethanesulfonyl)imide (product name: EMIMIm, available from Tokyo Chemical Industry Co., Ltd.) serving as additive and 14.8 mg of N,N-dimethyl-4-aminopyridine (product name: DMAP, available from Tokyo Chemical Industry Co., Ltd.) serving as a basic compound were added to and dissolved in 1 mL of a chlorobenzene solution including 186.5 mg of the hole-transporting material represented by D-7 above (available from Merck KGaA), to thereby prepare a hole-transporting layer coating liquid.

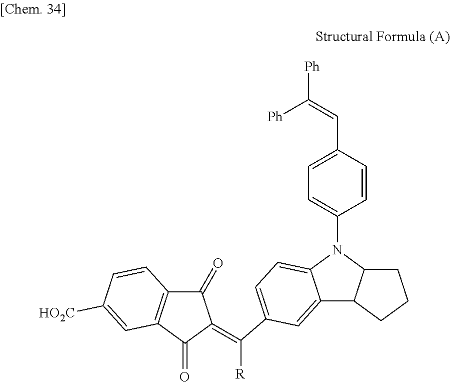

In Structural Formula (A), Ph is a phenyl group.

Next, the hole-transporting layer coating liquid was applied, by spin coating, onto the electron-transporting layer on which the photosensitizing compound had been adsorbed, to thereby form a hole-transporting layer (average thickness: 600 nm). On the hole-transporting layer, silver was deposited by vacuum vapor deposition to from a second electrode (average thickness: 100 nm), to thereby produce a photoelectric conversion element of Example 1.

### Example 2

A photoelectric conversion element of Example 2 was produced in the same manner as in Example 1, except that the hole-transporting material was replaced with the hole-transporting material represented by Structural Formula (FDT) below.

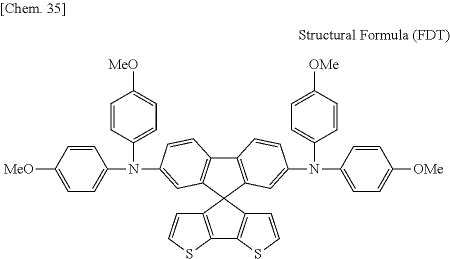 [SMILES: COc1ccc(N(c2ccc(OC)cc2)c2ccc3c(c2)C2(c4cc(N(c5ccc(OC)cc5)c5ccc(OC)cc5)ccc4-3)c3ccsc3-c3sccc32)cc1]

In Structural Formula (FDT), Me is a methyl group.

### Example 3

A photoelectric conversion element of Example 3 was produced in the same manner as in Example 1, except that the hole-transporting material was replaced with the hole-transporting material represented by D-10 above.

### Examples 4 to 6

Photoelectric conversion elements of Examples 4 to 6 were produced in the same manner as in Example 3, except that the amount of the N,N-dimethyl-4-aminopyridine serving as the basic compound was changed to 16.3 mg, 11.8 mg, and 8.9 mg, respectively.

### Example 7

A photoelectric conversion element of Example 7 was produced in the same manner as in Example 6, except that the photosensitizing compound was replaced with D358 (product name, available from MITSUBISHI PAPER MILLS LIMITED).

### Examples 8 to 14

Photoelectric conversion elements of Examples 8 to 14 were produced in the same manner as in Example 1, except that the basic compound was replaced with the basic compounds represented by P-1 to P-7 below, respectively, and the amount of the basic compound was changed to 41.1 mg, 37.1 mg, 24.7 mg, 24.5 mg, 27.8 mg, 16.6 mg, and 19.5 mg, respectively.

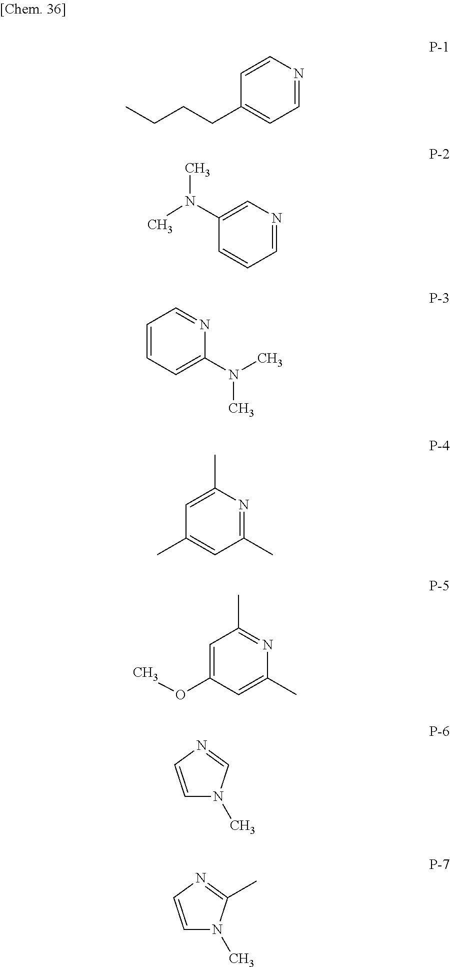

### Example 15

A photoelectric conversion element of Example 15 was produced in the same manner as in Example 1, except that 12.5 mg of the oxidizing agent represented by Structural Formula A below (product name: FK269, available from Sigma-Aldrich Co., LLC.) was added as the oxidizing agent to the hole-transporting layer coating liquid.

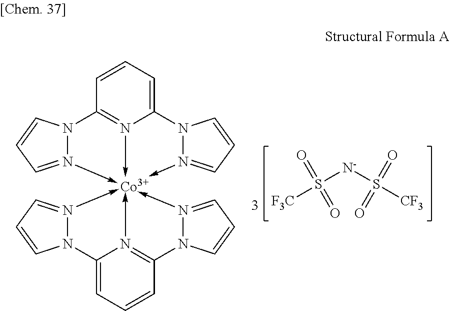

### Example 16

A photoelectric conversion element of Example 16 was produced in the same manner as in Example 15, except that the oxidizing agent was replaced with the oxidizing agent represented by Structural Formula B below (DN-Cu08) and the amount of the oxidizing agent was changed to 9.8 mg.

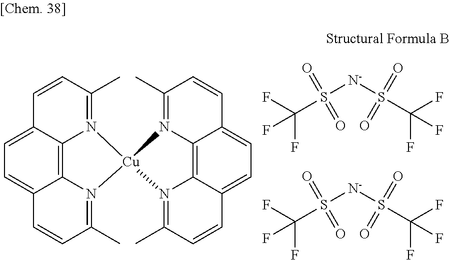

### Example 17

A photoelectric conversion element of Example 17 was produced in the same manner as in Example 15, except that the oxidizing agent was replaced with tris(4-bromophenyl)ammonium hexachloroantimonate (T4AH) and the amount of the oxidizing agent was changed to 7.7 mg.

### Example 18

A photoelectric conversion element of Example 18 was produced in the same manner as in Example 15, except that 1-ethyl-3-methylimidazoliumbis(trifluoromethanesulfonyl)imide serving as the additive was replaced with lithium bis(trifluoromethanesulfonyl)imide (LiTFSI) serving as an alkali metal salt.

### Example 19

A photoelectric conversion element of Example 19 was produced in the same manner as in Example 18, except that the alkali metal salt was replaced with sodium bis(trifluoromethanesulfonyl)imide (NaTFSI) and the amount of the alkali metal salt was changed to 19.7 mg.

### Example 20

A photoelectric conversion element of Example 20 was produced in the same manner as in Example 18, except that the alkali metal salt was replaced with lithium bis(fluorosulfonyl)imide (LiFSI) and the amount of the alkali metal salt was changed to 12.9 mg.

### Examples 21 to 25

Photoelectric conversion elements of Examples 21 to 25 were produced in the same manner as in Example 18, except that the basic compound was replaced with Compound No. 13 above, the basic compound represented by P-13 below, the basic compound represented by P-9 below, Compound No. 12 above, and the basic compound represented by P-10 below, respectively, and the amount of the basic compound was changed to 18.0 mg, 33.2 mg, 52.7 mg, 37.0 mg, and 55.3 mg, respectively.

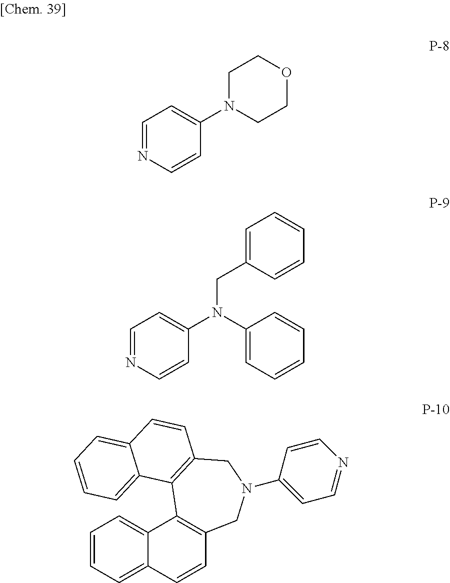

### Example 26

A photoelectric conversion element of Example 25 was produced in the same manner as in Example 24, except that the oxidizing agent was replaced with the cobalt complex compound represented by Structural Formula C below (FK209, available from Sigma-Aldrich Co., LLC.) and the amount of the oxidizing agent was changed to 17.8 mg.

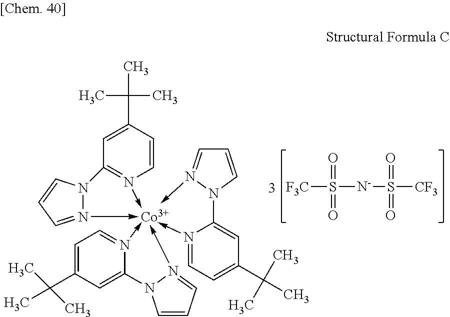

### Examples 27 to 29

Photoelectric conversion elements of Examples 27 to 29 were produced in the same manner as in Example 26, except that a portion of the hole-transporting layer present at the outer rim of the glass substrate where the electron-transporting layer was not formed was removed after forming the second electrode, as a sealing member, Acrylic Resin A (UV ray curable, product name: TB3035B, available from ThreeBond Holdings Co., Ltd.), Epoxy Resin A (UV ray curable, product name: TB3118, available from ThreeBond Holdings Co., Ltd.), and Epoxy Resin B (UV ray curable, product name: World Rock No. 5910, available from Kyoritsu Chemical & Co., Ltd.) were applied by a dispenser (product name: 2300N, available from SAN-EI TECH Ltd.), the resultant was transferred into a glove box purged with nitrogen gas and cover glass serving as a second substrate was placed on the sealing member, followed by performing ultraviolet ray irradiation to cure the sealing member to thereby seal a power generation region (FIG. 2).

### Examples 30 to 35

Photoelectric conversion elements of Examples 30 to 35 were produced in the same manner as in Example 29, except that Epoxy Resin B (UV ray curable, product name: World Rock No. 5910, available from Kyoritsu Chemical & Co., Ltd.) were applied by a dispenser (product name: 2300N, available from SAN-EI TECH Ltd.) to surround a power generation region, the resultant was transferred into a glove box purged with mixed gas of nitrogen gas and oxygen (oxygen concentration: 0.6% by volume, 3.0% by volume, 5.0% by volume, 10.0% by volume, 15.0% by volume, and 20.0% by volume) and cover glass serving as a second substrate was placed on Epoxy Resin B, followed by performing ultraviolet ray irradiation to cure Epoxy Resin B to thereby seal the power generation region (FIG. 1).

### Example 36

A photoelectric conversion element module of Example 36 was produced in the same manner as in Example 32, except that laser etching was performed on the ITO conductive film serving as the first electrode by a laser device to process into a 6-series-cell substrate, after forming the hole-transporting layer, through holes configured to connect photoelectric conversion elements in series were formed by laser processing, and then silver was deposited on the hole-transporting layer by vacuum vapor deposition using a mask having a pattern to give 6 series cells to form a second electrode (average thickness: 100 nm) (FIG. 6 and FIG. 7). Note that, FIG. 6 and FIG. 7 are schematic views which are observed from mutually different directions.

### Comparative Example 1

A photoelectric conversion element of Comparative Example 1 was produced in the same manner as in Example 6, except that the photosensitizing compound was replaced with the photosensitizing compound represented by Structural Formula (2) above (product name: D102, available from MITSUBISHI PAPER MILLS LIMITED), the chenodeoxycholic acid (CDCA) was not added, and the basic compound was replaced with 4-tert-butylpyridine (tBP).

### Comparative Example 2

A photoelectric conversion element of Comparative Example 2 was produced in the same manner as in Example 6, except that the basic compound was replaced with 4-tert-butylpyridine (tBP).

### Comparative Examples 3 to 4

Photoelectric conversion elements of Comparative Examples 3 to 4 were produced in the same manner as in Example 6, except that the basic compound was replaced with the basic compound represented by P-11 below and the basic compound represented by P-12 below.

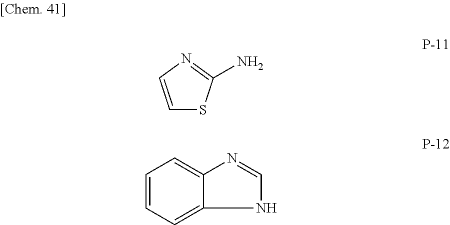 [SMILES: Nc1nccs1 ; c1ccc2[nH]cnc2c1]

### Comparative Example 5

A photoelectric conversion element of Comparative Example 5 was produced in the same manner as in Example 7, except that the basic compound was replaced with 4-tert-butylpyridine (tBP), the amount of the basic compound was changed to 7.4 mg, and the ionization potential of the hole-transporting layer was adjusted to the value presented in Table 2.

### Comparative Example 6

A photoelectric conversion element of Comparative Example 6 was produced in the same manner as in Comparative Example 5, except that the photosensitizing compound was replaced with the photosensitizing compound represented by Structural Formula (2) above (product name: D102, available from MITSUBISHI PAPER MILLS LIMITED).

<Ionization Potential>

Ionization potential of the photosensitizing compound, ionization potential of the hole-transporting material, and ionization potential of the hole-transporting layer were measured by means of an atmospheric pressure photoelectron spectroscopy apparatus (device name: AC-2, available from RIKEN KEIKI Co., Ltd.). Note that, the ionization potential of the photosensitizing compound was measured in the state that the photosensitizing compound was adsorbed on the electron-transporting layer.

Moreover, a ratio (ionization potential of hole-transporting layer/ionization potential of hole-transporting material) between the ionization potential of the hole-transporting material and the ionization potential of the hole-transporting layer was determined.

<pKa and Molecular Weight>

The pKa and molecular weight of the basic compound were calculated using software (ACD/Labs Software V11.02).

Next, each of the produced photoelectric conversion elements was evaluated in terms of “initial value retention rate after continuous irradiation” in the following manner. The results are presented in Table 1.

<Initial Value Retention Rate after Continuous Irradiation>

IV properties of each of the produced photoelectric conversion elements were evaluated under white LED irradiation adjusted to 200 lux by means of a solar battery evaluation system (DC voltage-power supply/monitor, 6241A, available from ADC CORPORATION) to determine initial maximum output power Pₘₐₓ₁ (microwatt/cm²).

Next, the photoelectric conversion element was stored for 500 hours in a nitrogen gas atmosphere under white LED irradiation adjusted to 1,000 lux. Thereafter, IV properties were evaluated again to determine the maximum output power Pₘₐₓ₂ (microwatt/cm²) after the continuous irradiation of 1,000 lux. “Initial value retention rate after continuous irradiation” (Pₘₐₓ₂/Pₘₐₓ₁) 1 was determined by dividing the obtained Pₘₐₓ₂ with Pₘₐₓ₁ that was the initial value.

TABLE 1

| | Hole- | Ip of hole- | Ip of hole- | | | |
|---|---|---|---|---|---|---|
| | transporting | transporting | transporting | | | |
| | material | material | layer | Ip ratio | Dye | Ip of dye |
| Ex. 1 | D-7 | 5.01 | 5.12 | 1.02 | DN455/ | 5.30 |
| | | | | | CDCA | |
| Ex. 2 | FDT | 5.16 | 5.28 | 1.02 | DN455/ | 5.30 |
| | | | | | CDCA | |
| Ex. 3 | D-10 | 4.95 | 5.06 | 1.02 | DN455/ | 5.30 |
| | | | | | CDCA | |
| Ex. 4 | D-10 | 4.95 | 5.01 | 1.01 | DN455/ | 5.30 |
| | | | | | CDCA | |
| Ex. 5 | D-10 | 4.95 | 5.16 | 1.04 | DN455/ | 5.30 |
| | | | | | CDCA | |
| Ex. 6 | D-10 | 4.95 | 5.25 | 1.06 | DN455/ | 5.30 |
| | | | | | CDCA | |
| Ex. 7 | D-10 | 4.95 | 5.25 | 1.06 | D358/ | 5.32 |
| | | | | | CDCA | |
| Ex. 8 | D-7 | 5.01 | 5.12 | 1.02 | DN455/ | 5.30 |
| | | | | | CDCA | |
| Ex. 9 | D-7 | 5.01 | 5.12 | 1.02 | DN455/ | 5.30 |
| | | | | | CDCA | |
| Ex. 10 | D-7 | 5.01 | 5.12 | 1.02 | DN455/ | 5.30 |
| | | | | | CDCA | |
| Ex. 11 | D-7 | 5.01 | 5.12 | 1.02 | DN455/ | 5.30 |
| | | | | | CDCA | |
| Ex. 12 | D-7 | 5.01 | 5.12 | 1.02 | DN455/ | 5.30 |
| | | | | | CDCA | |
| Ex. 13 | D-7 | 5.01 | 5.12 | 1.02 | DN455/ | 5.30 |
| | | | | | CDCA | |
| Ex. 14 | D-7 | 5.01 | 5.12 | 1.02 | DN455/ | 5.30 |
| | | | | | CDCA | |
| Ex. 15 | D-7 | 5.01 | 5.18 | 1.03 | DN455/ | 5.30 |
| | | | | | CDCA | |
| Ex. 16 | D-7 | 5.01 | 5.18 | 1.03 | DN455/ | 5.30 |
| | | | | | CDCA | |
| Ex. 17 | D-7 | 5.01 | 5.18 | 1.03 | DN455/ | 5.30 |
| | | | | | CDCA | |
| Ex. 18 | D-7 | 5.01 | 5.19 | 1.04 | DN455/ | 5.30 |
| | | | | | CDCA | |
| Ex. 19 | D-7 | 5.01 | 5.19 | 1.04 | DN455/ | 5.30 |
| | | | | | CDCA | |
| Ex. 20 | D-7 | 5.01 | 5.19 | 1.04 | DN455/ | 5.30 |
| | | | | | CDCA | |
| Ex. 21 | D-7 | 5.01 | 5.19 | 1.04 | DN455/ | 5.30 |
| | | | | | CDCA | |
| Ex. 22 | D-7 | 5.01 | 5.19 | 1.04 | DN455/ | 5.30 |
| | | | | | CDCA | |
| Ex. 23 | D-7 | 5.01 | 5.19 | 1.04 | DN455/ | 5.30 |
| | | | | | CDCA | |
| Ex. 24 | D-7 | 5.01 | 5.19 | 1.04 | DN455/ | 5.30 |
| | | | | | CDCA | |
| Ex. 25 | D-7 | 5.01 | 5.19 | 1.04 | DN455/ | 5.30 |
| | | | | | CDCA | |
| Ex. 26 | D-7 | 5.01 | 5.19 | 1.04 | DN455/ | 5.30 |
| | | | | | CDCA | |
| Ex. 27 | D-7 | 5.01 | 5.19 | 1.04 | DN455/ | 5.30 |
| | | | | | CDCA | |
| Ex. 28 | D-7 | 5.01 | 5.19 | 1.04 | DN455/ | 5.30 |
| | | | | | CDCA | |
| Ex. 29 | D-7 | 5.01 | 5.19 | 1.04 | D358/ | 5.30 |
| | | | | | CDCA | |
| Ex. 30 | D-7 | 5.01 | 5.19 | 1.04 | DN455/ | 5.30 |
| | | | | | CDCA | |
| Ex. 31 | D-7 | 5.01 | 5.19 | 1.04 | DN455/ | 5.30 |
| | | | | | CDCA | |
| Ex. 32 | D-7 | 5.01 | 5.19 | 1.04 | DN455/ | 5.30 |
| | | | | | CDCA | |
| Ex. 33 | D-7 | 5.01 | 5.19 | 1.04 | DN455/ | 5.30 |
| | | | | | CDCA | |
| Ex. 34 | D-7 | 5.01 | 5.19 | 1.04 | DN455/ | 5.30 |
| | | | | | CDCA | |
| Ex. 35 | D-7 | 5.01 | 5.19 | 1.04 | DN455/ | 5.30 |
| | | | | | CDCA | |
| Ex. 36 | D-7 | 5.01 | 5.19 | 1.04 | DN455/ | 5.30 |
| | | | | | CDCA | |
| Comp. | D-10 | 4.95 | 5.25 | 1.06 | D102 | 5.20 |
| Ex. 1 | | | | | | |
| Comp. | D-10 | 4.95 | 5.25 | 1.06 | DN455/ | 5.30 |
| Ex. 2 | | | | | CDCA | |
| Comp. | D-10 | 4.95 | 5.25 | 1.06 | DN455/ | 5.30 |
| Ex. 3 | | | | | CDCA | |
| Comp. | D-10 | 4.95 | 5.25 | 1.06 | DN455/ | 5.30 |
| Ex. 4 | | | | | CDCA | |
| Comp. | D-10 | 4.95 | 5.31 | 1.07 | D358/ | 5.32 |
| Ex. 5 | | | | | CDCA | |
| Comp. | D-10 | 4.95 | 5.31 | 1.07 | D102 | 5.20 |
| Ex. 6 | | | | | | |

| | | | | Alkali | | | | Initial | |
|---|---|---|---|---|---|---|---|---|---|
| | | | | metal | Molecular | | Oxygen | max | Retention |
| | | pKa of | | salt and | weight of | | concentration | output | rate after |
| | Basic | basic | Oxydizing | other | basic | Sealing | in seal | power | storage |
| | compound | compound | agent | additives | compound | member | (vol %) | (μW/cm²) | (%) |
| Ex. 1 | DMAP | 9.52 | NA | EMIMIm | 122.17 | NA | NA | 7.8 | 71 |
| Ex. 2 | DMAP | 9.52 | NA | EMIMIm | 122.17 | NA | NA | 7.7 | 71 |
| Ex. 3 | DMAP | 9.52 | NA | EMIMIm | 122.17 | NA | NA | 7.7 | 72 |
| Ex. 4 | DMAP | 9.52 | NA | EMIMIm | 122.17 | NA | NA | 7.5 | 71 |
| Ex. 5 | DMAP | 9.52 | NA | EMIMIm | 122.17 | NA | NA | 7.8 | 72 |
| Ex. 6 | DMAP | 9.52 | NA | EMIMIm | 122.17 | NA | NA | 7.6 | 72 |
| Ex. 7 | DMAP | 9.52 | NA | EMIMIm | 122.17 | NA | NA | 7.5 | 72 |
| Ex. 8 | P-1 | 6.04 | NA | EMIMIm | 135.21 | NA | NA | 7.0 | 70 |
| Ex. 9 | P-2 | 6.33 | NA | EMIMIm | 122.17 | NA | NA | 7.1 | 70 |
| Ex. 10 | P-3 | 7.04 | NA | EMIMIm | 122.17 | NA | NA | 7.3 | 72 |
| Ex. 11 | P-4 | 7.33 | NA | EMIMIm | 121.18 | NA | NA | 7.4 | 72 |
| Ex. 12 | P-5 | 7.97 | NA | EMIMIm | 137.18 | NA | NA | 7.6 | 72 |
| Ex. 13 | P-6 | 7.01 | NA | EMIMIm | 82.10 | NA | NA | 7.1 | 71 |
| Ex. 14 | P-7 | 7.76 | NA | EMIMIm | 96.13 | NA | NA | 7.3 | 71 |
| Ex. 15 | DMAP | 9.52 | FK269 | EMIMIm | 122.17 | NA | NA | 8.4 | 75 |
| Ex. 16 | DMAP | 9.52 | DN-Cu08 | EMIMIm | 122.17 | NA | NA | 8.1 | 73 |
| Ex. 17 | DMAP | 9.52 | FK269 | EMIMIm | 122.17 | NA | NA | 8.0 | 72 |
| Ex. 18 | DMAP | 9.52 | FK269 | LiTFSI | 122.17 | NA | NA | 8.8 | 79 |
| Ex. 19 | DMAP | 9.52 | FK269 | NaTFSI | 122.17 | NA | NA | 8.4 | 77 |
| Ex. 20 | DMAP | 9.52 | FK269 | LiFSI | 122.17 | NA | NA | 8.5 | 79 |
| Ex. 21 | Compound | 9.58 | FK269 | LiTFSI | 148.21 | NA | NA | 9.3 | 80 |
| | No. 13 | | | | | | | | |
| Ex. 22 | P-8 | 7.97 | FK269 | LiTFSI | 164.20 | NA | NA | 9.1 | 80 |
| Ex. 23 | P-9 | 7.78 | FK269 | LiTFSI | 260.33 | NA | NA | 9.1 | 81 |
| Ex. 24 | C-1 | 9.28 | FK269 | LiTFSI | 274.17 | NA | NA | 9.5 | 81 |
| Ex. 25 | P-10 | 8.99 | FK269 | LiTFSI | 372.46 | NA | NA | 9.3 | 81 |
| Ex. 26 | C-1 | 9.28 | FK269 | LiTFSI | 274.17 | NA | NA | 9.5 | 89 |
| Ex. 27 | C-1 | 9.28 | FK209 | LiTFSI | 274.17 | Acrylic | 0.0 | 9.6 | 83 |
| | | | | | | Resin A | | | |
| Ex. 28 | C-1 | 9.28 | FK209 | LiTFSI | 274.17 | Epoxy | 0.0 | 9.7 | 85 |
| | | | | | | Resin A | | | |
| Ex. 29 | C-1 | 9.28 | FK209 | LiTFSI | 274.17 | Epoxy | 0.0 | 9.8 | 85 |
| | | | | | | Resin B | | | |
| Ex. 30 | C-1 | 9.28 | FK209 | LiTFSI | 274.17 | Epoxy | 0.6 | 10.1 | 87 |
| | | | | | | Resin B | | | |
| Ex. 31 | C-1 | 9.28 | FK209 | LiTFSI | 274.17 | Epoxy | 3.0 | 10.3 | 89 |
| | | | | | | Resin B | | | |
| Ex. 32 | C-1 | 9.28 | FK209 | LiTFSI | 274.17 | Epoxy | 5.0 | 10.6 | 90 |
| | | | | | | Resin B | | | |
| Ex. 33 | C-1 | 9.28 | FK209 | LiTFSI | 274.17 | Epoxy | 10.0 | 10.7 | 92 |
| | | | | | | Resin B | | | |
| Ex. 34 | C-1 | 9.28 | FK209 | LiTFSI | 274.17 | Epoxy | 15.0 | 10.8 | 92 |
| | | | | | | Resin B | | | |
| Ex. 35 | C-1 | 9.28 | FK209 | LiTFSI | 274.17 | Epoxy | 21.0 | 10.7 | 90 |
| | | | | | | Resin B | | | |
| Ex. 36 | C-1 | 9.28 | FK269 | LiTFSI | 274.17 | Epoxy | 5.0 | 10.6 | 91 |
| | | | | | | Resin B | | | |
| Comp. | tBP | 5.98 | NA | EMIMIm | 135.21 | NA | NA | 5.1 | 53 |
| Ex. 1 | | | | | | | | | |
| Comp. | tBP | 5.98 | NA | EMIMIm | 135.21 | NA | NA | 5.8 | 54 |
| Ex. 2 | | | | | | | | | |
| Comp. | P-11 | 4.94 | NA | EMIMIm | 100.14 | NA | NA | 4.9 | 50 |
| Ex. 3 | | | | | | | | | |
| Comp. | P-12 | 12.56 | NA | EMIMIm | 118.14 | NA | NA | 4.8 | 47 |
| Ex. 4 | | | | | | | | | |
| Comp. | tBP | 5.98 | NA | EMIMIm | 135.21 | NA | NA | 5.9 | 54 |
| Ex. 5 | | | | | | | | | |
| Comp. | tBP | 5.98 | NA | EMIMIm | 135.21 | NA | NA | 4.6 | 45 |
| Ex. 6 | | | | | | | | | |

It was found from the results presented in Table 1 that the photoelectric conversion elements of Examples 1 to 36 had high photoelectric conversion performance with low illuminance and excellent stability over time. It was assumed that this was because high internal resistance could be obtained while maintaining excellent hole conduction from the photosensitizing compound at low illuminance, fine change in crystallinity of the hole-transporting layer over time could be suppressed, and contact at the interface could be excellently maintained.

On the other hand, the photoelectric conversion elements of Comparative Examples 1 to 6, which were outside the scope of the present disclosure, could not obtain desired properties.

As it can be understood from above, the photoelectric conversion element of the present disclosure has excellent photoelectric conversion performance with low illumination light and excellent stability over time.

For example, embodiments of the present disclosure are as follows.

<1> A photoelectric conversion element including:

a first electrode;

an electron-transporting layer including a photosensitizing compound;

a hole-transporting layer; and

a second electrode,

wherein the hole-transporting layer includes a p-type semiconductor material and a basic compound,

ionization potential of the hole-transporting layer is greater than ionization potential of the p-type semiconductor material, and is less than 1.07 times the ionization potential of the p-type semiconductor material,

ionization potential of the photosensitizing compound is greater than the ionization potential of the hole-transporting layer, and

an acid dissociation constant (pKa) of the basic compound is 6 or greater but 10 or less.

<2> The photoelectric conversion element according to <1>,

wherein the hole-transporting layer includes an oxidizing agent.

<3> The photoelectric conversion element according to <2>,

wherein the oxidizing agent is a complex of a metal that is at least one selected from the group consisting of Fe, Cu, Co, V, Zn, Ag, Mn, and Ru.

<4> The photoelectric conversion element according to any one of <1> to <3>,

wherein the hole-transporting layer includes an alkali metal salt.

<5> The photoelectric conversion element according to any one of <1> to <4>,

wherein a molecular weight of the basic compound is 140 g/mol or greater.

<6> The photoelectric conversion element according to any one of <1> to <5>,

wherein the basic compound is a tertiary amine compound represented by General Formula (1) below, or a tertiary amine compound represented by General Formula (2) below, or both:

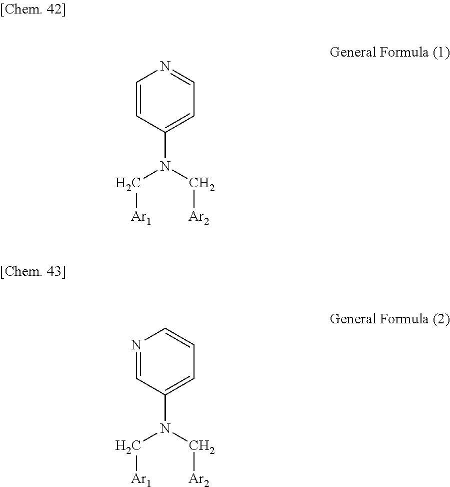

where, in General Formula (1) and General Formula (2), Ar₁ and Ar₂ are each an aryl group that may have a substituent, where Ar₁ and Ar₂ may be identical or different and may be bonded to each other.

<7> The photoelectric conversion element according to any one of <1> to <6>, further including a sealing member configured to shield the electron-transporting layer and the hole-transporting layer from an outer environment of the photoelectric conversion element.

<8> The photoelectric conversion element according to <7>,

wherein the sealing member is sandwiched between a pair of substrates, and the photoelectric conversion element has a void space inside the sealed photoelectric conversion element where at least the electron-transporting layer and the hole-transporting layer are shielded from the outer environment

<9> The photoelectric conversion element according to any one of <1> to <6>, further including a sealing member configured to shield the electron-transporting layer, the hole-transporting layer, and the second electrode from an outer environment of the photoelectric conversion element.

<10> The photoelectric conversion element according to <9>,

wherein the sealing member is sandwiched between a pair of substrates, and the photoelectric conversion element has a void space inside the sealed photoelectric conversion element where at least the electron-transporting layer, the hole-transporting layer, and the second electrode are shielded from an outer environment.

<11> The photoelectric conversion element according to any one of <7> to <10>,

wherein the sealing member includes an epoxy resin.

<12> The photoelectric conversion element according to <8> or <10>,

wherein the void space includes oxygen.

<13> The photoelectric conversion element according to any one of <7> to <12>,

wherein the sealing member includes inorganic filler.

<14> A photoelectric conversion element module including:

a plurality of the photoelectric conversion elements according to any one of <1> to <13>.

<15> The photoelectric conversion element module according to <14>,

wherein the photoelectric conversion elements are connected in series or in parallel.

<16> The photoelectric conversion element module according to <14> or <15>,

wherein, among at least two photoelectric conversion elements next to each other, the first electrode in one of the photoelectric conversion elements and the second electrode in other photoelectric conversion element are electrically connected via a conduction part that penetrates at least the hole-transporting layer and a hole-blocking layer, where the hole-transporting layer and the hole-blocking layer are each in a state of a continuous layer in the photoelectric conversion elements next to each other.

<17> A photoelectric conversion element module including:

a photoelectric conversion element-disposed region where a plurality of photoelectric conversion elements are disposed next to one another; and

a sealing member that is disposed at a rim of the photoelectric conversion element-disposed region, and includes an epoxy resin,

wherein each of the photoelectric conversion elements includes a first electrode, an electron-transporting layer including a photosensitizing compound, a hole-transporting layer, and a second electrode,

the sealing member is configured to shield the electron transporting layer from an outer environment of the photoelectric conversion element,

the hole-transporting layer includes a p-type semiconductor material and a basic compound,

ionization potential of the hole-transporting layer is greater than ionization potential of the p-type semiconductor material and is less than 1.07 times the ionization potential of the p-type semiconductor material,

ionization potential of the photosensitizing compound is greater than the ionization potential of the hole-transporting layer, and

an acid dissociation constant (pKa) of the basic compound is 6 or greater but 10 or less.

<18> An electronic device including:

the photoelectric conversion element according to any one of <1> to <13> and/or the photoelectric conversion element module according to any one of <14> to <17>; and

a device that is driven by electric power generated through photoelectric conversion performed by the photoelectric conversion element and/or the photoelectric conversion element module.

<19> A power supply module including:

the photoelectric conversion element according to any one of <1> to <13> and/or the photoelectric conversion element module according to any one of <14> to <17>; and

a power supply IC.

The photoelectric conversion element according to any one of <1> to <13>, the photoelectric conversion element module according to any one of <14> to <17>, the electronic device according to <18>, and the power supply module according to <19> can solve the above-described various problems existing in the art and can achieve the object of the present disclosure.

### REFERENCE SIGNS LIST

1: first substrate
2, 2a, and 2b: first electrode
3: hole-blocking layer
4: electron-transporting layer
5: photosensitizing compound
6: hole-transporting layer
7, 7a, and 7b: second electrode
8: sealing member
9: second substrate
10: void part
11: through part
12: sealing member
101: photoelectric conversion element
102: photoelectric conversion element module

1. A photoelectric conversion element comprising:
a first electrode;
an electron-transporting layer including a photosensitizing compound;
a hole-transporting layer; and
a second electrode,
wherein the hole-transporting layer includes a p-type semiconductor material and a basic compound,
ionization potential of the hole-transporting layer is greater than ionization potential of the p-type semiconductor material, and is less than 1.07 times the ionization potential of the p-type semiconductor material,
ionization potential of the photosensitizing compound is greater than the ionization potential of the hole-transporting layer, and
an acid dissociation constant (pKa) of the basic compound is 6 or greater but 10 or less.

2. The photoelectric conversion element according to claim 1,
wherein the hole-transporting layer includes an oxidizing agent.

3. The photoelectric conversion element according to claim 2,
wherein the oxidizing agent is a complex of a metal that is at least one selected from the group consisting of Fe, Cu, Co, V, Zn, Ag, Mn, and Ru.

4. The photoelectric conversion element according to claim 1,
wherein the hole-transporting layer includes an alkali metal salt.

5. The photoelectric conversion element according to claim 1,
wherein a molecular weight of the basic compound is 140 g/mol or greater.

6. The photoelectric conversion element according to claim 1,
wherein the basic compound is a tertiary amine compound represented by General Formula (1) below, or a tertiary amine compound represented by General Formula (2) below, or both: 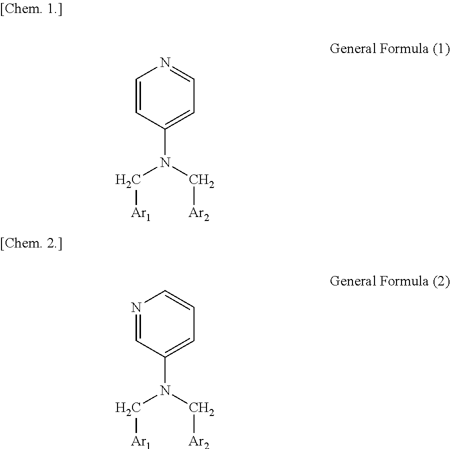
where, in General Formula (1) and General Formula (2), Ar1 and Ar2 are each an aryl group that may have a substituent, where Ar1 and Ar2 may be identical or different and may be bonded to each other.

7. The photoelectric conversion element according to claim 1, further comprising a sealing member configured to shield the electron-transporting layer and the hole-transporting layer from an outer environment of the photoelectric conversion element.

8. The photoelectric conversion element according to claim 7,
wherein the sealing member is sandwiched between a pair of substrates, and the photoelectric conversion element has a void space inside the sealed photoelectric conversion element where at least the electron-transporting layer and the hole-transporting layer are shielded from the outer environment.

9. The photoelectric conversion element according to claim 1, further comprising a sealing member configured to shield the electron-transporting layer, the hole-transporting layer, and the second electrode from an outer environment of the photoelectric conversion element.

10. The photoelectric conversion element according to claim 9,
wherein the sealing member is sandwiched between a pair of substrates, and the photoelectric conversion element has a void space inside the sealed photoelectric conversion element where at least the electron-transporting layer, the hole-transporting layer, and the second electrode are shielded from an outer environment.

11. The photoelectric conversion element according to claim 7,
wherein the sealing member includes an epoxy resin.

12. The photoelectric conversion element according to claim 8,
wherein the void space includes oxygen.

13. A photoelectric conversion element module comprising:
a plurality of the photoelectric conversion elements according to claim 1.

14. The photoelectric conversion element module according to claim 13,
wherein the photoelectric conversion elements are connected in series or in parallel.

15. The photoelectric conversion element module according to claim 13,
wherein, among at least two photoelectric conversion elements next to each other, the first electrode in one of the photoelectric conversion elements and the second electrode in other photoelectric conversion element are electrically connected via a conduction part that penetrates at least the hole-transporting layer and a hole-blocking layer, where the hole-transporting layer and the hole-blocking layer are each in a state of a continuous layer in the photoelectric conversion elements next to each other.

16. A photoelectric conversion element module comprising:
a photoelectric conversion element-disposed region where a plurality of photoelectric conversion elements are disposed next to one another; and
a sealing member that is disposed at a rim of the photoelectric conversion element-disposed region, and includes an epoxy resin,
wherein each of the photoelectric conversion elements includes a first electrode, an electron-transporting layer including a photosensitizing compound, a hole-transporting layer, and a second electrode,
the sealing member is configured to shield the electron transporting layer from an outer environment of the photoelectric conversion element,
the hole-transporting layer includes a p-type semiconductor material and a basic compound,
ionization potential of the hole-transporting layer is greater than ionization potential of the p-type semiconductor material and is less than 1.07 times the ionization potential of the p-type semiconductor material,
ionization potential of the photosensitizing compound is greater than the ionization potential of the hole-transporting layer, and
an acid dissociation constant (pKa) of the basic compound is 6 or greater but 10 or less.

17. An electronic device comprising:
the photoelectric conversion element according to claim 1; and
a device that is driven by electric power generated through photoelectric conversion performed by the photoelectric conversion element, or the photoelectric conversion element module, or both.

18. A power supply module comprising:
the photoelectric conversion element according to claim 1; and
a power supply IC.
